(19) United States
(12) Patent Application Publication
(10) Pub. No.: US 2025/0046643 A1
(43) Pub. Date: Feb. 6, 2025

(54) DIRECT-PICK ROBOT FOR MULTI-STATION SEMICONDUCTOR PROCESSING CHAMBERS

(71) Applicant: Lam Research Corporation, Fremont, CA (US)

(72) Inventors: Richard M. Blank, San Jose, CA (US); Izya Kremerman, Los Gatos, CA (US)

(21) Appl. No.: 18/715,235

(22) PCT Filed: Dec. 1, 2022
(86) PCT No.: PCT/US2022/080775

§ 371 Date: May 31, 2024

Related U.S. Application Data
(60) Provisional application No. 63/264,905, filed on Dec. 3, 2021.

(51) Int. Cl. H01L 21/687; B65G 47/90

(52) U.S. Cl. CPC H01L 21/68707; B65G 47/90

(57) ABSTRACT

Disclosed herein are direct-pick wafer handling robot systems that may be used to directly pick four wafers from, or directly place four wafers in, stations of a multi-station module, e.g., a quad-station module (QSM). Such wafer handling robot systems include two sets of robot arm pairs, with each robot arm pair able to be used independently of the other so that one robot arm pair may be used to pick wafers from a QSM while the other robot arm pair supports a set of four wafers to be placed into that same QSM once the wafers in the QSM are removed. Such wafer handling robot systems may allow for each wafer to be directly placed within each station of the QSM and can be adapted to allow each such wafer placement to be individually adjusted to allow each wafer to be centered on a respective target pedestal.

### RELATED APPLICATION(S)

An application data sheet is filed concurrently with this specification as part of the present application. Each application that the present application claims benefit of or priority to as identified in the concurrently filed application data sheet is incorporated by reference herein in its entirety and for all purposes.

### BACKGROUND

The processing of semiconductor wafers to produce integrated circuits and other structures is typically performed in a semiconductor processing tool, which may include one or more semiconductor processing chambers, each of which is configured to process one or more wafers. Some semiconductor processing tools may have one or more semiconductor processing chambers that are multi-station chambers, e.g., that have the capability to process multiple different wafers at different locations within the chamber simultaneously (a multi-station chamber may also be referred to herein as a multi-station processing chamber). One particular type of multi-station chamber is a quad-station module (QSM), which features four wafer processing stations, with each such station having a wafer-receiving surface, such as provided by a pedestal. The stations within a QSM are typically laid out in a circular/square pattern, thereby allowing, in some cases, an internal carousel, rotational indexer system, or wafer handling robot to be used to rotate wafers between different stations within the QSM chamber.

FIG. 1 depicts a schematic of an example QSM. The QSM of FIG. 1 has a process chamber 104 that contains four pedestals 106, each at a station labeled A, B, C, or D. A rotational indexer (not shown) may be placed in the process chamber 104 and may include four arms arranged in a “plus” (+) configuration which are rotatable about a rotational axis centered between the four pedestals 106. Wafers that are on the pedestals 106 may be lifted off the pedestals 106 by lift pins (not shown) and the indexer arms then rotated therebeneath. The wafers may then be lowered onto the indexer arms and the lift pins retracted, after which the indexer may be rotated by a multiple of 90° to shift the wafers between different stations. The lift pins may then be extended to lift the wafers off of the indexer and the indexer then rotated by 45° to move the indexer arms to locations in between each pedestal. The wafers may then be lowered onto their respective pedestals 106 by lowering the lift pins.

In such a QSM, the wafers are typically indirectly placed onto their initial destination pedestals by an external wafer handling robot. For example, as shown by the arrows in FIG. 1, a wafer may be introduced to the process chamber 104 through a wafer loading port associated with station A (at bottom left) and may then be moved to any of stations B-D by the indexer. Thus, every wafer introduced into the QSM of FIG. I would be directly placed by the external wafer handling robot into station A but would be indirectly placed into stations B-D by the indexer. Similarly, wafers from the process chamber 104 may be removed from the process chamber 104 via station D, thereby requiring each wafer to be picked to first be moved to station D by the indexer (if not already at station D) before the external wafer handling robot is able to retrieve the wafer.

In a variant of the QSM of FIG. 1, an external wafer handling robot (or two such robots) may deliver two wafers, one to station A and the other to station D, simultaneously. Both such wafers may then be moved by the indexer to stations B and C to allow another two wafers to be simultaneously delivered to stations A and D.

In yet another variant of a QSM, the QSM may have an indexer with four arms grouped into two pairs of adjacent arms, with the two pairs of arms being rotatable, and vertically translatable, relative to one another so as to allow the two pairs of arms to be shifted vertically relative to one another and then rotated relative to each other by 180°, thereby placing the ends of the arms in one pair of arms over the ends of the arms in the other pair of arms. Thus, two indexer arms may be positioned in station A and the other two indexer arms positioned in station D, all simultaneously. External wafer handling robots may then place four wafers into stations A and D at the same time, lowering them onto the waiting indexer arms. The pairs of arms may then be rotated relative to one another to move them back into a “plus” configuration and used to place the wafers at and/or move the wafers between stations A-D. Such an indexer is discussed in more detail in U.S. Pat. Pub. No. 2018/0211864, which is hereby incorporated herein by reference in its entirety.

### SUMMARY

Details of one or more implementations of the subject matter described in this specification are set forth in the accompanying drawings and the description below. Other features, aspects, and advantages will become apparent from the description, the drawings, and the claims. The implementations discussed herein include, but are not limited to, at least the implementations discussed below.

In some implementations, a system is provided that includes a base, a torso unit rotatably connected with the base such that the torso unit is rotatable relative to the base about a main rotational axis, a pair of first robot arms supported by the torso unit, and a pair of second robot arms supported by the torso unit. In such implementations, the first robot arms may each be configured to transition between at least a first retracted state, a first near-extension state, and a first far-extension state. Moreover, a first distal location of each first robot arm that is furthest from the main rotational axis when that first robot arm is in the first far-extension state may be closer to the main rotational axis when that first robot arm is in the first retracted state than when that first robot arm is in the first near-extension state, the first distal location of each first robot arm may be closer to the main rotational axis when that first robot arm is in the first near-extension state than when that first robot arm is in the first far-extension state, the second robot arms may each be configured to transition between at least a second retracted state, a second near-extension state, and a second far-extension state, a second distal location of each second robot arm that is furthest from the main rotational axis when that second robot arm is in the second far-extension state may be closer to the main rotational axis when that second robot arm is in the second retracted state than when that second robot arm is in the second near-extension state, and the second distal location of each second robot arm may be closer to the main rotational axis when that second robot arm is in the second near-extension state than when that second robot arm is in the second far-extension state.

In some such implementations, each of the first robot arms may be configured to support two wafers in an over/under configuration with one of the two wafers centered on a corresponding upper first location that is fixed with respect to a portion of that first robot arm that is configured to support the wafers and the other of the two wafers centered on a corresponding lower first location that is fixed with respect to the portion of that first robot arm that is configured to support the wafers. Furthermore, the upper first locations may each be nominally centered over different first corners of a first square region when the first robot arms are at least in one of the first near-extension state or the first far-extension state, the lower first locations may each be nominally centered over different second corners of the first square region different from the first corners of the first square region when the first robot arms are at least in the other of the first near-extension state or the first far-extension state, each of the second robot arms may be configured to support two wafers in an over/under configuration with one of the two wafers centered on a corresponding upper second location that is fixed with respect to a portion of that second robot arm that is configured to support the wafers and the other of the two wafers centered on a corresponding lower second location that is fixed with respect to the portion of that second robot arm that is configured to support the wafers, the upper second locations may each be nominally centered over different first corners of a second square region when the second robot arms are at least in one of the second near-extension state or the second far-extension state, the lower second locations may each be nominally centered over different second corners of the second square region different from the first corners of the second square region when the second robot arms are at least in the other of the second near-extension state or the second far-extension state, and the first square region and the second square region may be located in the same position and may have the same orientation and the same size.

In some such implementations, the upper first location and the lower first location for at least one of the first robot arms both lie along a corresponding common vertical axis. In some alternate or additional implementations, the upper first location and the lower first location for at least one of the first robot arms may both lie along different, non-coaxial vertical axes.

In some implementations, for each first robot arm, that first robot arm may have a corresponding first end effector support arm and a plurality of corresponding first arm links, the corresponding first arm links for that first robot arm including a corresponding first base link and one or more corresponding first intermediate arm links. Moreover, the corresponding first base link for that first robot arm may be rotatably connected with the torso unit such that the corresponding first base link for that first robot arm is rotatable relative to the torso unit about a corresponding first axis, and the corresponding first base link for that first robot arm may support the one or more corresponding first intermediate arm links and the one or more corresponding first base links for that first robot arm may support the corresponding first end effector support arm for that first robot arm. Furthermore, for each second robot arm, that second robot arm may have a corresponding second end effector support arm and a plurality of corresponding second arm links, the corresponding second arm links for that second robot arm including a corresponding second base link and one or more corresponding second intermediate arm links. Moreover, the corresponding second base link for that second robot arm may be rotatably connected with the torso unit such that the corresponding second base link for that second robot arm is rotatable relative to the torso unit about a corresponding second axis, and the corresponding second base link for that second robot arm may support the one or more corresponding second intermediate arm links and the one or more corresponding second base links for that second robot arm may support the corresponding second end effector support arm for that second robot arm. The first axes and the second axes may all be substantially parallel to one another, the first axes may be spaced apart from one another in directions perpendicular to the first axes, and the second axes may be spaced apart from one another in directions perpendicular to the second axes.

In some implementations, each first robot arm may be configured to cause the corresponding first end effector support arm for that first robot arm to translate along a corresponding translation axis relative to the torso unit responsive, at least in part, to rotation of the first base link for that first robot arm relative to the torso unit, each second robot arm may be configured to cause the corresponding second end effector support arm for that second robot arm to translate along a corresponding translation axis relative to the torso unit responsive, at least in part, to rotation of the second base link for that second robot arm relative to the torso unit, and the translation axes of the first robot arms and the second robot arms may all be substantially parallel with one another.

In some implementations, the first arm links in the plurality of corresponding first arm links for each of the first robot arms may be configured to rotate relative to one another about corresponding rotational axes substantially parallel to the first axes, the first end effector support arm for each of the first robot arms may be configured to rotate about a corresponding rotational axis relative to the corresponding first intermediate arm link of that first robot arm closest thereto (where that corresponding rotational axis is substantially parallel to the first axes), the second arm links in the plurality of corresponding second arm links for each of the second robot arms may be configured to rotate relative to one another about corresponding rotational axes substantially parallel to the second axes, and the second end effector support arm for each of the second robot arms may be configured to rotate about a corresponding rotational axis relative to the corresponding second intermediate arm link of that second robot arm closest thereto (where that corresponding rotational axis is substantially parallel to the second axes).

In some implementations, each first robot arm may have two corresponding first arm links and each second robot arm may have two corresponding second arm links.

In some such implementations, each of the first base links may have a corresponding first base link length defined by the distance between the first axis and the corresponding rotational axis about which the corresponding first intermediate arm link is configured to rotate relative to that first base link, each of the first intermediate arm links may have a corresponding first intermediate arm link length defined by the distance between the corresponding rotational axis about which that first intermediate arm link is configured to rotate relative to the corresponding first base link and the corresponding rotational axis that the corresponding first end effector support arm is configured to rotate relative to that first intermediate arm link, each of the second base links may have a corresponding second base link length defined by the distance between the second axis and the corresponding rotational axis about which the corresponding second intermediate arm link is configured to rotate relative to that second base link, each of the second intermediate arm links may have a corresponding second intermediate arm link length defined by the distance between the corresponding rotational axis about which that second intermediate arm link is configured to rotate relative to the corresponding second base link and the corresponding rotational axis that the corresponding second end effector support arm is configured to rotate relative to that second intermediate arm link, the first base link length and the first intermediate arm link length for at least one of the first robot arms may be equal, and the second base link length and the second intermediate arm link length for at least one of the second robot arms may be equal.

In some such implementations, the first base link length and the first intermediate arm link length for at least one of the first robot arms may be equal to each other, the second base link length and the second intermediate arm link length for at least one of the second robot arms may be equal to each other, and the first base link length may be longer than the second base link length.

In some implementations, the first base link length and the first intermediate arm link length for at least one of the first robot arms may be equal to each other and to the second base link length and the second intermediate arm link length for at least one of the second robot arms.

In some implementation, the first base link length and the first intermediate arm link length for both of the first robot arms may be equal, and the second base link length and the second intermediate arm link length for both of the second robot arms may be equal.

In some such implementations, the first base link length and the first intermediate arm link length for both of the first robot arms and the second base link length and the second intermediate arm link length for both of the second robot arms may all be equal.

In some such implementations, the first base link length, the second base link length, the first intermediate arm link length, and the second intermediate arm link length for a first pair of the first and second robot arms located on a common side of a reference plane of the torso unit that is coplanar with the main rotation axis and interposed between both of the first robot arms may all be the same, the first axis and the second axis of the first pair of the first and second robot arms may be coaxial, the first base link of the first robot arm of the first pair of the first and second robot arms may be fixed in space with respect to a corresponding first inner bypass portion, the first intermediate arm link of the first robot arm of the first pair of the first and second robot arms may be fixed in space with respect to a corresponding first outer bypass portion, the first inner bypass portion may include a corresponding first portion that is fixedly connected with the first base link of the first robot arm of the first pair of the first and second robot arms, a corresponding second portion that is rotatably connected with the first intermediate arm link of the first robot arm of the first pair of the first and second robot arms, and a corresponding bridging portion that spans between the corresponding first portion and the corresponding second portion of the first inner bypass portion and that is positioned such that the corresponding bridging portion of the first inner bypass portion is positioned further from the first axis of the first robot arm of the first pair of the first and second robot arms than the corresponding rotational axis about which the corresponding first intermediate arm link of the first robot arm of the first pair of the first and second robot arms is configured to rotate relative to the first base link of the first robot arm of the first pair of the first and second robot arms, the first outer bypass portion may include a corresponding first portion that is rotatably connected with the first base link of the first robot arm of the first pair of the first and second robot arms, a corresponding second portion that is fixedly connected with the first intermediate arm link of the first robot arm of the first pair of the first and second robot arms, and a corresponding bridging portion that spans between the corresponding first portion and the corresponding second portion of the first outer bypass portion and that is positioned such that the corresponding bridging portion of the first outer bypass portion is positioned further from the first axis of the first robot arm of the first pair of the first and second robot arms than the corresponding bridging portion of the first inner bypass portion when the first robot arm of the first pair of the first and second robot arms is in the first retracted state.

In some such implementations, the first base link length, the second base link length, the first intermediate arm link length, and the second intermediate arm link length for a second pair of the first and second robot arms located on an opposite side of the reference plane of the torso unit may all be the same, the first axis and the second axis of the second pair of the first and second robot arms may be coaxial, the first base link of the first robot arm of the second pair of the first and second robot arms may be fixed in space with respect to a corresponding second inner bypass portion, the first intermediate arm link of the first robot arm of the second pair of the first and second robot arms may be fixed in space with respect to a corresponding second outer bypass portion, the second inner bypass portion may include a corresponding first portion that is fixedly connected with the first base link of the first robot arm of the second pair of the first and second robot arms, a corresponding second portion that is rotatably connected with the first intermediate arm link of the first robot arm of the second pair of the first and second robot arms, and a corresponding bridging portion that spans between the corresponding first portion and the corresponding second portion of the second inner bypass portion and that is positioned such that the corresponding bridging portion of the second inner bypass portion is positioned further from the first axis of the first robot arm of the second pair of the first and second robot arms than the corresponding rotational axis about which the corresponding first intermediate arm link of the first robot arm of the second pair of the first and second robot arms is configured to rotate relative to the first base link of the first robot arm of the second pair of the first and second robot arms, and the second outer bypass portion may include a corresponding first portion that is rotatably connected with the first base link of the first robot arm of the second pair of the first and second robot arms, a corresponding second portion that is fixedly connected with the first intermediate arm link of the first robot arm of the second pair of the first and second robot arms, and a corresponding bridging portion that spans between the corresponding first portion and the corresponding second portion of the second outer bypass portion and that is positioned such that the corresponding bridging portion of the second outer bypass portion is positioned further from the first axis of the first robot arm of the second pair of the first and second robot arms than the corresponding bridging portion of the second inner bypass portion when the first robot arm of the second pair of the first and second robot arms is in the first retracted state.

In some such implementations, the first pair of first and second robot arms and the second pair of first and second robot arms may be arranged symmetrically with respect to the reference plane.

In some implementations, the first axes may be spaced apart by a distance that is different than a distance that the second axes are spaced apart by.

In some implementations, the first end effector support arms may each have a corresponding first portion, a corresponding second portion, and a corresponding offset jog portion. The corresponding first portion and the corresponding second portion of each of the first end effector support arms may extend along parallel axes that are offset from one another in a direction perpendicular to those parallel axes, and the corresponding offset jog portion of each of the first end effector support arms may span between the corresponding first portion and the corresponding second portion of that first end effector support arm.

In some implementations, the second end effector support arms may each have a corresponding first portion, a corresponding second portion, and a corresponding offset jog portion. The corresponding first portion and the corresponding second portion of each of the second end effector support arms may extend along parallel axes that are offset from one another in a direction perpendicular to those parallel axes, and the corresponding offset jog portion of each of the second end effector support arms may span between the corresponding first portion and the corresponding second portion of that second end effector support arm.

In some implementations, the base may be fixedly mounted with respect to the transfer chamber, the torso unit may be located at least partially within the transfer chamber, the first robot arms may be located entirely within the transfer chamber when in the first retracted state, the second robot arms may be located entirely within the transfer chamber when in the second retracted state, and the torso unit, along with the first robot arms and the second robot arms, may be rotatable by at least 90° within and relative to the transfer chamber when the first robot arms are in the first retracted state and the second robot arms are in the second retracted state.

In some implementations, the system may also include one or more multi-station processing chambers. Each multi-station processing chamber may be connected with the transfer chamber by one or more corresponding wafer transfer passages, each multi-station processing chamber may have a corresponding pair of near pedestals that are closer to the transfer chamber and a corresponding pair of far pedestals that are farther from the transfer chamber, the first robot arms may be configured to transfer wafers to the corresponding pair of near pedestals of each of the multi-station processing chambers when the torso unit is rotated to align the first robot arms with the one or more corresponding wafer transfer passages of that multi-station processing chamber and the first robot arms are in the first near-extension state, the first robot arms may be configured to transfer wafers to the corresponding pair of far pedestals of each of the multi-station processing chambers when the torso unit is rotated to align the first robot arms with the one or more corresponding wafer transfer passages of that multi-station processing chamber and the first robot arms are in the first far-extension state, the second robot arms may be configured to transfer wafers to the corresponding pair of near pedestals of each of the multi-station processing chambers when the torso unit is rotated to align the second robot arms with the one or more corresponding wafer transfer passages of that multi-station processing chamber and the second robot arms are in the second near-extension state, and the second robot arms may be configured to transfer wafers to the corresponding pair of far pedestals of each of the multi-station processing chambers when the torso unit is rotated to align the second robot arms with the one or more corresponding wafer transfer passages of that multi-station processing chamber and the second robot arms are in the second far-extension state.

In some such implementations, each multi-station processing chamber may be a quad-station module.

In some implementations, the system may further include one or more active wafer centering sensor systems, each configured to obtain center location measurements of wafers transported through one of the wafer transfer passages by the first robot arms and/or the second robot arms.

In some implementations, the system may further include a controller having one or more memory devices and one or more processors, the one or more memory devices storing computer-executable instructions which, when executed by the one or more processors, cause the one or more processors to cause: a) the first robot arms to transition from the first retracted state to the first far-extension state while each supporting a pair of wafers, b) the first robot arms to remain in the first far-extension state while bottom wafers supported by the first robot arms are lifted off of the first robot arms, c) the first robot arms to transition from the first far-extension state to the first near-extension state after (b) and while each supporting the wafer of the pair of wafers supported by that first robot arm that was not removed in (b), d) the first robot arms to remain in the first near-extension state while upper wafers supported by the first robot arms are lifted off of the first robot arms, and e) the first robot arms to transition from the first near-extension state to the first retracted state after (d) and while each supporting no wafer.

In some such implementations, the one or more memory devices may further store computer-executable instructions which, when executed by the one or more processors, cause the one or more processors to cause, sequentially, the torso unit to rotate, at least one of the first robot arms to extend or retract, or the torso unit to rotate and the at least one of the first robot arms to extend or retract so as to center one of the wafers lifted off the first robot arms during (b) on a first far target location prior to lifting that wafer off of the first robot arm supporting that wafer at the start of (b), and the torso unit to rotate, at least the other of the first robot arms to extend or retract, or the torso unit to rotate and the at least the other of the first robot arms to extend or retract so as to center the other of the wafers lifted off the first robot arms during (b) on a second far target location prior to lifting that wafer off of the first robot arm supporting that wafer at the start of (b).

In some implementations, the one or more memory devices may further store computer-executable instructions which, when executed by the one or more processors, cause the one or more processors to cause, at least partially simultaneously, one of the first robot arms to adjust an amount of extension thereof, an amount of rotation thereof relative to the torso unit, or an amount of extension thereof and an amount of rotation thereof relative to the torso unit so as to center one of the wafers lifted off the first robot arms during (b) on a first far target location prior to lifting that wafer off of the first robot arm supporting that wafer at the start of (b), and the other of the first robot arms to adjust an amount of extension thereof, an amount of rotation thereof relative to the torso unit, or an amount of extension thereof and an amount of rotation thereof relative to the torso unit so as to center the other of the wafers lifted off the first robot arms during (b) on a second far target location prior to lifting that wafer off of the first robot arm supporting that wafer at the start of (b).

In some implementations, the one or more memory devices may further store computer-executable instructions which, when executed by the one or more processors, cause the one or more processors to cause, at least partially simultaneously, one of the first robot arms to adjust an amount of extension thereof, an amount of rotation thereof relative to the torso unit, or an amount of extension thereof and an amount of rotation thereof relative to the torso unit so as to center one of the wafers lifted off the first robot arms during (b) on a first far target location prior to lifting that wafer off of the first robot arm supporting that wafer at the start of (b), and the torso unit to rotate, at least the other of the first robot arms to extend or retract, or the torso unit to rotate and the at least the other of the first robot arms to extend or retract so as to center the other of the wafers lifted off the first robot arms during (b) on a second far target location prior to lifting that wafer off of the first robot arm supporting that wafer at the start of (b).

In some implementations, the one or more memory devices may further store computer-executable instructions which, when executed by the one or more processors, cause the one or more processors to cause f) the first robot arms to transition from the first retracted state to the first near-extension state while each supporting no wafers, g) the first robot arms to remain in the first near-extension state while each of the first robot arms has a corresponding wafer placed thereupon, h) the first robot arms to transition from the first near-extension state to the first far-extension state after (g) and while each supports the single wafer placed thereupon in (g), i) the first robot arms to remain in the first far-extension state while each of the first robot arms has another wafer placed thereupon and in a location beneath the wafer already supported by that first robot arm, and j) the first robot arms to transition from the first far-extension state to the first retracted state after (i) and while each supporting the two wafers placed thereupon.

In some implementations, the one or more memory devices may further store computer-executable instructions which, when executed by the one or more processors, cause the one or more processors to cause: 1) the second robot arms to transition from the second retracted state to the second far-extension state while each supporting a pair of wafers, 2) the second robot arms to remain in the second far-extension state while bottom wafers supported by the second robot arms are lifted off of the second robot arms, 3) the second robot arms to transition from the second far-extension state to the second near-extension state after (2) and while each supporting the wafer of the pair of wafers supported by that second robot arm that was not removed in (2), 4) the second robot arms to remain in the second near-extension state while upper wafers supported by the second robot arms are lifted off of the second robot arms, and 5) the second robot arms to transition from the second near-extension state to the second retracted state after (4) and while each supporting no wafer.

In some implementations, the one or more memory devices may further store computer-executable instructions which, when executed by the one or more processors, cause the one or more processors to cause, sequentially, the torso unit to rotate, at least one of the second robot arms to extend or retract, or the torso unit to rotate and the at least one of the second robot arms to extend or retract so as to center one of the wafers lifted off the second robot arms during (2) on a first far target location prior to lifting that wafer off of the second robot arm supporting that wafer at the start of (2), and the torso unit to rotate, at least the other of the second robot arms to extend or retract, or the torso unit to rotate and the at least the other of the second robot arms to extend or retract so as to center the other of the wafers lifted off the second robot arms during (2) on a second far target location prior to lifting that wafer off of the second robot arm supporting that wafer at the start of (2).

In some implementations, the one or more memory devices may further store computer-executable instructions which, when executed by the one or more processors, cause the one or more processors to cause, at least partially simultaneously, one of the second robot arms to adjust an amount of extension thereof, an amount of rotation thereof relative to the torso unit, or an amount of extension thereof and an amount of rotation thereof relative to the torso unit so as to center one of the wafers lifted off the second robot arms during (2) on a first far target location prior to lifting that wafer off of the second robot arm supporting that wafer at the start of (2), and the other of the second robot arms to adjust an amount of extension thereof, an amount of rotation thereof relative to the torso unit, or an amount of extension thereof and an amount of rotation thereof relative to the torso unit so as to center the other of the wafers lifted off the second robot arms during (2) on a second far target location prior to lifting that wafer off of the second robot arm supporting that wafer at the start of (2).

In some implementations, the one or more memory devices may further store computer-executable instructions which, when executed by the one or more processors, cause the one or more processors to cause, at least partially simultaneously, one of the second robot arms to adjust an amount of extension thereof, an amount of rotation thereof relative to the torso unit, or an amount of extension thereof and an amount of rotation thereof relative to the torso unit so as to center one of the wafers lifted off the second robot arms during (2) on a first far target location prior to lifting that wafer off of the second robot arm supporting that wafer at the start of (2), and the torso unit to rotate, at least the other of the second robot arms to extend or retract, or the torso unit to rotate and the at least the other of the second robot arms to extend or retract so as to center the other of the wafers lifted off the second robot arms during (2) on a second far target location prior to lifting that wafer off of the second robot arm supporting that wafer at the start of (2).

In some implementations, the one or more memory devices may further store computer-executable instructions which, when executed by the one or more processors, cause the one or more processors to cause 6) the second robot arms to transition from the second retracted state to the second near-extension state while each supporting no wafers, 7) the second robot arms to remain in the second near-extension state while each of the second robot arms has a corresponding wafer placed thereupon. 8) the second robot arms to transition from the second near-extension state to the second far-extension state after (7) and while each supports the single wafer placed thereupon in (7), 9) the second robot arms to remain in the second far-extension state while each of the second robot arms has another wafer placed thereupon and in a location beneath the wafer already supported by that second robot arm, and 10) the second robot arms to transition from the second far-extension state to the second retracted state after (9) and while each supporting the two wafers placed thereupon.

In some implementations, a system may be provided that includes a base, a torso unit rotatably connected with the base such that the torso unit is rotatable relative to the base about a main rotational axis, and a pair of robot arms supported by the torso unit. The robot arms may each be configured to transition between at least a retracted state, a near-extension state, and a far-extension state, a distal location of each robot arm that is furthest from the main rotational axis when that robot arm is in the far-extension state may be closer to the main rotational axis when that robot arm is in the retracted state than when that robot arm is in the near-extension state, and the distal location of each robot arm may be closer to the main rotational axis when that robot arm is in the near-extension state than when that robot arm is in the far-extension state.

In some such implementations, each of the robot arms may be configured to support two wafers in an over/under configuration with one of the two wafers centered on a corresponding upper location that is fixed with respect to a portion of that robot arm that is configured to support the wafers and the other of the two wafers centered on a corresponding lower location that is fixed with respect to the portion of that robot arm that is configured to support the wafers, the upper locations may each be nominally centered over different first corners of a square region when the robot arms are at least in one of the near-extension state or the far-extension state, and the lower locations may each be nominally centered over different second corners of the square region different from the first corners of the square region when the robot arms are at least in the other of the near-extension state or the far-extension state.

In some implementations, the upper location and the lower location for at least one of the robot arms may both lie along a corresponding common vertical axis. In some other or additional implementations, the upper location and the lower location for at least one of the robot arms may both lie along different, non-coaxial vertical axes.

In some implementations, for each robot arm, that robot arm may have a corresponding end effector support arm and a plurality of corresponding arm links, the corresponding arm links for that robot arm including a corresponding base link and one or more corresponding intermediate arm links, the corresponding base link for that robot arm may be rotatably connected with the torso unit such that the corresponding base link for that robot arm is rotatable relative to the torso unit about a corresponding first axis, and the corresponding base link for that robot arm may support the one or more corresponding intermediate arm links and the one or more corresponding base links for that robot arm may support the corresponding end effector support arm for that robot arm. In such implementations, the first axes may be substantially parallel to one another and spaced apart from one another in directions perpendicular to the first axes.

In some implementations, each robot arm may be configured to cause the corresponding end effector support arm for that robot arm to translate along a corresponding translation axis relative to the torso unit responsive, at least in part, to rotation of the base link for that robot arm relative to the torso unit, and the translation axes of the robot arms may be substantially parallel with one another.

In some implementations, the arm links in the plurality of corresponding arm links for each of the robot arms may be configured to rotate relative to one another about corresponding rotational axes substantially parallel to the first axes, and the end effector support arm for each of the robot arms may be configured to rotate about a corresponding rotational axis relative to the corresponding intermediate arm link of that robot arm closest thereto (where that corresponding rotational axis is substantially parallel to the first axes).

In some implementations, each robot arm may have two corresponding arm links.

In some implementations, each of the base links may have a corresponding base link length defined by the distance between the first axis and the corresponding rotational axis about which the corresponding intermediate arm link is configured to rotate relative to that base link, each of the intermediate arm links may have a corresponding intermediate arm link length defined by the distance between the corresponding rotational axis about which that intermediate arm link is configured to rotate relative to the corresponding base link and the corresponding rotational axis that the corresponding end effector support arm is configured to rotate relative to that intermediate arm link, and the base link lengths and the intermediate arm link lengths may be equal.

In some implementations, the robot arms may be arranged symmetrically with respect to a reference plane.

In some implementations, the end effector support arms may each have a corresponding first portion, a corresponding second portion, and a corresponding offset jog portion. The corresponding first portion and the corresponding second portion of each of the end effector support arms may extend along parallel axes that are offset from one another in a direction perpendicular to those parallel axes, and the corresponding offset jog portion of each of the end effector support arms may span between the corresponding first portion and the corresponding second portion of that end effector support arm.

In some implementations, the system may further include a transfer chamber. The base may be fixedly mounted with respect to the transfer chamber, the torso unit may be located at least partially within the transfer chamber, the robot arms may be located entirely within the transfer chamber when in the retracted state, and the torso unit, along with the robot arms, may be rotatable by at least 90° within and relative to the transfer chamber when the robot arms are in the retracted state.

In some implementations, the system may further include one or more multi-station processing chambers. Each multi-station processing chamber may be connected with the transfer chamber by one or more corresponding wafer transfer passages, each multi-station processing chamber may have a corresponding pair of near pedestals that are closer to the transfer chamber and a corresponding pair of far pedestals that are farther from the transfer chamber, the robot arms may be configured to transfer wafers to the corresponding pair of near pedestals of each of the multi-station processing chambers when the torso unit is rotated to align the robot arms with the one or more corresponding wafer transfer passages of that multi-station processing chamber and the robot arms are in the near-extension state, and the robot arms may be configured to transfer wafers to the corresponding pair of far pedestals of each of the multi-station processing chambers when the torso unit is rotated to align the robot arms with the one or more corresponding wafer transfer passages of that multi-station processing chamber and the robot arms are in the far-extension state.

In some such implementations, each multi-station processing chamber may be a quad-station module.

In some implementations, the system may further include one or more active wafer centering sensor systems, each configured to obtain center location measurements of wafers transported through one of the wafer transfer passages by the robot arms.

In some implementations, the system may further include a controller having one or more memory devices and one or more processors, the one or more memory devices storing computer-executable instructions which, when executed by the one or more processors, cause the one or more processors to cause: a) the robot arms to transition from the retracted state to the far-extension state while each supporting a pair of wafers, b) the robot arms to remain in the far-extension state while bottom wafers supported by the robot arms are lifted off of the robot arms, c) the robot arms to transition from the far-extension state to the near-extension state after (b) and while each supporting the wafer of the pair of wafers supported by that robot arm that was not removed in (b), d) the robot arms to remain in the near-extension state while upper wafers supported by the robot arms are lifted off of the robot arms, and e) the robot arms to transition from the near-extension state to the retracted state after (d) and while each supporting no wafer.

In some implementations, the one or more memory devices may further store computer-executable instructions which, when executed by the one or more processors, cause the one or more processors to cause, sequentially, the torso unit to rotate, at least one of the robot arms to extend or retract, or the torso unit to rotate and the at least one of the robot arms to extend or retract so as to center one of the wafers lifted off the robot arms during (b) on a first far target location prior to lifting that wafer off of the robot arm supporting that wafer at the start of (b), and the torso unit to rotate, at least the other of the robot arms to extend or retract, or the torso unit to rotate and the at least the other of the robot arms to extend or retract so as to center the other of the wafers lifted off the robot arms during (b) on a second far target location prior to lifting that wafer off of the robot arm supporting that wafer at the start of (b).

In some implementations, the one or more memory devices may further store computer-executable instructions which, when executed by the one or more processors, cause the one or more processors to cause, at least partially simultaneously, one of the robot arms to adjust an amount of extension thereof, an amount of rotation thereof relative to the torso unit, or an amount of extension thereof and an amount of rotation thereof relative to the torso unit so as to center one of the wafers lifted off the robot arms during (b) on a first far target location prior to lifting that wafer off of the robot arm supporting that wafer at the start of (b), and the other of the robot arms to adjust an amount of extension thereof, an amount of rotation thereof relative to the torso unit, or an amount of extension thereof and an amount of rotation thereof relative to the torso unit so as to center the other of the wafers lifted off the robot arms during (b) on a second far target location prior to lifting that wafer off of the robot arm supporting that wafer at the start of (b).

In some implementations, the one or more memory devices may further store computer-executable instructions which, when executed by the one or more processors, cause the one or more processors to cause, at least partially simultaneously, one of the robot arms to adjust an amount of extension thereof, an amount of rotation thereof relative to the torso unit, or an amount of extension thereof and an amount of rotation thereof relative to the torso unit so as to center one of the wafers lifted off the robot arms during (b) on a first far target location prior to lifting that wafer off of the robot arm supporting that wafer at the start of (b), and the torso unit to rotate, at least the other of the robot arms to extend or retract, or the torso unit to rotate and the at least the other of the robot arms to extend or retract so as to center the other of the wafers lifted off the robot arms during (b) on a second far target location prior to lifting that wafer off of the robot arm supporting that wafer at the start of (b).

In some implementations, the one or more memory devices may further store computer-executable instructions which, when executed by the one or more processors, cause the one or more processors to cause f) the robot arms to transition from the retracted state to the near-extension state while each supporting no wafers, g) the robot arms to remain in the near-extension state while each of the robot arms has a corresponding wafer placed thereupon, h) the robot arms to transition from the near-extension state to the far-extension state after (g) and while each supports the single wafer placed thereupon in (g), i) the robot arms to remain in the far-extension state while each of the robot arms has another wafer placed thereupon and in a location beneath the wafer already supported by that robot arm, and j) the robot arms to transition from the far-extension state to the retracted state after (i) and while each supporting the two wafers placed thereupon.

In addition to the above-listed implementations, other implementations evident from the discussion below and the Figures are to be understood to also fall within the scope of this disclosure.

### BRIEF DESCRIPTION OF THE FIGURES

Reference to the following Figures is made in the discussion below: the Figures are not intended to be limiting in scope and are simply provided to facilitate the discussion below.

FIG. 1 depicts a schematic of an example QSM.

FIGS. 2 through 4 depict overhead views of a semiconductor processing tool that features a transfer chamber that is connected on three sides with three different processing chambers.

FIGS. 5-7 depict an example robot arm system in various states of extension.

FIG. 8 depicts an isometric view of a transfer chamber and QSM with a robot arm system having horizontally staggered over/under wafer support locations.

FIG. 9 depicts the same transfer chamber and QSM as in FIG. 8 with the left two wafers raised up off the end effector that supports them to permit the end effector to be seen.

FIG. 10 shows a top view of two horizontally offset wafers just prior to being passed through a wafer load slot.

FIG. 11 depicts an enlarged detail view of an example end effector configured to carry two wafers in a horizontally staggered, over/under configuration.

FIG. 12 depicts an enlarged detail view of an example end effector configured to carry two wafers in a horizontally aligned over/under configuration.

FIGS. 13 and 14 depict front and side views of the robot arm system of FIG. 5.

FIGS. 15 and 16 depict isometric views of the robot arm system of FIG. 5.

FIG. 17 depicts a cutaway schematic representation of an example robot arm system.

FIG. 18 depicts another cutaway schematic representation of another example robot arm system.

FIG. 19 depicts a plan view of a robot arm system similar to that diagrammed in FIG. 18.

FIG. 20 depicts a plan view diagram of an example robot arm system having first robot arms and second robot arms in which the first axes are not coaxial with the second axes.

FIG. 21 depicts a plan view diagram of another example robot arm system having first robot arms and second robot arms in which the first axes are coaxial with the second axes but the first and second robot arms unequal in length.

FIG. 22 depicts a schematic of optical sensors for an active wafer centering (AWC) system that may be used to obtain individual wafer center measurements relative to an end effector for a configuration of two wafers supported in a stacked arrangement.

FIGS. 23 through 44 depict isometric views of an example semiconductor processing tool that includes a transfer chamber and processing chamber during different stages of robot arm system operation.

FIG. 45 depicts an isometric view of an example robot arm system with a single pair of robot arms.

FIG. 46 depicts a cutaway schematic representation of an example robot arm system with a single pair of robot arms.

FIG. 47 depicts another cutaway schematic representation of another example robot arm system with a single pair of robot arms.

FIG. 48 depicts a plan view of a robot arm system similar to that diagrammed in FIG. 47.

FIG. 49 shows two top views of an example robot arm system in a transfer chamber adjacent to a QSM.

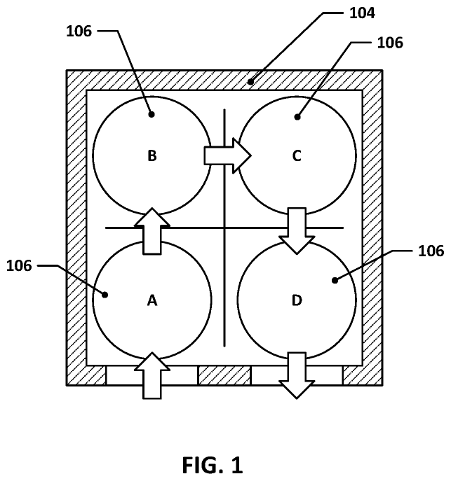

The above-described Figures are provided to facilitate understanding of the concepts discussed in this disclosure, and are intended to be illustrative of some implementations that fall within the scope of this disclosure, but are not intended to be limiting—implementations consistent with this disclosure and which are not depicted in the Figures are still considered to be within the scope of this disclosure.

### DETAILED DESCRIPTION

Disclosed herein are new wafer handling robot systems that allow for a plurality, e.g., four, wafers to be directly placed in different stations of a multi-station processing chamber, e.g., a quad-station module (QSM). In some implementations, the wafer handling robot system provides two pairs of robot arms, with the robot arms of each pair of robot arms mounted to a common torso unit that is able to rotate relative to the multi-station processing chamber. Each robot arm of the two pairs of robot arms is able to transition between three states relative to the torso unit—a retracted state, a near-extension state, and a far-extension state. When all of the robot arms of the wafer handling robot system are in their respective retracted states, the torso unit may be able to be rotated within, for example, a transfer chamber that may house the wafer handling robot system without collision of the wafer handling robot or wafers supported thereby with the transfer chamber (or other equipment). In some additional implementations of the wafer handling robot system, only a single pair of opposing robot arms may be mounted to a common torso unit; such wafer handling robot systems may have reduced throughput capacity as compared with implementations that include two pairs of robot arms, but may be less expensive and may, in certain contexts, offer no actual throughput penalty.

The transfer chamber may be connected, either directly or indirectly, with one or more processing chambers, e.g., QSMs, load locks or load ports, etc, that may receive and/or supply wafers to the wafer handling robot system. For example, in a generally square transfer chamber, each of three of the sides of the transfer chamber may be connected with a different processing chamber, each of which is a QSM. The fourth side of the transfer chamber may, for example, be connected with load locks or another other chamber or chambers from which wafers may initially be supplied to the transfer chamber or removed therefrom. The torso unit may be able to be nominally rotated to each of four different rotational positions, each allowing the robot arms mounted thereto to extend into (and later retract from) a corresponding one of the different processing chambers or other chamber(s). In the case of multi-station chambers, such as are found in QSMs, the stations and pedestals therewithin may be arranged in a circular or square pattern, with two of the stations and/or pedestals being located closer to the transfer chamber than the remaining two stations and/or pedestals. The two pedestals or stations of a QSM that are closer to the transfer chamber may be referred to herein as the “near” pedestals or stations, while the two pedestals or stations that are farther from the transfer chamber may be referred to herein as the “far” pedestals or stations.

When the torso unit is rotated so as to align with one of the processing chambers, the robot arms of the wafer handling robot system may be positioned such that they may be caused to transition into the near-extension state or the far-extension state without colliding with, for example, the walls of the processing chambers or transfer chamber.

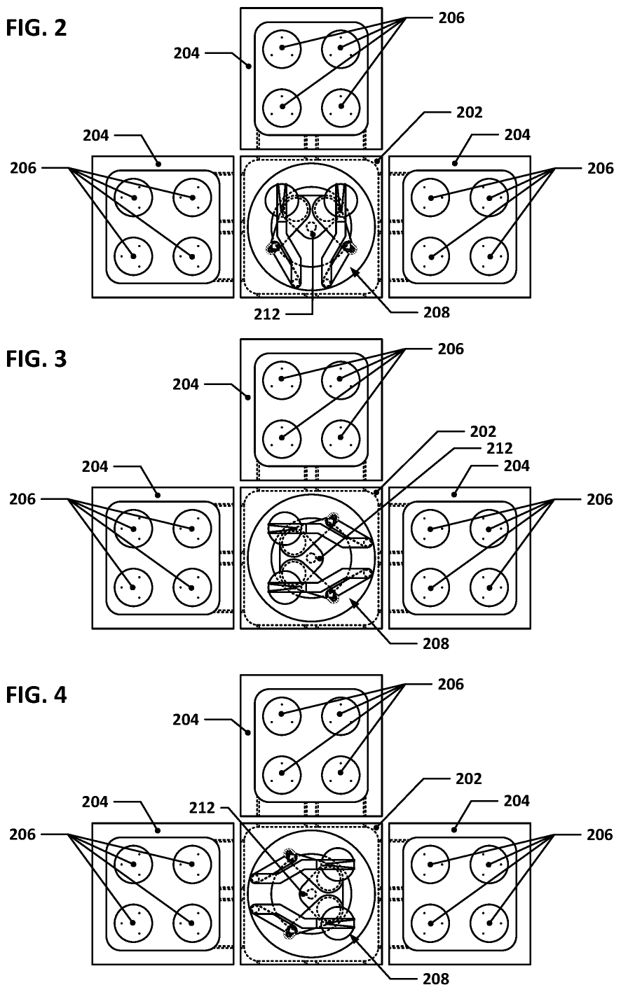

FIGS. 2 through 4 depict overhead views of a semiconductor processing tool that features a transfer chamber 202 that is connected on three sides with three different processing chambers 204 (the processing chambers 204 and the transfer chamber 202 are shown with gaps in between them, although in actual practice such chambers would be butted up against each other or the gaps filled with other equipment, e.g., slit valves to allow the processing chambers 204 to be sealed off from the transfer chamber 202). Each processing chamber 204 is a four-station QSM with each station having a corresponding pedestal 206. As can be seen, in the middle of the transfer chamber 202 is located a wafer handling robot system 208 with a torso unit 212 that can be rotated about an axis so as to face towards the middle process chamber (FIG. 2), the left process chamber (FIG. 3), or the right process chamber (FIG. 4).

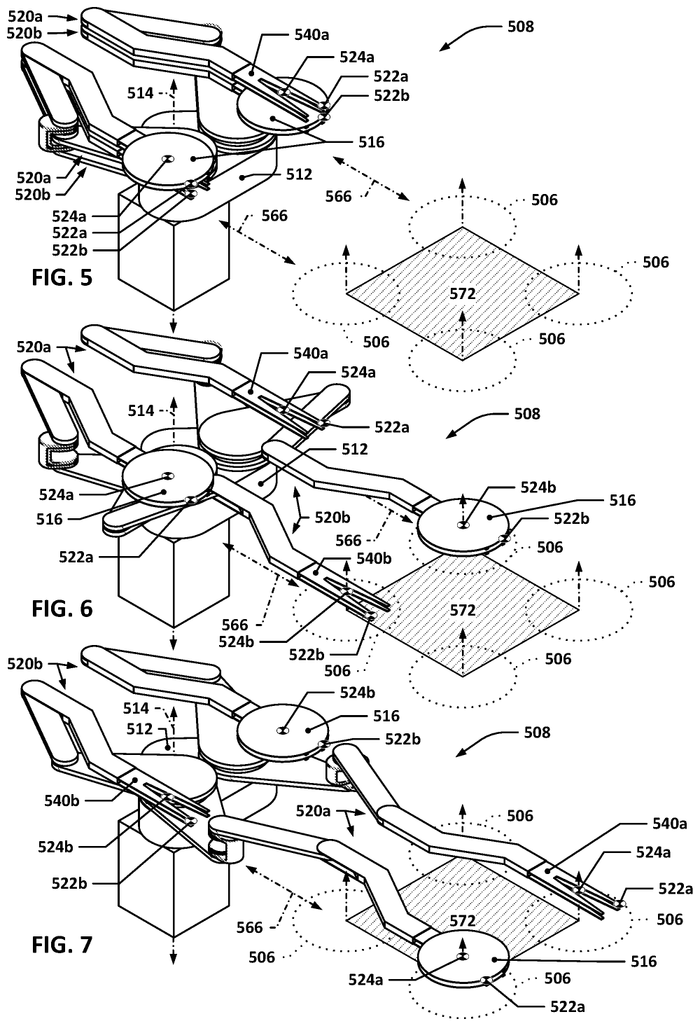

FIGS. 5-7 depict an example robot arm system 508 in various states of extension; the depicted example robot arm system 508 is one with two pairs of robot arms. FIG. 5 depicts the robot arm system 508 with both pairs of first and second robot arms 520a/b in the retracted state. FIG. 6 depicts the robot arm system 508 with the pair of first robot arms 520a in the retracted state and the pair of second robot arms 520b in the near-extension state. FIG. 7 depicts the robot arm system 508 with the pair of first robot arms 520a in the far-extension state and the pair of second robot arms 520b in the retracted state. It will be understood that both pairs of first and second robot arms may be transitioned between all three states.

FIGS. 5-7 also depict a square region 572 that has corners that are nominally coincident with the center points of pedestals 506 (or target points on such pedestals 506 where wafers 516 are to nominally be centered), e.g., as may be the case in a multi-station chamber that is a QSM. The target points, which may also be referred to as target locations, may be divided into near target points or locations (for the near pedestals 506) and far target points or locations (for the far pedestals 506).

Each of the first robot arms 520a and second robot arms 520b may have a portion thereof, e.g., first end effectors 540a and second end effectors 540b, respectively, that is configured to support a pair of the wafers 516 during wafer transport. Each such portion of the first robot arms 520a and the second robot arms 520b may, respectively, have a corresponding first location 524a or a second location 524b associated therewith that corresponds with the location where wafers placed thereupon are nominally centered; the first locations 524a and the second locations 524b, respectively, are fixed in space relative to the corresponding portions of the first robot arms 520a and the second robot arms 520b, respectively, with which each is associated. It will be understood that each first location 524a may be thought of as including both an upper first location 524a and a lower first location 524a, with the upper first location 524a representing a location over which the upper wafer 516 supported by the first end effector 540a is nominally centered during wafer transport by the first end effector 540a, and the lower first location 524a representing a location over which the lower or bottom wafer 516 supported by the first end effector 540a is nominally centered during wafer transport by the first end effector 540a. In the depicted implementation, the upper and lower first locations 524a are centered on each other when viewed from above, but in other implementations, e.g., where wafers 516 are carried in a horizontally staggered or offset over/under configuration, the upper and lower first locations 524a may not be centered on each other when viewed from above, e.g., vertical axes passing through the upper and lower first locations 524a may not be coaxial with each other.

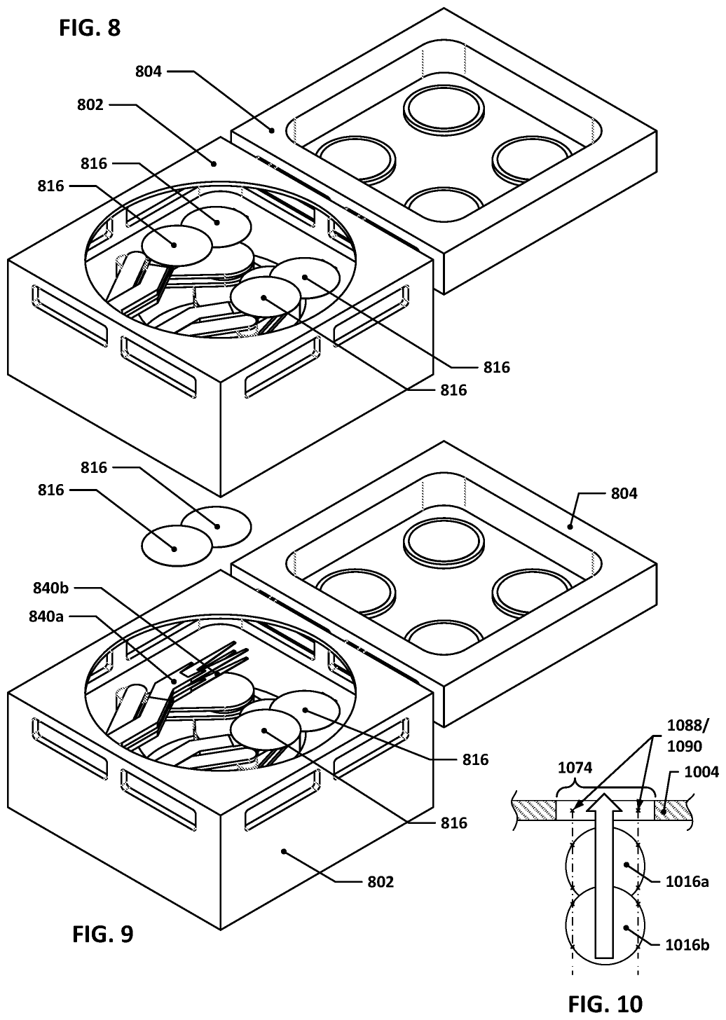

FIG. 8 depicts an isometric view of a transfer chamber and QSM with a robot arm system having horizontally staggered over/under wafer support locations. FIG. 9 depicts the same transfer chamber and QSM with the left two wafers raised up off the end effector that supports them to permit the end effector to be seen. As can be seen in FIGS. 8, a process chamber 804 and a transfer chamber 802 are shown: a robot arm system—similar to that discussed above with respect to FIGS. 5-7, is housed within the transfer chamber 802 and may be controlled so as to transport wafers 816 into and out of the process chamber 804. In FIG. 9, the leftmost wafers 816 supported by the robot arm system have been moved upward to allow end effectors 840a and 840b to be seen.

As can be seen in the schematic of FIG. 10, which shows a top view of two horizontally offset wafers just prior to being passed through a wafer load slot 1074 of a process chamber 1004 (which may be a QSM or other multi-station chamber). The wafer load slot may be equipped with, or have located nearby, optical sensors of an AWC system. In FIG. 10, the two x's labeled 1088 and 1090 represent the locations of optical beam emitter and receiver pairs of the AWC system; the optical emitters 1088 and the optical receivers 1090 may be configured to detect when an object, such as a wafer, blocks a vertically oriented line of sight of the optical receiver 1090 (for the purposes of FIG. 10, such a vertical line of sight may be understood to be perpendicular to the page).

By horizontally staggering the wafers on the end effector, wafer 1016a and wafer 1016b may transit through the wafer load slot 1074 such that the edges of the wafers 1016a and 1016b that cross the vertical lines of sight of the optical receivers in two separate groups, with the edge/optical line of sight intersections for both wafers 1016a and 1016b not being intermingled with those of the other wafer 1016a or 1016b. Such an arrangement may allow for single-beam optical sensors of an AWC system (as opposed to those discussed with respect to FIG. 34) to be used to sequentially obtain center location measurements for both wafers supported by the end effector since such beam sensors may be spaced apart such that four points along the edge of the leading wafer may cross through the beam sensors before four points along the edge of the trailing wafer, thereby allowing the center of each wafer to be determined without worry of which wafer edge is triggering the AWC sensor. Such measured center locations may then be used by the AWC to guide centering of each wafer on a respective pedestal or wafer support within the chamber.

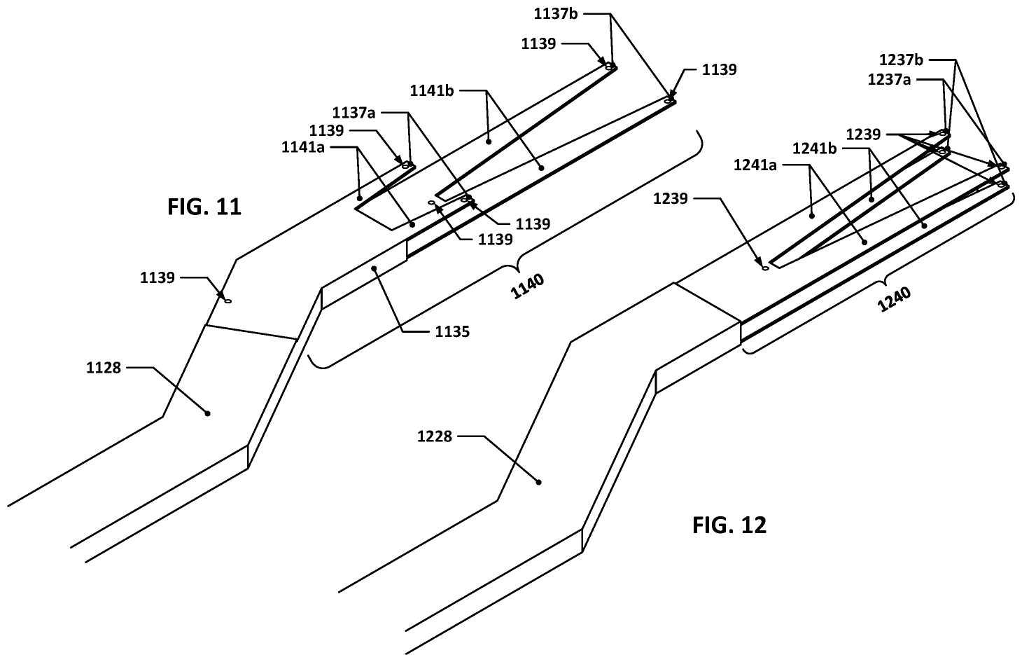

FIG. 11 depicts an enlarged detail view of an example end effector configured to carry two wafers in a horizontally staggered, over/under configuration. The example end effector 1140 includes a base 1135 from which two sets of blades 1141a and 1141b extend. The base 1135 may be supported by an end effector support arm 1128. The respective tips 1137a and 1137b of the blades 1141a and 1141b may be positioned at different distances from the base 1135. Both sets of blades 1141a and 1141b may feature a plurality of contact pads 1139 or similar features that may serve as contact locations for supporting a wafer supported by the end effector. As is evident, one of the contact pads 1139 for the upper portion of the end effector 1140 is located on the base 1135, thereby allowing the wafer supported thereby to be positioned at least partially over the base 1135. This allows the blades 1141a (the upper blades) to extend from the base 1135 to a much lesser extent than the blades 1141b, thereby providing the horizontal offset noted above.

FIG. 12 depicts an enlarged detail view of an example end effector configured to carry two wafers in a horizontally aligned over/under configuration (similar to that shown in FIGS. 5-7). The example end effector 1240 includes a base (provided, in this case, by end effector support arm 1228) from which two sets of blades 1241a and 1241b extend. The respective tips 1237a and 1237b of the blades 1241a and 1241b may be positioned at the generally the same distance from the base (although not necessarily—however, both sets of blades may be configured to support the wafers in the same horizontal location such that they are horizontally aligned). Both sets of blades 1241a and 1241b may feature a plurality of contact pads 1239 or similar features that may serve as contact locations for supporting a wafer supported by the end effector. This configuration allows the blades 1241a and the blades 1241b to simultaneously support wafers in a horizontally aligned over/under configuration.

Returning to FIGS. 5-7, it will be further understood that each second location may similarly include both an upper second location 524b and a lower second location 524b that may be analogous to the upper and lower first locations 524a. In view of the fact that each first end effector 540a of the present example (and later examples discussed herein) has upper and lower first locations 524a centered on one another when viewed from above, and the fact that each second end effector 540b of the present example (and later examples discussed herein) has upper and lower second locations 524b centered on one another when viewed from above, the first locations 524a are simply referred to as first locations 524a without any special distinction between the upper and lower instances thereof. Similarly, the second locations 524b are simply referred to as second locations 524b without any special distinction between the upper and lower instances thereof.

In FIGS. 5-7, a pair of wafers 516 is shown being supported on the first end effector 540a of the left first robot arm 520a and another pair of wafers 516 is shown being supported on the second end effector 540b of the right second robot arm 520b; this is simply for illustrative purposes so that in each of the near- and far-extension states depicted in FIGS. 6 and 7, the relevant extension state is shown with a robot arm in each of the wafer-loaded and wafer-unloaded states.

Each first end effector 540a and second end effector 540b may have a corresponding first location 524a and second location 524b, respectively, that is fixed with respect to that first end effector 540a or second end effector 540b, respectively, and which is nominally centered over or under a wafer or wafers 516 supported on that first end effector 540a or second end effector 540b when that first end effector 540a or second end effector 540b is used to transport such wafers 516 during normal use. In other words, the corresponding first location 524a for each first end effector 540a is the nominal target point where wafers 516 to be transported by that first end effector 540a are to be centered over or under; it will be appreciated that such first locations 524a do not necessarily correspond to any physically observable features on the first end effectors 540a and may, in some cases, actually be located such that they do not overlap with the first end effectors 540a at all (for example, some blade-type end effectors such as those shown may have the shape of a flat plate with a large. V-shaped cutout in one end, with the portions thereof near the end of the V designed to support a wafer such that the center of the wafer is positioned over/within the interior of the V-shaped cutout, i.e., a location that does not actually overlap the material of the end effector when viewed from above). The second locations 524b may be similarly located with respect to the second end effectors 540b.

As discussed above, the first robot arms 520a and the second robot arms 520b are each configured to be actuated so as to be able to be transitioned between at least three different states, examples of each of which are represented by each of FIGS. 5-7.

When one of the first robot arms 520a or the second robot arms 520b is in its corresponding far extension state (see FIG. 7), there is a corresponding distal location on that robot arm that is furthest from a rotational axis 514 (also referred to herein as a main rotation axis or main rotational axis) of the robot arm system 508. Thus, the first robot arms 520a may have first distal locations 522a, and the second robot arms 520b may have second distal locations 522b.

When the first robot arms 520a or the second robot arms 520b are in the retracted state, the first distal locations 522a or second distal locations 522b, respectively, may be closer to the rotational axis 514 than when those first robot arms 520a or second robot arms 520b are in the near- or far-extension states. Similarly, when the first robot arms 520a or the second robot arms 520b are in the near-extension state, the first distal locations 522a or second distal locations 522b, respectively, may be closer to the rotational axis 514 than when those first robot arms 520a or second robot arms 520b are in the far-extension states.

In the near-extension state, shown in FIG. 6 with respect to the second robot arms 520b, the second end effectors 540b of the second robot arms 520b are positioned such that the corresponding second locations 524b that are fixed in space relative to the second end effectors 540b and which generally align (when viewed from above) with center points of wafers 516 that are supported by, or are to be supported by, the second end effectors 540b are located directly above a target location, e.g., one of the corners of the square region 572, on one of the “near” pedestals 506 at which wafers are to be placed. Such a target location is usually the nominal center point of the far pedestal. Similar conventions apply as well to the first robot arms, respectively.

Similarly, in the far-extension state, shown in FIG. 7 with respect to the first robot arms 520a, the first end effectors 540a of the first robot arms 520a are positioned such that the corresponding first locations 524a that are fixed in space relative to the first end effectors 540a and which generally align (when viewed from above) with center points of wafers 516 that are supported by, or are to be supported by, the first end effectors 540a are located directly above a target location, e.g., one of the corners of the square region 572, on one of the “far” pedestals 506 at which wafers are to be placed. Such a target location is usually the nominal center point of the near pedestal. Similar conventions apply as well to the second robot arms, respectively.

In some implementations, the first robot arms 520a and/or the second robot arms 520b may be configured to allow the first locations 524a and the second locations 524b to be extended inward or outward along translation axes 566. In some such implementations, the first robot arms 520a and/or the second robot arms 520b may each be single-degree-of-freedom robot arms that are kinematically configured so as to only be able to extend the first end effectors 540a and/or the second end effectors 540b, respectively, along the translation axes (which may be fixed in space relative to the torso unit 512; accordingly, it will be understood that while such first robot arms 520a and/or such second robot arms 520b may be limited to effecting translational wafer movement relative to the torso unit 512, the torso unit 512 may also be rotated to cause the first robot arms 520a and/or the second robot arms 520b to rotate as well). In other implementations, however, the first robot arms 520a and/or the second robot arms 520b may each be two-degree-of-freedom robot arms that are kinematically configured so as to be able to extend the first end effectors 540a and/or the second end effectors 540b, respectively, along the translation axes but also be able to rotate the first robot arms 520a and/or the second robot arms 520b relative to the torso unit 512, as is discussed later herein.

In the implementation depicted in FIGS. 5 through 7, the first robot arms 520a and the second robot arms 520b are both types of selective compliance assembly robot arms (or SCARAs) that each have a single degree of freedom. In the configuration show, the first robot arms 520a and the second robot arms 520b are “nested” such that the second robot arms 520b are located entirely in between portions of the first robot arms 520a. Thus, the second robot arms 520b may be extended or retracted without colliding with the first robot arms 520a when the first robot arms 520a are in the retracted state (even though the second robot arms 520b may be completely overlapped by the first robot arms 520a when both the first robot arms 520a and the second robot arms 520b are in the retracted state and the robot arm system is viewed from above). The first robot arms 520a may be similarly extendable and retractable without colliding with the second robot arms 520b when the second robot arms 520b are in the retracted state.

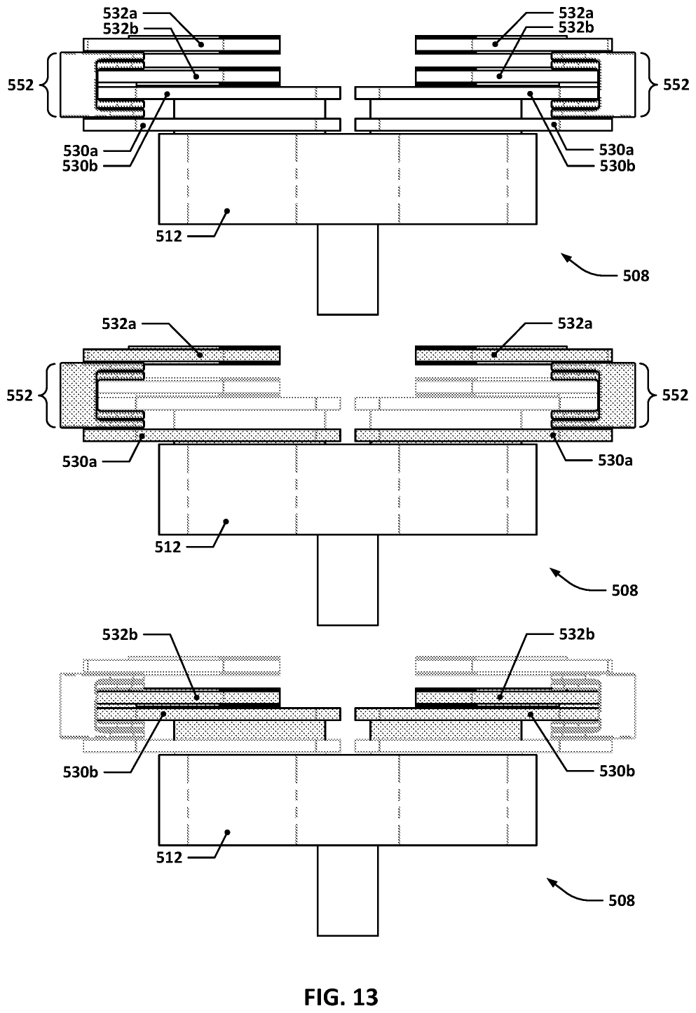

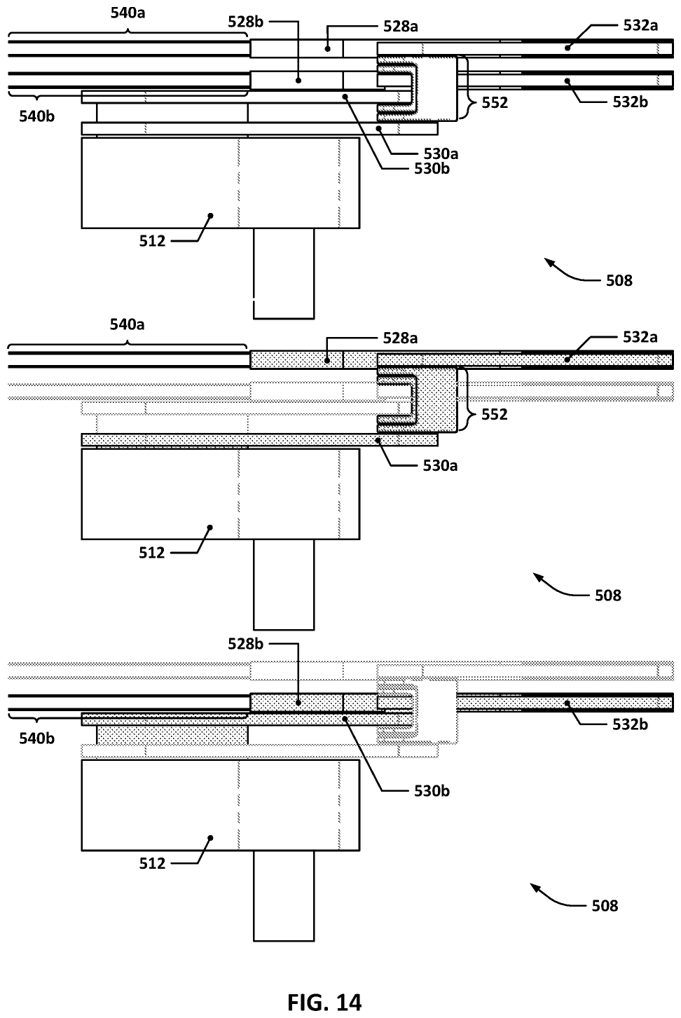

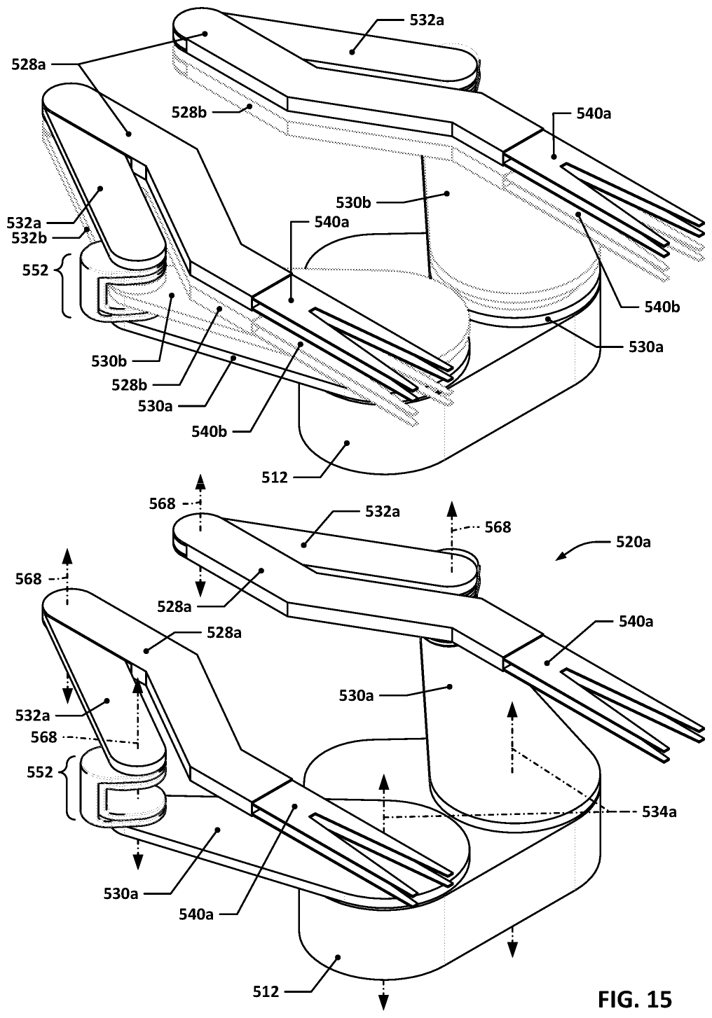

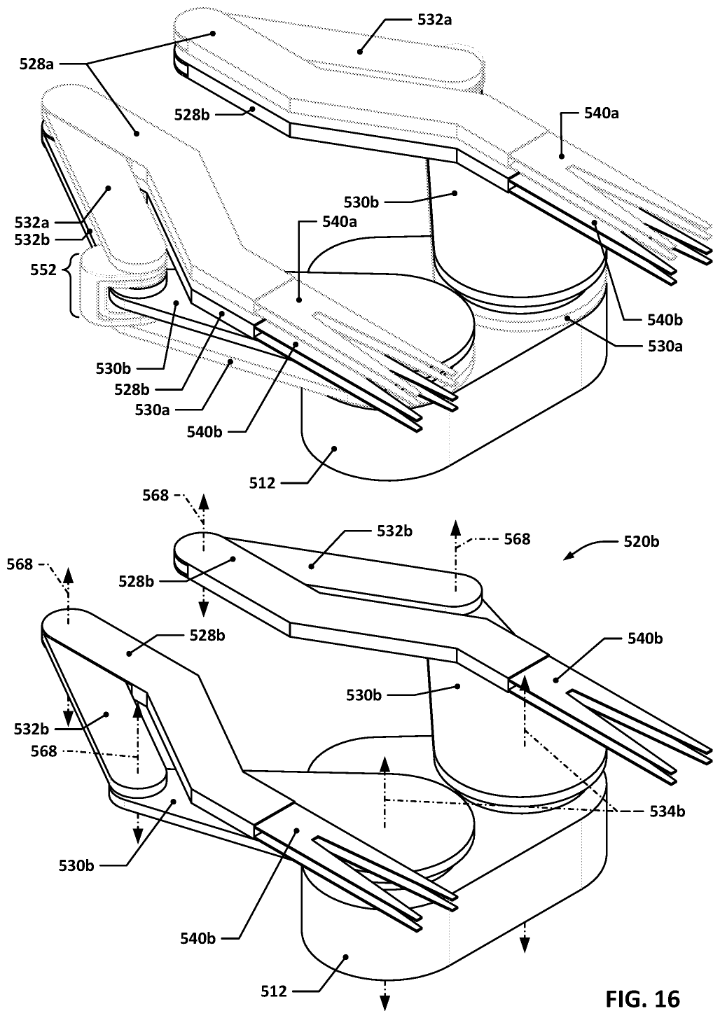

FIGS. 13 and 14 depict front and side views of the robot arm system 508 that more clearly illustrate this nested configuration. FIGS. 15 and 16 depict isometric views that give further clarity on the configuration of such a robot arm system.

In each of FIGS. 13 and 14, a set of three drawings of the robot arm system is provided. with the uppermost view showing both the first robot arms 520a and the second robot arms 520b. The middle view in each of FIGS. 13 and 14 emphasizes the first robot arms 520a with shading (and deemphasizes the second robot arms 520b by rendering them in grey lines), and the bottom view in each of FIGS. 13 and 14 emphasizes the second robot arms 520b with shading (and deemphasizes the first robot arms 520a by rendering them in grey lines). Somewhat similarly, the top view in FIG. 15 depicts the first robot arms 520a in black line font and the second robot arms 520b in grey line font and the bottom view in FIG. 15 depicts the first robot arms 520a with the second robot arms 520b simply omitted. Similarly, the top view in FIG. 16 depicts the second robot arms 520b in black line font and the first robot arms 520a in grey line font and the bottom view in FIG. 16 depicts the second robot arms 520b with the first robot arms 520a simply omitted.

As can be seen in FIGS. 13 through 16, the first robot arms 520a include a plurality of first robot arm links. In the depicted implementations, the first robot arm links each include a first base link 530a and a first intermediate arm link 532a. The first robot arms 520a also each include a first end effector support arm 528a (see FIG. 14) that is rotatably connected with the first intermediate arm link 532a and which supports the first end effector 540a relative to the remainder of that first robot arm 520a. Each of the various first arm links may be rotatably connected with one or two other first arm links so as to form an articulated robot arm. In the depicted implementation, as shown in FIG. 15, the first end effector support arms 528a are each rotatably connected with a different one of the two first intermediate arm links 532a such that each is able to rotate about a corresponding rotational axis 568 relative to the first intermediate arm link 532a to which it is rotatably connected. Similarly, the first intermediate arm links 532a are each rotatably connected with a different one of the two first base links 530a such that each is able to rotate about a corresponding rotational axis 568 relative to the first base link 530a to which it is rotatably connected. Finally, each first base link 530a is rotatably connected with the torso unit 512 such that each is able to rotate about a corresponding first axis 534a relative to the torso unit 512.

Similarly, the second robot arm links each include a second base link 530b and a second intermediate arm link 532b. The second robot arms 520b also each include a second end effector support arm 528b (see FIG. 14) that is rotatably connected with the second intermediate arm link 532b and which supports the second end effector 540b relative to the remainder of the second robot arm 520b. Each of the various second arm links may be rotatably connected with one or two other second arm links so as to form an articulated robot arm. In the depicted implementation, as shown in FIG. 16, the second end effector support arms 528b are each rotatably connected with a different one of the two second intermediate arm links 532b such that each is able to rotate about a corresponding rotational axis 568 relative to the second intermediate arm link 532b to which it is rotatably connected. Similarly, the second intermediate arm links 532b are each rotatably connected with a different one of the two second base links 530b such that each is able to rotate about a corresponding rotational axis 568 relative to the second base link 530b to which it is rotatably connected. Finally, each second base link 530b is rotatably connected with the torso unit 512 such that each is able to rotate about a corresponding second axis 534b relative to the torso unit 512.

As can be seen, the first robot arms 520a and the second robot arms 520b are nearly identical in construction, shape, and size—however, the first robot arms 520a each have a bypass elbow portion 552 as part of the rotational joint between the first intermediate arm link 532a and the first base link 530a of each first robot arm 520a. The bypass elbow portion may feature two structures that are able to rotate relative to one another, but which also have a gap in between portions thereof along the axis of rotation. Thus, other components, such as the ends of the second base links 530b and the second intermediate arm links 532b that are rotatably connected with each other, may be caused to travel through the bypass elbow portions by passing through the gap, thereby allowing such structures to pass through the rotational center axes between the first intermediate arm links 532a and the first base links 530a.

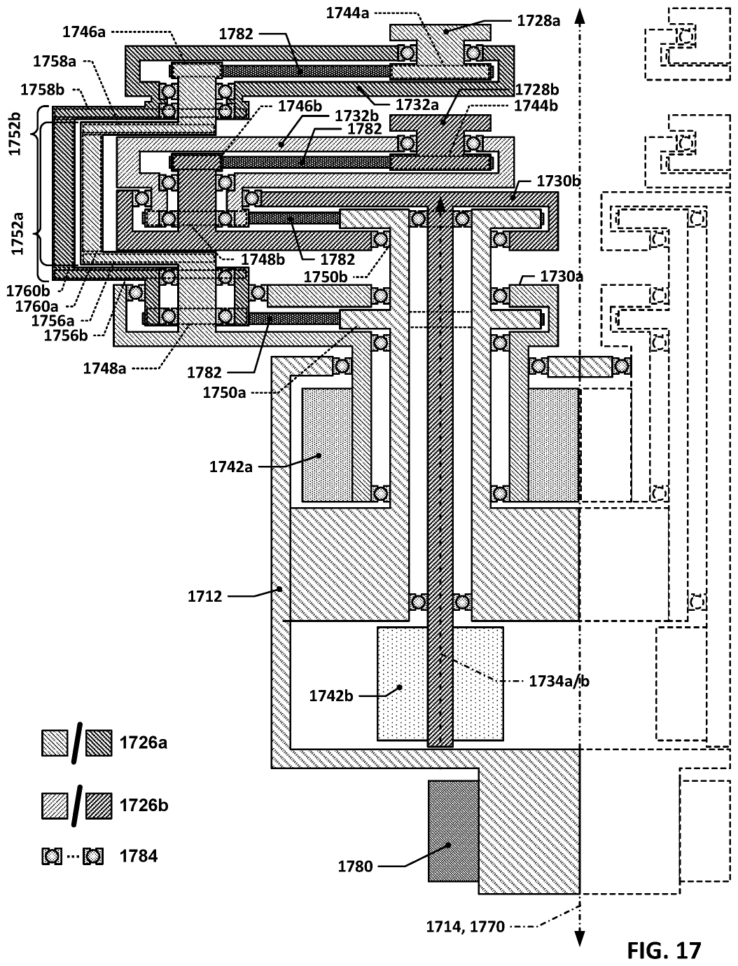

To provide further clarity on the internal workings of such robot arm systems, reference is made to FIG. 17, which depicts a cutaway schematic representation of such a robot arm system. As shown, only half of a robot arm system such as the robot arm system 508 is visible, with the other half (a portion of which is shown) rendered in broken lines. The robot arm system includes a torso unit 1712 that may be rotatable about a rotational axis 1714; a reference plane 1770 of the torso unit 1712 is also shown—the reference plane 1770 may, for example, be a plane of general symmetry in the robot arm system and may be perpendicular to the page of FIG. 17 and coincident or coplanar with the rotational axis 1714. A torso unit drive motor 1780 may be provided to provide rotational input to the torso unit 1712, thereby allowing the robot arm system to be rotated, e.g., as shown in FIGS. 2-4.

The torso unit 1712 may contain a first arm drive motor 1742a and a second arm drive motor 1742b, each of which may be configured to provide rotational input to a corresponding first robot arm or second robot arm, respectively. In this particular example, the first arm drive motor 1742a and the second arm drive motor 1742b may be directly connected with a corresponding first robot arm or a corresponding second robot arm, and there may be another first arm drive motor 1742a and another second arm drive motor 1742b provided on the other side of the reference plane 1770 to drive the other first robot arm and the other second robot arm, respectively. However, in other implementations, a single first arm drive motor 1742a and/or a single second arm drive motor 1742b may be provided that is configured to drive both first robot arms and/or both second robot arms, respectively, simultaneously, e.g., through the use of belts, gearing, or other mechanisms for transferring rotational power from one rotational axis to another, offset but parallel, rotational axis. Generally speaking, it may be desirable to move both first robot arms in parallel/tandem, and both second robot arms similarly in parallel/tandem, although in implementations where the first robot arms and/or the second robot arms are not commonly driven, the first robot arms and/or the second robot arms may, in some such implementations, be driven at different times from their counterpart first or second robot arms. This may, however, result in lower throughput of wafers being placed or picked by such robot arm systems.

As shown, the first arm drive motor 1742a is configured to cause a first base link 1730a of the first arm links 1726a to rotate relative to the torso unit 1712 when driven, and the second arm drive motor 1742b is configured to cause a second base link 1730b of the second arm links 1726b to rotate relative to the torso unit 1712 when driven.

With respect to the second arm links 1726b, the second base link 1730b may be rotatably connected with a second intermediate arm link 1732b, as indicated by the bearings 1784 that are shown in the interface between them. The various rotational interfaces of FIG. 17 are generally indicated by representative bearings 1784, although it will be understood that there may be a variety of ways in which such bearings may be arranged in order to achieve similar rotational motions, and the depicted locations are not to be considered limiting in any manner.

A system of internal pulleys and drive belts may be used to cause the second intermediate arm link 1732b and a second end effector support arm 1728b that may be rotatably connected with the second intermediate arm link 1732b to also rotate relative to the second arm link 1726b to which each is rotatably connected in tandem with rotation of the second base link 1730b relative to the torso unit.

For example, a second intermediate arm link drive pulley 1750b may be provided that is fixed in space relative to the torso unit 1712. Similarly, a second intermediate arm link pulley 1748b may be provided that is fixed in space relative to the second intermediate arm link 1732b; a belt 1782 may be provided that spans between the second intermediate arm link pulley 1748b and the second intermediate arm link drive pulley 1750b. The second intermediate arm link drive pulley 1750b may be sized so as to be twice as large in radius as the second intermediate arm link pulley 1748b. Thus, when the second base link 1730b is caused to rotate relative to the torso unit 1712, and thus the second intermediate arm link drive pulley 1750b, this causes the belt 1782 spanning between the second intermediate arm link pulley 1748b and the second intermediate arm link drive pulley 1750b to drive the second intermediate arm link pulley 1748b at twice the rotational rate of the second base link 1730b (and in the opposite rotational direction). This causes the second intermediate arm link 1732b to rotate relative to the second base link 1730b by twice as much, and in the opposite direction, as the second base link 1730b rotates relative to the torso unit 1712.

The second intermediate arm link 1732b may also be configured internally with a belt and pulley system that may similarly cause the second end effector support arm 1728b to rotate relative to the second intermediate arm link 1732b in tandem with rotation of the second base link 1730b relative to the torso unit 1712. For example, the second intermediate arm link 1732b may have within it a second end effector support arm drive pulley 1746b that is fixed in space relative to the second base link 1730b and a second end effector support arm pulley 1744b that is fixed in space relative to the second end effector support arm 1728b. Another belt 1782 may span between the second end effector support arm drive pulley 1746b and the second end effector support arm pulley 1744b. In this case, the second end effector support arm drive pulley 1746b may have a radius that is half that of the second end effector support arm pulley 1744b, thereby causing the second end effector support arm 1728b to rotate relative to the second intermediate arm link 1732b at half the rate that the second intermediate arm link 1732b rotates relative to the second base link 1730b. Such an arrangement may be used to cause a single rotational input to the second base link 1730b to generate rotational movement in the second base link 1730b and the second intermediate arm link 1732b relative to the torso unit while causing the second end effector support arm 1728b to simply translate, without rotation, relative to the torso unit 1712.

The first arm links 1726a, may be similarly configured, e.g., the first base link 1730a may be rotatably connected with a first intermediate arm link 1732a, as indicated by the bearings 1784 that are shown in the interface between them. A similar system of internal pulleys and drive belts may be used to cause the first intermediate arm link 1732a and a first end effector support arm 1728a that may be rotatably connected with the first intermediate arm link 1732a to also rotate relative to the first arm link 1726a to which each is rotatably connected in tandem with rotation of the first base link 1730a relative to the torso unit.

A first intermediate arm link drive pulley 1750a may be provided that is fixed in space relative to the torso unit 1712. Similarly, a first intermediate arm link pulley 1748a may be provided that is fixed in space relative to the first intermediate arm link 1732a; a belt 1782 may be provided that spans between the first intermediate arm link pulley 1748a and the first intermediate arm link drive pulley 1750a. The first intermediate arm link drive pulley 1750a may be sized so as to be twice as large in radius as the first intermediate arm link pulley 1748a. Thus, when the first base link 1730a is caused to rotate relative to the torso unit 1712, and thus the first intermediate arm link drive pulley 1750a, this causes the belt 1782 spanning between the first intermediate arm link pulley 1748a and the first intermediate arm link drive pulley 1750a to drive the first intermediate arm link pulley 1748a at twice the rotational rate of the first base link 1730a (and in the opposite rotational direction). This causes the first intermediate arm link 1732a to rotate relative to the first base link 1730a by twice as much, and in the opposite direction, as the first base link 1730a rotates relative to the torso unit 1712.

The first intermediate arm link 1732a may also be configured internally with a belt and pulley system that may similarly cause the first end effector support arm 1728a to rotate relative to the first intermediate arm link 1732a in tandem with rotation of the first base link 1730a relative to the torso unit 1712. For example, the first intermediate arm link 1732a may have within it a first end effector support arm drive pulley 1746a that is fixed in space relative to the first base link 1730a and a first end effector support arm pulley 1744a that is fixed in space relative to the first end effector support arm 1728a. Another belt 1782 may span between the first end effector support arm drive pulley 1746a and the first end effector support arm pulley 1744a. In this case, the first end effector support arm drive pulley 1746a may have a radius that is half that of the first end effector support arm pulley 1744a, thereby causing the first end effector support arm 1728a to rotate relative to the first intermediate arm link 1732a at half the rate that the first intermediate arm link 1732a rotates relative to the first base link 1730a. Such an arrangement may be used to cause a single rotational input to the first base link 1730a to generate rotational movement in the first base link 1730a and the first intermediate arm link 1732a relative to the torso unit while causing the first end effector support arm 1728a to simply translate, without rotation, relative to the torso unit 1712.

As can be seen in the second arm links 1726b, a shaft may be provided that extends up from the second base link 1730b and provides a fixed structure to which the second end effector support arm drive pulley 1746b may be connected; the shaft can be axisymmetric along its length, if desired. It will be understood that the various arm links, pulleys, etc, that are shown, while often depicted as being contiguous with other elements, may, in practice, be provided by assemblies of multiple pieces that may, for example, be bolted together so as to form a “fixed” assembly.

The first arm links 1726a may have a similar arrangement, except that the shaft used to support the first end effector support arm drive pulley 1746a has an inner bypass portion 1752a in it. The inner bypass portion 1752a may have a first portion 1756a, a second portion 1758a, and a bridging portion 1760a that spans between one end of the first portion 1756a and a corresponding end of the second portion 1758a. A gap may exist between the first portion 1756a and the second portion 1758a; the gap may be sized larger than the thickness of the rotational joint where the second base link 1730b rotatably connects with the second intermediate arm link 1732b. The bridging portion 1760a may be positioned such that a surface of the bridging portion that faces towards the corresponding rotational axis of the rotational joint between the first base link 1730a and the first intermediate arm link 1732a is offset from that rotational axis in a direction perpendicular to that rotational axis by a distance that is sufficient to allow the rotational joint between the second base link 1730b and the second intermediate arm link 1732b to swing through the gap without colliding with the bridging portion 1760a when the first arm links 1726a are in a configuration that is consistent with the first robot arms being in the retracted state.

The portion of the first intermediate arm link 1732a that extends into the first base link 1730a in order to fixedly support the first intermediate arm link pulley 1748a may correspondingly be equipped with an outer bypass portion 1752b. The outer bypass portion 1752b may have a first portion 1756b, a second portion 1758b, and a bridging portion 1760b that spans between one end of the first portion 1756b and a corresponding end of the second portion 1758b. A gap may exist between the first portion 1756b and the second portion 1758b; the gap may be sized larger than the thickness of the first bypass elbow portion between, and inclusive of, the first portion 1756a and the second portion 1758a. The bridging portion 1760b may be positioned such that a surface of the bridging portion that faces towards the corresponding rotational axis of the rotational joint between the first base link 1730a and the first intermediate arm link 1732a is offset from that rotational axis in a direction perpendicular to that rotational axis by a distance that is greater than the distance between that rotational axis and the surface of the bridging portion 1760a of the inner bypass portion 1752a that is furthest from that rotational axis.

The use of such bypass elbow portions allows the robot arm system of FIG. 17 (and the robot arm system 508 discussed earlier, as well as later implementations discussed herein) to be configured such that the first base link 1730a and the second base link 1730b may be the same size, shape, and dimensions (or at least have subcomponents thereof that are). The first intermediate arm link 1732a and the second intermediate arm link 1732b may similarly be the same size, shape, and dimensions. Such configurations may therefore require fewer unique parts and may therefore be less expensive to manufacture. Such configurations may also be more compact than some alternative designs, which may be advantageous if the transfer chamber with which such a robot arm system is to be used has limited space available.

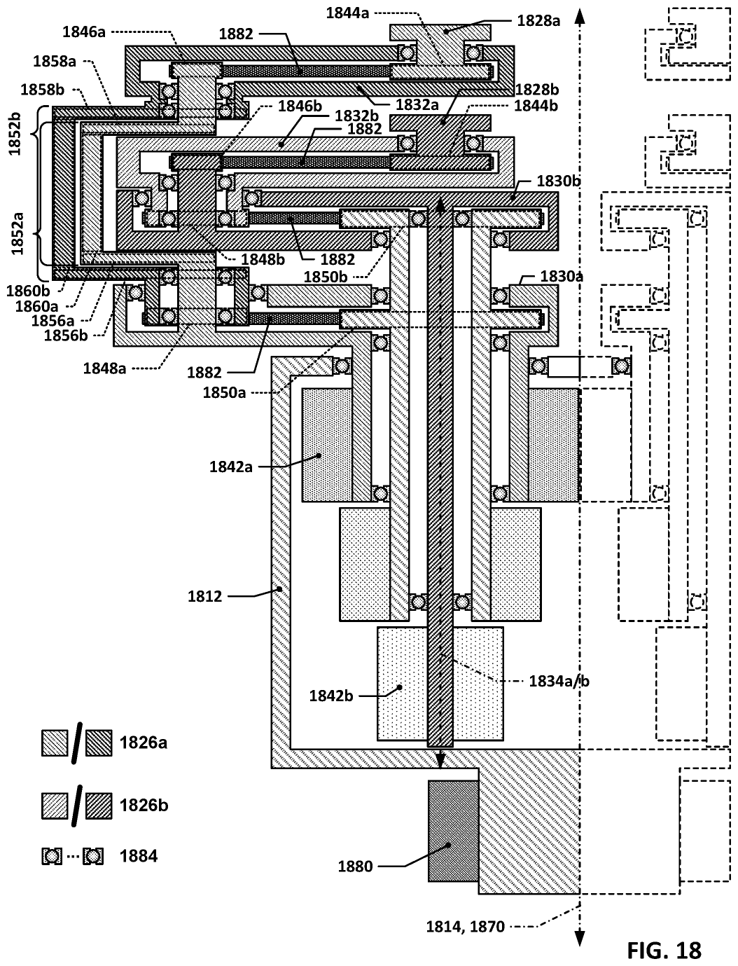

The robot arm system diagrammed in FIG. 17 features first and second robot arms that are only able to provide for translational movement of the end effectors supported thereby relative to the torso unit 1712. In some implementations, however, the first and/or second robot arms may be configured to provide for both translational and rotational movement of the end effectors supported thereby relative to the torso unit 1712. FIG. 18 depicts a cutaway schematic representation of an example robot arm system that features first and second robot arms that are configured to provide for both translational and rotational movement of end effectors supported thereby relative to a torso unit.

The robot arm system of FIG. 18 is nearly identical in structure to that shown in FIG. 17, and it will be understood that the descriptions of elements of the robot arm system of FIG. 17 that are referenced by the same last two digits (or same last two digits and a/b suffix) as corresponding elements in FIG. 18 are equally applicable to those corresponding elements of FIG. 18. In the interest of brevity, such elements are not separately described below and the reader is instead directed to refer to the earlier discussion of similar elements bearing the same last two digits (or last two digits and a/b suffix) with respect to FIG. 17 for descriptions of such elements in FIG. 18.

The implementation of FIG. 18 differs from that of FIG. 17 in that the first intermediate link drive pulley 1850a and the second intermediate link drive pulley 1850b are not, as in FIG. 17, fixed with respect to the torso unit 1812 but are instead configured to be rotated by arm rotation motor. When the arm rotation motor is kept stationary and one or the other of the first arm drive motor 1842a and the second arm drive motor 1842b activated, the first robot arm or the second robot arm, respectively, may be caused to cause the first end effector or the second end effector, respectively, thereof to translate relative to the torso unit 1812. However, when the first arm drive motor 1842a, the second arm drive motor 1842b, and the arm rotation motor are all caused to activate in unison so as to cause the first intermediate link drive pulley 1850a and the second intermediate link drive pulley 1850b to rotate in the same directions, by the same amounts, and at the same speeds as the first base link 1830a and the second base link 1830b, the first robot arm and the second robot arm may simply rotate about the corresponding first and second axes 1834a/b without any extension of the first end effector or the second end effector, respectively, thereof. Such robot arm systems may also be operated so as to perform both extension/retraction of the end effectors thereof and rotation of the robot arms (and thus the end effectors) simultaneously, e.g., by causing the first intermediate link drive pulley 1850a and the second intermediate link drive pulley 1850b to rotate by different amounts and/or speeds and/or directions as compared with the first base link 1830a and/or the second base link 1830b.

As discussed above, the end effectors of the first and second robot arms of FIG. 17 are able to be rotated in unison relative to the transfer chamber/processing chamber(s) by way of the rotation of the torso unit 1812. However, the end effectors of each pair of first robot arms of FIG. 17 are not able to be rotated relative to one another. Similarly, the end effectors of each pair of second robot arms of FIG. 17 are also not able to be rotated relative to one another. In contrast, the implementation of FIG. 18 not only allows the end effectors of the first and second robot arms to be rotated in unison relative to the transfer chamber/process chamber(s), but also allows each first robot arm to be rotated relative to the other first robot arm and each second robot arm to be rotated relative to the other second robot arm. Note that due to the fact that each set of first and second robot arms is driven by a common first intermediate link drive pulley 1850a and second intermediate link drive pulley 1850b, it may be desirable to rotate the first robot arm of such a pair in tandem with the second robot arm of such a pair to avoid, for example, rotating one robot arm of the pair and causing the other robot arm of the pair to extend or retract due to not being rotated (or being rotated by a different amount and/or at a different speed).

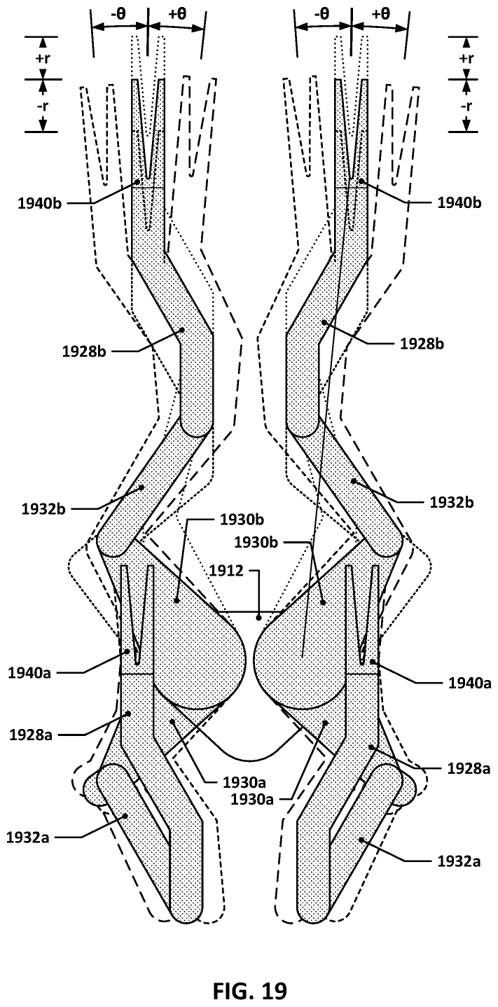

Implementations such as that of FIG. 18 allow each first robot arm to be extended to a different amount and rotated to a different relative angle relative to the other first robot arm. FIG. 19 depicts an example of a robot arm system with a torso unit 1912 that supports two first robot arms each having a first base link 1930a, a first intermediate arm link 1932a, and a first end effector support arm 1928a that supports a first end effector 1940a and two second robot arms each having a second base link 1930b, a second intermediate arm link 1932b, and a second end effector support arm 1928b that supports a second end effector 1940b. In FIG. 19, the second robot arms are both shown in a far extension state, with the first robot arms shown in the retracted state. Each second robot arm may, due to having a configuration such as that shown in FIG. 18, be capable of being moved—independently of the other second robot arm—from the depicted location thereof so as to, for example, extend further by a distance of up to +r, retract inward by a distance of up to −r, swivel left by an angle of up to −θ, and/or swivel right by an angle of up to +θ, or any combination thereof. This allows the centers of wafers supported by the second end effectors 1940b to be independently repositioned so as to be centered on pedestals that may be located beneath the second end effectors 1940b. The dotted outlines that are shown represent the silhouettes of the second robot arms in the further-extended and partially retracted states, and the dashed outlines that are shown represent silhouettes of the first and second robot arms in the left/right rotation states. It will be understood that the first robot arms, when extended to the near- or far-extension states, are able to be independently moved and repositioned in a manner similar to how the second robot arms are shown as being able to be rotated and/or extended/retracted.

This allows, for example, each first robot arm to be controllable so as to be able to perform a wafer centering operation relative to a pedestal of a processing chamber independently of, and at the same time as, a wafer centering operation being performed by the other first robot arm. Thus, both first robot arms are able to simultaneously be controlled so as to center wafers supported thereby over respective pedestals.

It will be appreciated that the range of movements shown in FIG. 19 is, while feasible, generally exaggerated in comparison to the amount of actual robot arm movement that may be performed during wafer centering operations. For example, the amount by which wafers may need to be repositioned during centering operations is typically on the order of a millimeter or two or less, so the amount of extension/retraction or left/right rotation that may be needed to perform wafer centering may be on the order of only a millimeter or two of extension and/or retraction and/or less than a degree of rotation.

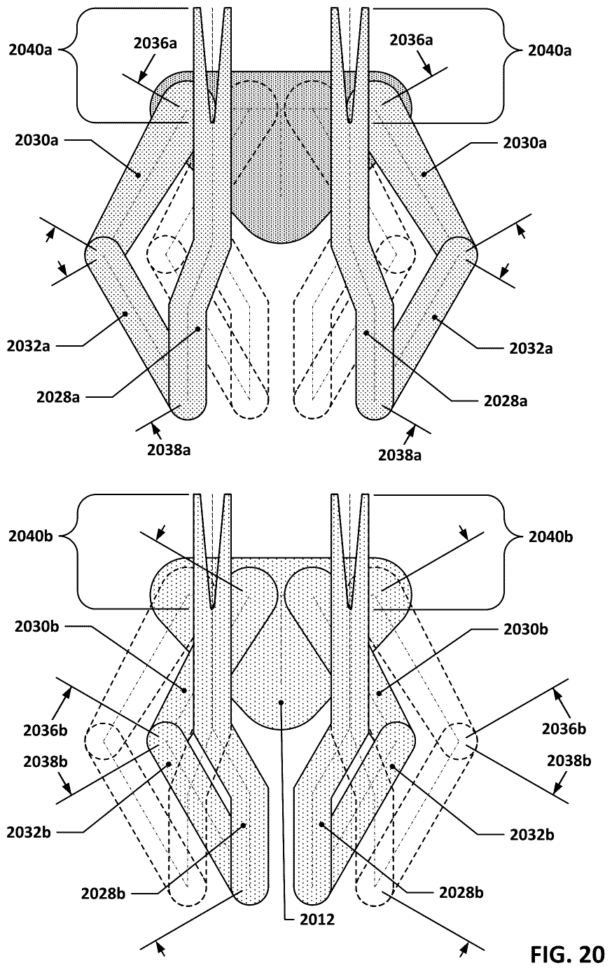

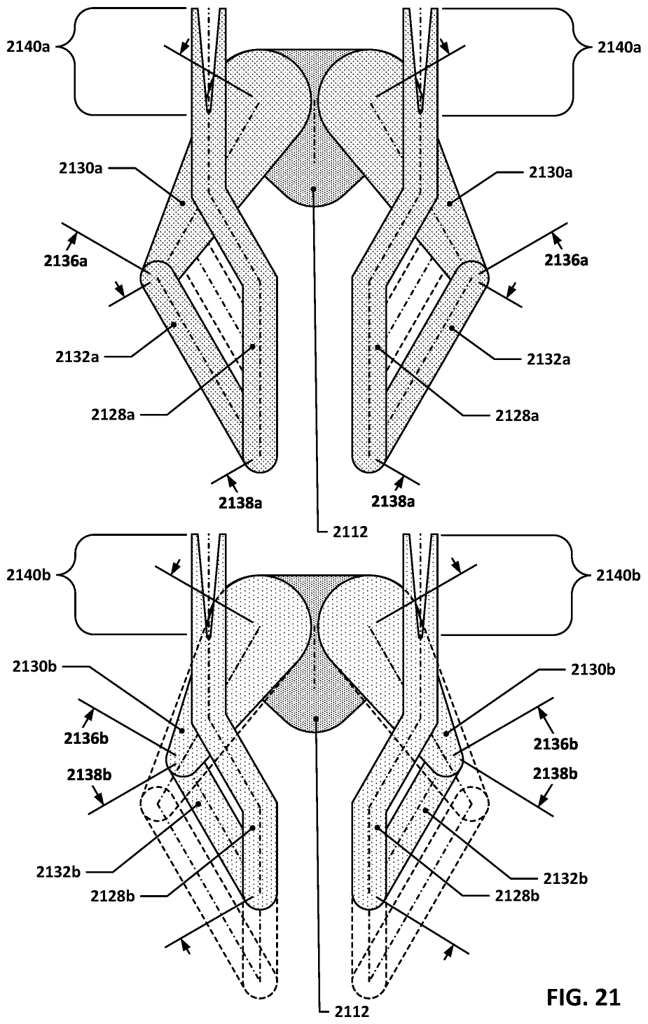

Various alternative robot arm systems that may be used in place of the robot arm systems discussed above are discussed below with reference to FIGS. 20 and 21.

FIG. 20 depicts a plan view diagram of an example robot arm system having first robot arms (which are shaded in the upper diagram of FIG. 20) and second robot arms (shaded in the lower diagram of FIG. 20) in which the first axes about which first base links 2030a are configured to rotate are not coaxial with the second axes about which corresponding second base links 2030b are configured to rotate. Thus, the first axes and the second axes may be spaced apart from one another, e.g., on opposing sides of a reference plane that passes through the axis of rotation of torso unit 2012. This allows the first robot arms and the second robot arms to be staggered from one another in directions perpendicular to their extension axes. In such a configuration, the first robot arms and the second robot arms may be constructed identically, except that the rotational joints between the first base links 2030a and the first intermediate arm links 2032a may be equipped with a spacer that vertically offsets the first base links 2030a and the first intermediate arm links 2032a such that there is clearance for the second base links 2030b and the second intermediate arm links 2032b to pass therebetween. Such an arrangement, however, allows the bypass elbow portion discussed above to be omitted—as long as the first robot arms are spaced far enough from the second robot arms that the second intermediate arm link 2032b can rotate from the position it is in in the retracted state to the position it is in in the far-extension state without contacting the above-mentioned spacer.

The first base links 2030a may have first base link lengths 2036a that define the distance between the corresponding first axes for the rotational joints between the first base links 2030a and the torso unit 2012 and the corresponding rotational axes for the rotational joints between the first base links 2030a and the first intermediate arm links 2032a. The first intermediate arm links may correspondingly have first intermediate arm link lengths 2038a that define the distance between the corresponding rotational axes for the rotational joints between the first intermediate arm links 2032a and the first end effector support arms 2028a and first base links 2030a rotatably connected thereto. Similarly, the second base links 2030b may have second base link lengths 2036b that define the distance between the corresponding second axes for the rotational joints between the second base links 2030b and the torso unit 2012 and the corresponding rotational axes for the rotational joints between the second base links 2030b and the second intermediate arm links 2032b. The second intermediate arm links may correspondingly have second intermediate arm link lengths 2038b that define the distance between the corresponding rotational axes for the rotational joints between the second intermediate arm links 2032b and the second end effector support arms 2028b and second base links 2030b rotatably connected thereto.

In the robot arm system depicted in FIG. 20, the first base link lengths 2036a, the second base link lengths 2036b, the first intermediate arm link lengths 2038a, and the second intermediate arm link lengths 2038b are, as with the example robot arm system discussed earlier with respect to FIGS. 13 through 17, all the same length. However, in the example robot arm system discussed earlier with respect to FIGS. 13 through 17, the first axes and the second axes on each side of the torso unit were coaxial, whereas in the example of FIG. 20, the two first axes are spaced apart from one another in directions perpendicular to the first axes by a distance that is greater than the distance that the second axes are similarly spaced apart by,

Another difference between the robot arm system of FIG. 20 and that discussed earlier is in first end effector support arms 2028a and second end effector support arms 2028b, which may each support first end effectors 2040a and second end effectors 2040b, respectively. The first end effector support arms 2028a and the second end effector support arms 2028b may, like those of the robot system of FIGS. 13-16, each feature two portions—a first portion that extends from the rotational joint that attaches the first end effector support arm 2028a or the second end effector support arm 2028b to the corresponding intermediate arm link and a second portion that terminates in the first end effector 2040a or the second end effector 2040b, as appropriate. These two portions may be offset from one another along an axis that is perpendicular to the translation axis of the respective robot arm and may be joined by a corresponding offset jog portion that spans between the first portion and the second portion. The first portion and the second portion may also generally extend along directions that are parallel to the translation axis. In some instances, the first portion may simply be part of the offset jog portion, e.g., if the offset jog portion is moved closer to the relevant rotational joint, thereby shortening the length of the first portion until the first portion simply becomes the end of the offset jog portion.

In the implementation of FIGS. 13-16, the portions and offset jog portion of each end effector support arm may be similarly sized and dimensioned, thereby allowing, in some cases, the first end effector support arms 528a and second end effector support arms 528b to be provided using identical components (at least with respect to the major structural components thereof), thereby simplifying manufacture and reducing cost. In the implementation depicted in FIG. 20, this could potentially also be the case if, for example, the centerlines of the end effectors for a given pair of adjacent first and second robot arms were to be positioned so as to be coincident with a plane that was midway between the first and second axes for those robot arms and midway between the rotational axes for the rotational joints between the end effector support arms and the intermediate arm links for those robot arms. In the example of FIG. 20, however, the relevant offset for the first end effector support arms 2028a is slightly less than that of the second end effector support arms 2028b, thereby resulting in the first end effector support arms 2028a and the second end effector support arms 2028b being differently structured.

FIG. 21 depicts a plan view diagram of another example robot arm system having first robot arms (which are shaded in the upper diagram of FIG. 21) and second robot arms (shaded in the lower diagram of FIG. 21) in which the first axes about which first base links 2130a are configured to rotate are coaxial with the second axes about which corresponding second base links 2130b are configured to rotate. Thus, the first axis of one first robot arm and the second axis of one second robot arm may be coaxial, and the first axis of another first robot arm and the second axis of another second robot arm may be coaxial with each other (which the two pairs of first and second axes being spaced apart from one another. Such an arrangement is similar to that of the robot arm system of FIGS. 13-16, but the first robot arms and the second robot arms in this example are not identical.

The first base links 2130a may have first base link lengths 2136a that define the distance between the corresponding first axes for the rotational joints between the first base links 2130a and the torso unit 2112 and the corresponding rotational axes for the rotational joints between the first base links 2130a and the first intermediate arm links 2132a. The first intermediate arm links may correspondingly have first intermediate arm link lengths 2138a that define the distance between the corresponding rotational axes for the rotational joints between the first intermediate arm links 2132a and the first end effector support arms 2128a and first base links 2130a rotatably connected thereto. Similarly, the second base links 2130b may have second base link lengths 2136b that define the distance between the corresponding second axes for the rotational joints between the second base links 2130b and the torso unit 2112 and the corresponding rotational axes for the rotational joints between the second base links 2130b and the second intermediate arm links 2132b. The second intermediate arm links may correspondingly have second intermediate arm link lengths 2138b that define the distance between the corresponding rotational axes for the rotational joints between the second intermediate arm links 2132b and the second end effector support arms 2128b and second base links 2130b rotatably connected thereto.

In the robot arm system depicted in FIG. 21, the first base link lengths 2136a and the first intermediate arm link lengths 2138a may be the same and the second base link lengths 2136b and the second intermediate arm link lengths 2138b may be the same, but the first base link lengths 2136a and the first intermediate arm link lengths 2138a may be larger than the second base link lengths 2136b and the second intermediate arm link lengths 2138b. The additional length of the first base link lengths 2136a and the first intermediate arm link lengths 2138a allows the rotational joint between the first base link 2130a and the first intermediate arm link 2132a to be positioned further outward from the first axis than the rotational joint between the second base link 2130b and the second intermediate arm link 2132b, thereby providing clearance that allows the second base link 2130b and the second intermediate arm link 2132b to swing past the first base link 2130a and the first intermediate arm link 2132a without collision when the first robot arms are in the retracted state.

It will be understood that while the example robot arm systems discussed herein have bilateral symmetry, other implementations may feature bilateral asymmetry. For example, a robot arm system may be provided that features left first and second robot arms similar to those shown for the robot arm system 508 in FIGS. 5-16 and right first and second robot arms similar to those shown in FIG. 20 or FIG. 21, thereby forming a robot arm system that has bilateral asymmetry but still provides bilaterally symmetric translation characteristics.

The robot arm systems discussed above may, as noted earlier, allow for direct placement of the wafers transported thereby at each of four stations of a QSM-type multi-station processing chamber, or similar processing chamber. Such placement may also be performed on a wafer-by-wafer basis, with each wafer being centered on the destination pedestal or other wafer support structure using an active wafer centering (AWC) system, as is commonly used in the industry. In an AWC system, optical beam sensors that are fixed with respect to a semiconductor processing chamber may detect when a wafer being transported into the chamber crosses optical beams emitted by the optical beam sensors. The location of the end effector of the wafer transport robot at the time that each optical beam is interrupted by the wafer during such transit may be used to determine the actual position of the wafer relative to the end effector, e.g., of the wafer center relative to the first location or the second location of the first end effector or the second end effector, as discussed earlier. The wafer handling robot may then be controlled so as to slightly adjust the movement of the robot arm transporting the wafer so as to align the wafer center with the desired location of the wafer center at the destination pedestal (or wafer support). Such adjustments are typically quite small, e.g., on the order of less than a millimeter.

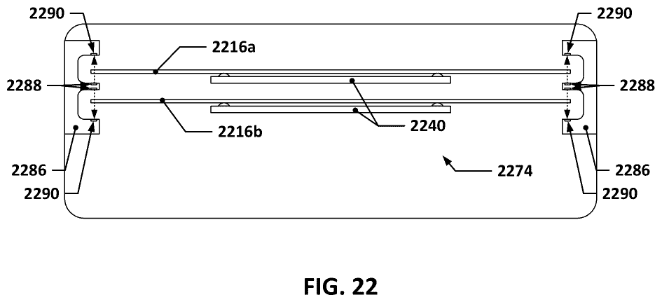

FIG. 22 depicts a schematic of two AWC sensor systems that may be used to obtain individual wafer center measurements relative to an end effector for a configuration of two wafers supported in a stacked arrangement: such AWC sensor systems may be referred to as a dual-wafer AWC sensor systems. In FIG. 22, a first wafer 2216a and a second wafer 2216b are supported in a configuration in which the first wafer 2216a is directly over the second wafer 2216b. Both the first wafer 2216a and the second wafer 2216b are supported by a common end effector 2240 as they are passed into a processing chamber via a wafer transfer passage 2274. AWC sensor systems 2286 may be provided on either side of the wafer transfer passage 2274; each AWC sensor system 2286 may have an E-shaped structure in which the middle horizontal leg of the “E” has photoemitters/light sources 2288 that direct optical beams in upward and downward directions. The middle horizontal leg of the “E” may be positioned such that it will be interposed between the two wafers 2216a and 2216b supported by the end effector 2240 and such that each optical beam emitted by the photoemitters/light sources 2288 intersects with a different one of the two wafers 2216a and 2216b when the end effector 2240 moves the wafers 2216a and 2216b through the wafer transfer passage 2274. The upper and lower legs of the “E” may each house an optical receiver 2290 or other sensor for detecting the light emitted by one of the two photoemitters/light sources 2288. Such AWC sensor systems 2286 may be provided on both sides of the wafer transfer passage 2274; a second set of such AWC sensor systems 2286 (not pictured) may be provided at a different altitude within the wafer transfer passage 2274 to allow similar wafer center measurements to be obtained for wafers transported by another end effector at a lower or higher elevation. Such AWC sensor system allow each wafer transported by the robot arm systems discussed herein, e.g., with end effectors that support wafers in an over/under configuration, to have an AWC measurement obtained that allows the AWC system for the multi-station chamber to fine-tune the placement of each wafer on its destination pedestal or wafer support, thereby allowing for individualized wafer centering within each station. It will be understood that the end effectors discussed herein that are configured to transport two wafers in an over/under configuration may be configured to do so with the centers of the two wafers generally coincident with a common vertical axis, e.g., with one wafer centered over or under the other wafer, or may, alternatively, be configured to do so with the centers of the two wafers offset horizontally so as to not generally intersect with a common vertical axis. Both types of end effector are considered to be within the scope of this disclosure.

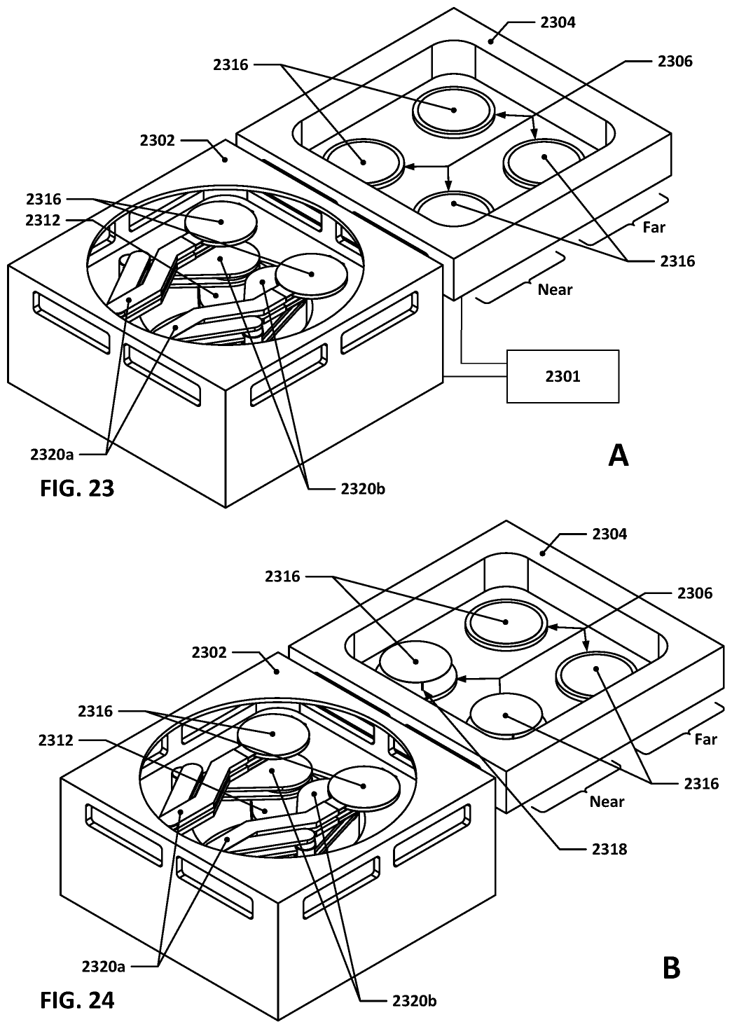

FIGS. 23 through 44 depict isometric views of an example semiconductor processing tool, also referenced below simply as a “tool,” that includes a transfer chamber 2302 and processing chamber 2304. The transfer chamber 2302 is equipped with a robot arm system similar to that shown in FIGS. 13-16. The processing chamber 2304 has four wafer processing stations, each with its own pedestal 2306. The stations/pedestals 2306 that are farthest from the transfer chamber 2302 are labeled as “far” stations or pedestals 2306, while the stations/pedestals 2306 that are closest to the transfer chamber 2302 are labeled as “near” stations or pedestals 2306. The robot arm system has a pair of first robot arms 2320a and a pair of second robot arms 2320b, both supported by a torso unit 2312. These features are common to all of FIGS. 23 through 44. Also visible in FIG. 23 (but omitted in the remaining views) is a controller 2301, which may be communicatively connected with the robot arm system and/or the processing chambers 2304 and which may be used to control movements of the torso unit and the first and second robot arms, as well as potentially the actuation of lift pins of the pedestals 2306. The controller 2301 may also, in some instances, be communicatively connected with an AWC system such as is discussed above.

FIG. 23 depicts the tool in a state of operation in which a first set of four wafers 2316 are loaded onto the end effectors of the first robot arms 2320a and a second set of four wafers 2316 are resident on the pedestals 2306. The second set of four wafers 2316 may have just completed undergoing one or more semiconductor processing operations within the processing chamber 2304, and it may be desirable to remove them and replace them with the first set of wafers 2316. FIGS. 24-34 depict various stages during this process.

In FIG. 24, the wafers 2316 on the near pedestals 2306 have been lifted by lift pins 2318 off of the near pedestals 2306 to an elevation that is sufficient to allow the end effectors of the second robot arms 2320b to be moved to be underneath those wafers 2316.

In FIG. 25, the second robot arms 2320b have been transitioned from the retracted state to the near-extension state, thereby placing the end effectors thereof underneath the wafers 2316 that have been lifted by the lift pins 2318 above the near pedestals 2306.

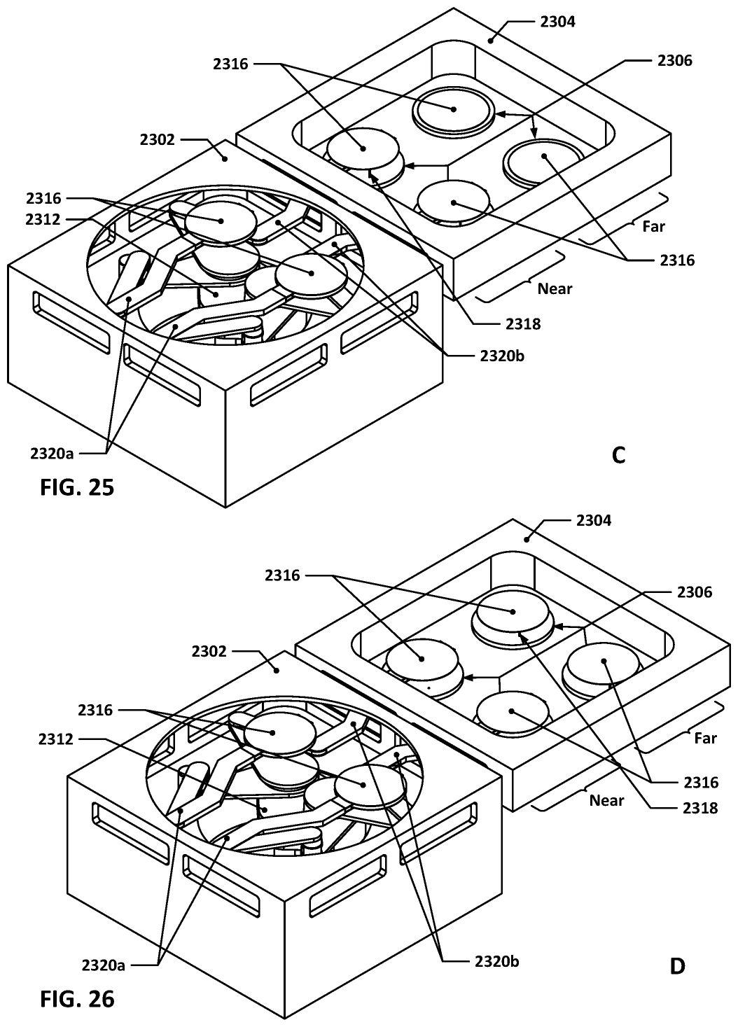

In FIG. 26, the lift pins 2318 for the near pedestals 2306 have been retracted to lower the wafers 2316 supported thereby onto the end effectors of the second robot arms 2320b. At the same time, lift pins 2318 in the far pedestals 2306 have been activated to lift the wafers 2316 supported by the far pedestals 2306 to a height that is somewhat less than the height that the lift pins 2318 for the near pedestals 2306 lifted the wafers 2316 from the near pedestals 2306. This height may be selected such that it places the wafers 2316 from the far pedestals 2306 at an elevation in between the upper and lower blades of the end effectors of the second robot arms 2320b. Alternatively, if the robot arm system is equipped with a Z-axis drive capability, the lift pins 2318 may instead lift the wafers 2316 to the same height as with the near pedestals 2306 and the robot arm system may instead cause the second robot arms 2320b to change in elevation so that the wafers 2316 being lifted by the lift pins are at the same relative elevation with respect to the end effectors of the second robot arms 2320b. It will also be understood that the lifting of the wafers 2316 from the far pedestals 2306 may also be done earlier, e.g., in conjunction with the lifting of the wafers 2316 from the near pedestals 2306.

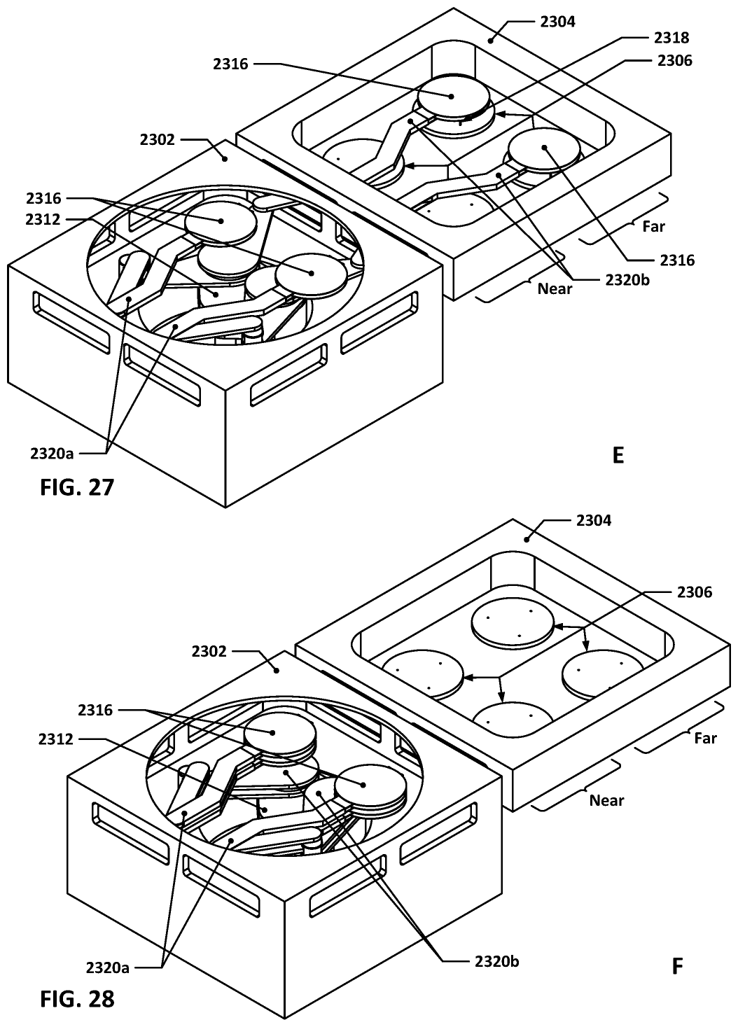

In FIG. 27, the second robot arms 2320b have been caused to transition from the near-extension state to the far-extension state, thereby maneuvering the end effectors thereof such that the wafers 2316 that are lifted off of the far pedestals 2306 by the corresponding lift pins 2318 are positioned beneath the wafers 2316 already supported by the end effectors of the second robot arms 2320b but above the lower blade of those same end effectors. The wafers 2316 supported by the lift pins 2318 for the far pedestals 2306 may then be lowered onto the end effectors for the second robot arms 2320b.

In FIG. 28, the second robot arms 2320b are caused to transition from the far-extension state to the retracted state, thereby withdrawing all four wafers 2316 in the second set of wafers 2316 from the processing chamber 2304. As can be seen, there are now eight wafers 2316 housed within the transfer chamber 2302 at this point, and the processing chamber 2304 is empty of wafers and ready to receive the wafers 2316 of the first set of wafers 2316.

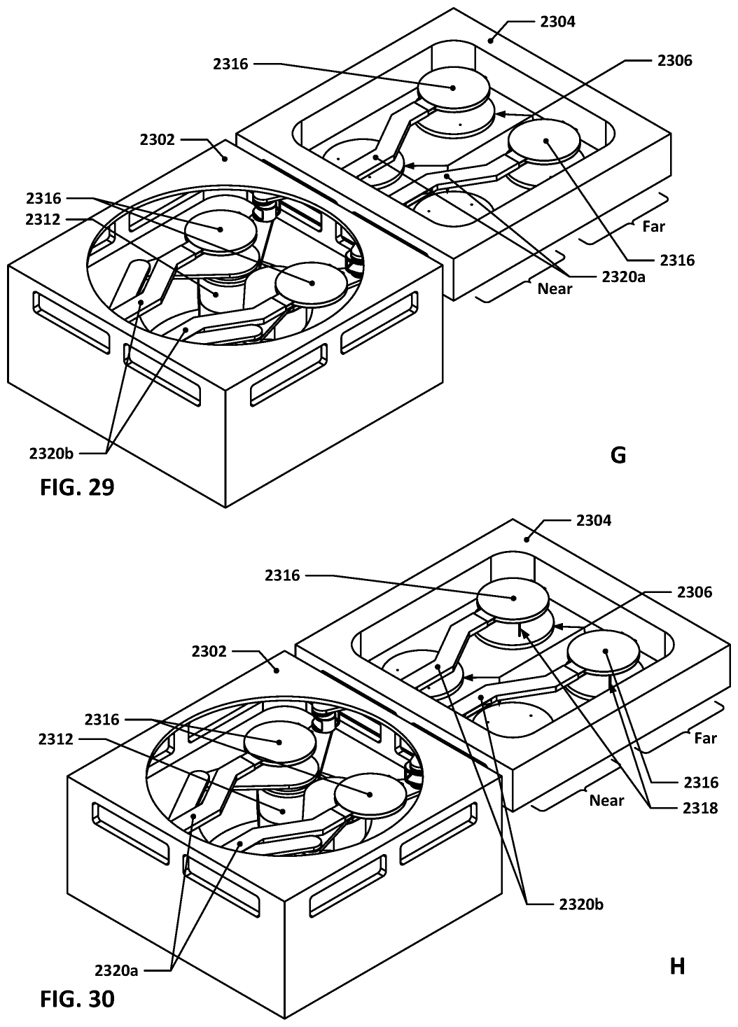

In FIG. 29, the first robot arms 2320a have been caused to transition to the far-extension state, thereby introducing the first set of wafers 2316 into the processing chamber 2304 and positioning the wafers 2316 in the first set of wafers 2316 over the far pedestals 2306.

In FIG. 30, the lift pins 2318 for the far pedestals 2306 have been caused to extend so as to lift the two wafers 2316 supported in the lower position of the end effectors of the first robot arms off of those end effectors. If an AWC system is used to allow for individual centering of each placed wafer, then the robot arm system may be controlled to first center one of the two wafers 2316 supported in the lower position of one of the two first robot arms 2320a on the corresponding far pedestal 2306 and then cause only the lift pins of that corresponding far pedestal 2306 to then lift that single wafer 2316 off of the corresponding end effector. Once that wafer 2316 is no longer supported by the end effector and is instead supported by the lift pins 2318 for the far pedestal 2306 that that wafer 2316 is to be placed on, the robot arm system may be further controlled so as to center the wafer 2316 supported in the lower position of the end effector for the other first robot arm 2320a on the other far pedestal 2306 before causing the lift pins 2318 thereof to extend and also lift the wafer 2316 supported in the lower position of the end effector for the other first robot arm 2320a off of that end effector. At this stage, both wafers 2316 that were previously supported by the end effectors of the first robot arms 2320a in the lower positions thereof have been centered over their respective far pedestals 2306 and are no longer supported by the end effectors of the first robot arms 2320a. It will be understood that if the robot arm system that is used is similar to that shown in FIG. 18, then the wafer centering operations may be performed concurrently rather than serially, which may reduce the overall time needed to place the wafers 2316 onto the far pedestals 2306 in the process chamber 2304.

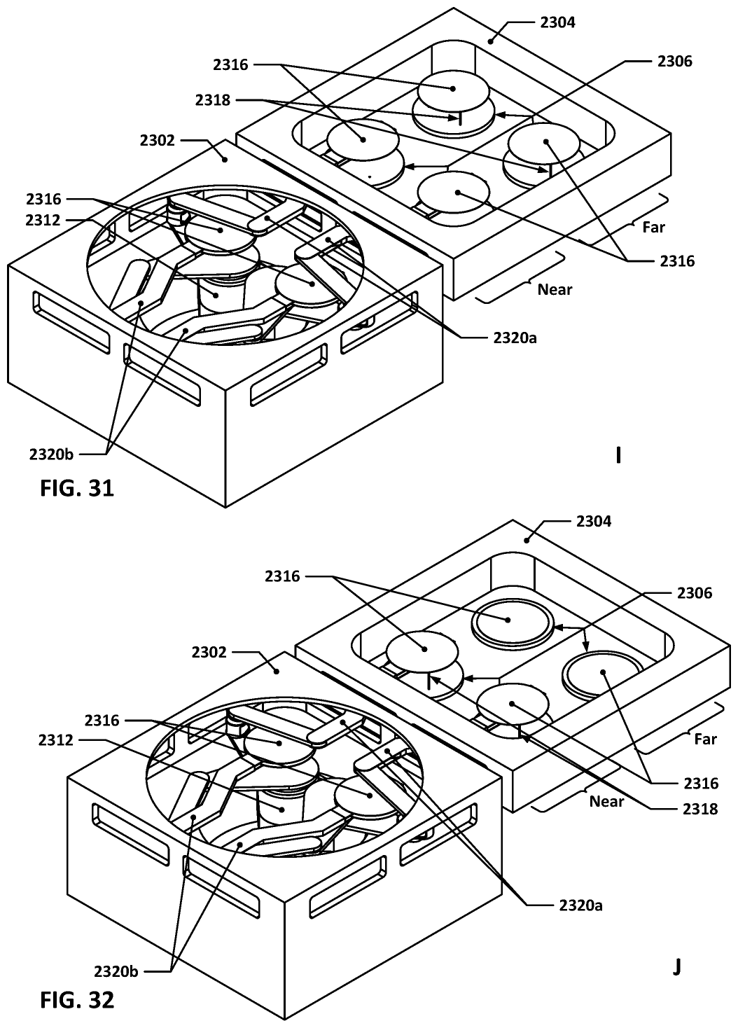

In FIG. 31, the first robot arms have been caused to transition from the far-extension state to the near-extension state, thereby leaving the wafers 2316 that were previously supported by the end effectors of the first robot arms 2320a suspended over the far pedestals 2306 and supported by the corresponding lift pins 2318.

In FIG. 32, the lift pins 2318 for the near pedestals 2306 have been extended to lift the two wafers 2316 that are still supported by the first robot arms 2320a off of the end effectors of the first robot arms. As discussed above with respect to FIG. 30, the lift pins 2318 for the near pedestals 2306 may be raised in a staggered fashion, with each wafer 2316 still supported by the first robot arms 2320a being caused to be centered over its respective near pedestal 2306 prior to the lift pins 2318 for that pedestal being raised to lift that wafer 2316 off of the supporting first robot arm 2320a. In implementations that support it, such centering may be performed concurrently by each first robot arm 2320a.

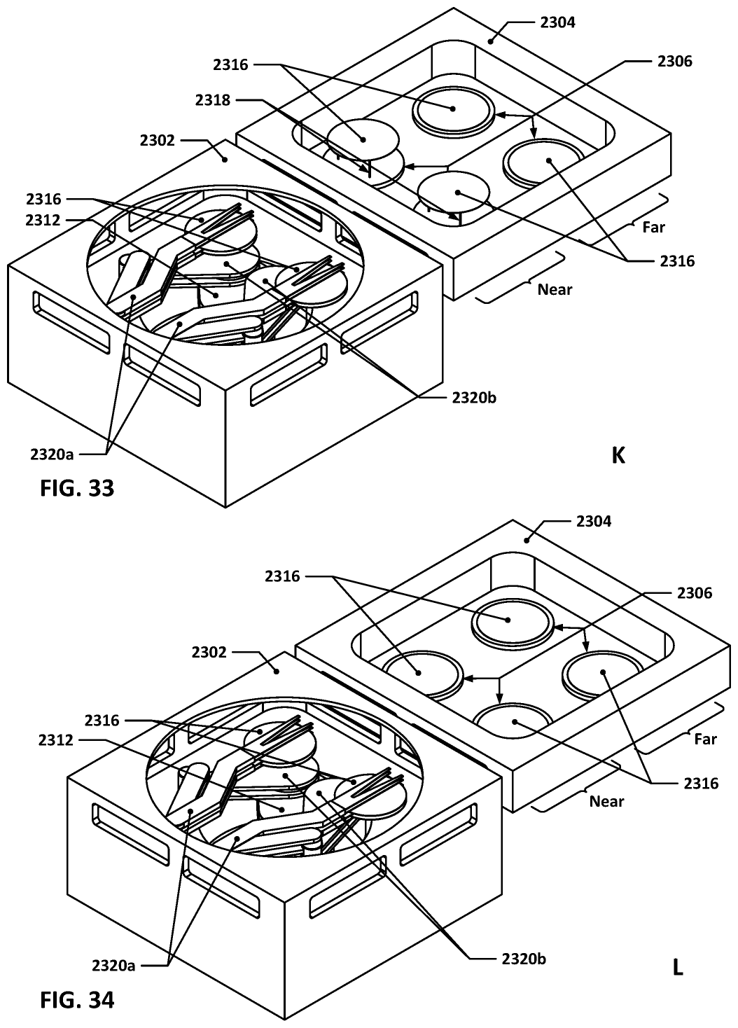

In FIG. 33, the first robot arms 2320a have been caused to transition into the retracted state, thereby leaving the remaining pair of wafers 2316 supported on the lift pins 2318 of the near pedestals 2306.

In FIG. 34, the lift pins 2318 of the near pedestals 2306 are caused to retract, thus lowering the last two wafers 2316 of the first set of wafers 2316 onto their respective near pedestals 2306. It will be understood, of course, that the wafers 2316 placed at the far pedestals 2306 do not need to be lowered onto their respective far pedestals 2306 as part of the operations depicted in FIG. 32, but may instead be lowered at a later time, e.g., simultaneously with the lowering of the wafers 2316 onto the near pedestals 2306 (such as during the operations depicted in FIG. 34).

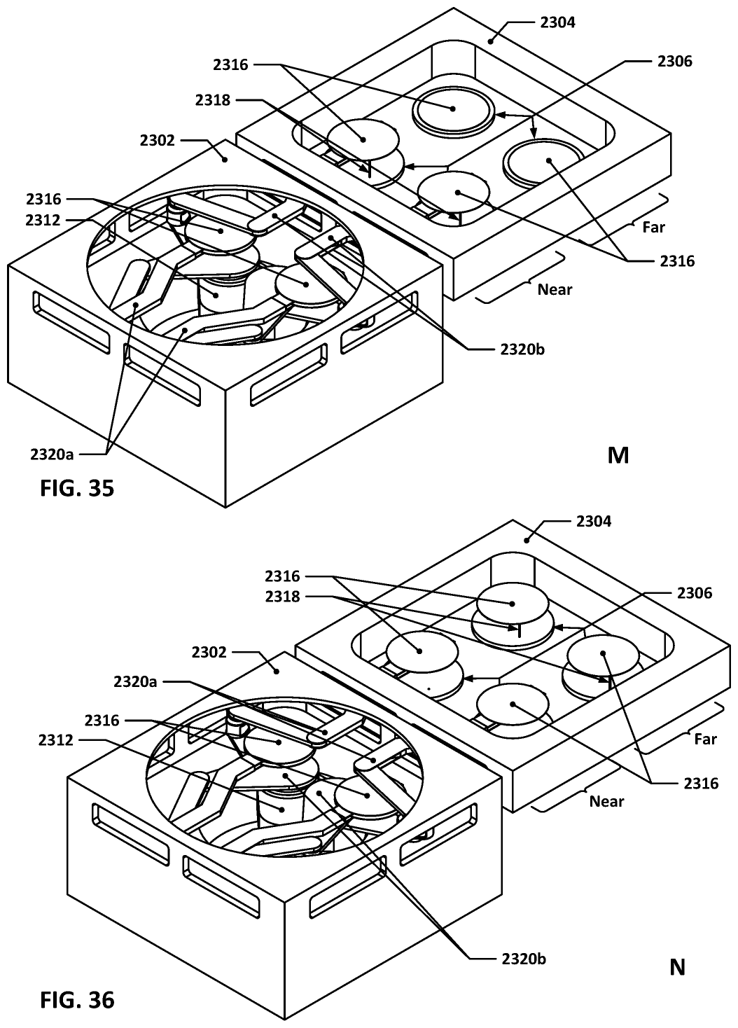

FIGS. 35-44 depict similar operations to those discussed with respect to FIGS. 24 through 34, but with the first set of wafers 2316 initially being resident in the processing chamber 2304 and the second set of wafers 2316 being resident within the transfer chamber 2302 and supported by the second robot arms 2320b. In actual practice, once a set of wafers is removed from the processing chamber, that set of wafers will typically be moved to another processing chamber or to a set of load locks for transport out of the tool and a different set of wafers from yet another processing chamber or from such load locks will be loaded onto the robot arm system for introduction into the processing chamber(s) of the tool.

In FIG. 35, the wafers 2316 on the near pedestals 2306 have been lifted by lift pins 2318 off of the near pedestals 2306 to an elevation that is sufficient to allow the end effectors of the first robot arms 2320a to be moved to be underneath those wafers 2316. The first robot arms 2320a have also been transitioned from the retracted state to the near-extension state, thereby placing the end effectors thereof underneath the wafers 2316 that have been lifted by the lift pins 2318 above the near pedestals 2306.

In FIG. 36, the lift pins 2318 for the near pedestals 2306 have been retracted to lower the wafers 2316 supported thereby onto the end effectors of the first robot arms 2320a. At the same time, lift pins 2318 in the far pedestals 2306 have been activated to lift the wafers 2316 supported by the far pedestals 2306 to a height that is somewhat less than the height that the lift pins 2318 for the near pedestals 2306 lifted the wafers 2316 from the near pedestals 2306. This height may be selected such that it places the wafers 2316 from the far pedestals 2306 at an elevation in between the upper and lower blades of the end effectors of the first robot arms. Alternatively, if the robot arm system is equipped with a Z-axis drive capability, the lift pins 2318 may instead lift the wafers 2316 to the same height as with the near pedestals 2306 and the robot arm system may instead cause the first robot arms 2320a to change in elevation so that the wafers 2316 being lifted by the lift pins are at the same relative elevation with respect to the end effectors of the first robot arms 2320a. It will also be understood that the lifting of the wafers 2316 from the far pedestals 2306 may also be done earlier, e.g., in conjunction with the lifting of the wafers 2316 from the near pedestals 2306.

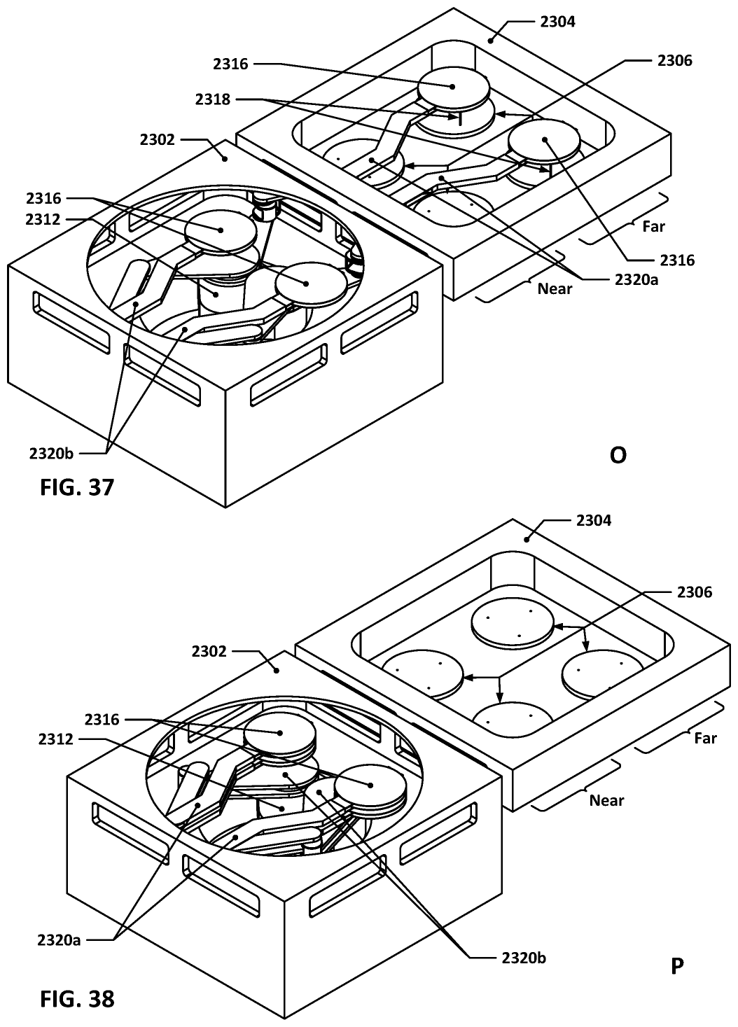

In FIG. 37, the first robot arms 2320a have been caused to transition from the near-extension state to the far-extension state, thereby maneuvering the end effectors thereof such that the wafers 2316 that are lifted off of the far pedestals 2306 by the corresponding lift pins 2318 are positioned beneath the wafers 2316 already supported by the end effectors of the first robot arms 2320a but above the lower blade of those same end effectors. The wafers 2316 supported by the lift pins 2318 for the far pedestals 2306 may then be lowered onto the end effectors for the first robot arms 2320a.

In FIG. 38, the second robot arms 2320b are caused to transition from the far-extension state to the retracted state, thereby withdrawing all four wafers 2316 in the second set of wafers 2316 from the processing chamber 2304. As can be seen, there are now eight wafers 2316 again housed within the transfer chamber 2302 at this point, and the processing chamber 2304 is empty of wafers and ready to receive the wafers 2316 of the second set of wafers 2316.

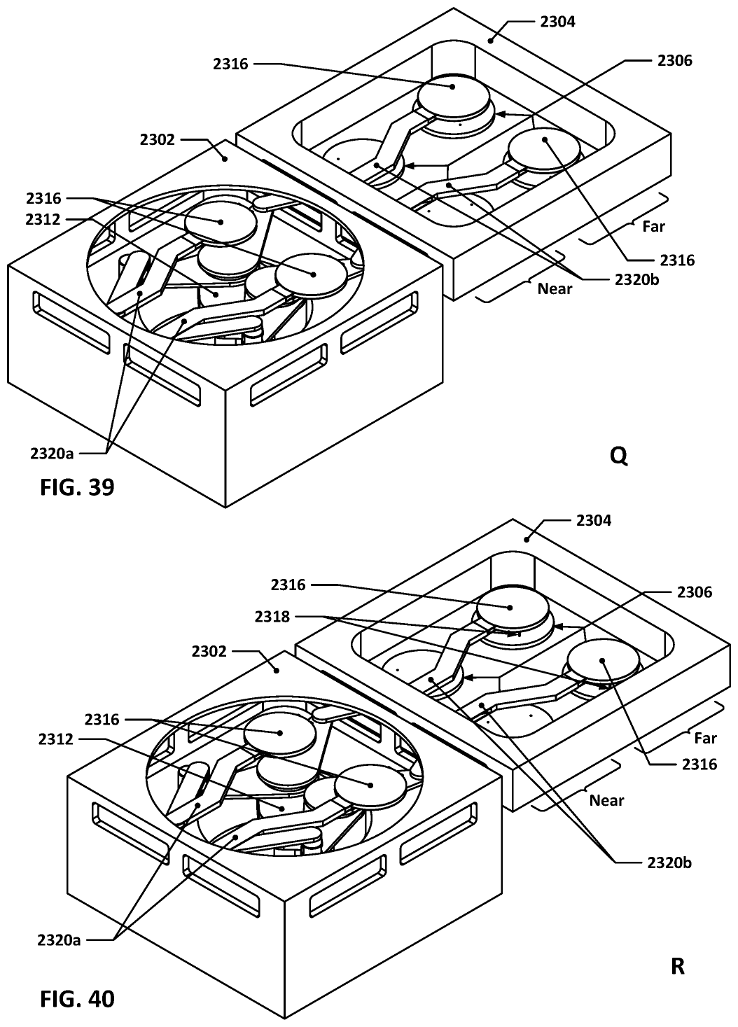

In FIG. 39, the second robot arms 2320b have been caused to transition to the far-extension state, thereby introducing the second set of wafers 2316 into the processing chamber 2304 and positioning the wafers 2316 in the second set of wafers 2316 over the far pedestals 2306.

In FIG. 40, the lift pins 2318 for the far pedestals 2306 have been caused to extend so as to lift the two wafers 2316 supported in the lower position of the end effectors of the second robot arms off 2320b of those end effectors. If an AWC system is used to allow for individual centering of each placed wafer, then, as discussed earlier with respect to FIGS. 30 and 32, the robot arm system may be controlled to first center one of the two wafers 2316 supported in the lower position of one of the two second robot arms 2320b on the corresponding far pedestal 2306 and then cause only the lift pins of that corresponding far pedestal 2306 to then lift that single wafer 2316 off of the corresponding end effector. Once that wafer 2316 is no longer supported by the end effector and is instead supported by the lift pins 2318 for the far pedestal 2306 that that wafer 2316 is to be placed on, the robot arm system may be further controlled so as to center the wafer 2316 supported in the lower position of the end effector for the other second robot arm 2320b on the other far pedestal 2306 before causing the lift pins 2318 thereof to extend and also lift the wafer 2316 supported in the lower position of the end effector for the other second robot arm 2320b off of that end effector. As noted earlier, if the robot arm system that is used is similar to that shown in FIG. 18, then the wafer centering operations may be performed concurrently rather than serially, which may reduce the overall time needed to place the wafers 2316 onto the far pedestals 2306 in the process chamber 2304. At this stage, both wafers 2316 that were previously supported by the end effectors of the second robot arms 2320b in the lower positions thereof have been centered over their respective far pedestals 2306 and are no longer supported by the end effectors of the second robot arms 2320b.

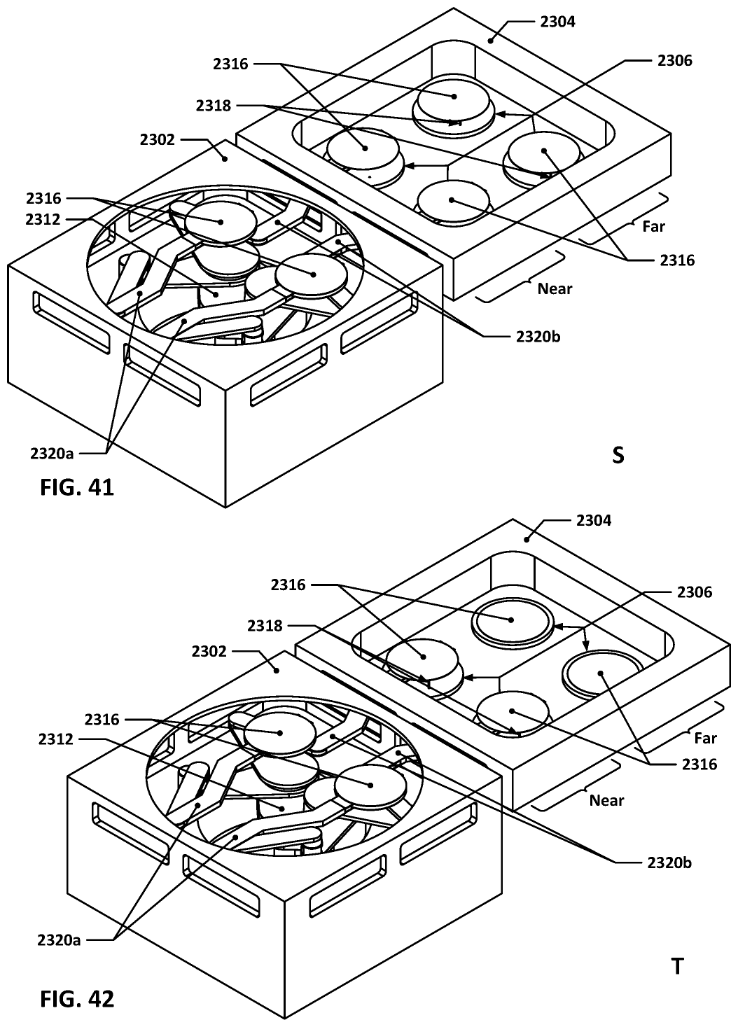

In FIG. 41, the second robot arms 2320b have been caused to transition from the far-extension state to the near-extension state, thereby leaving the wafers 2316 that were previously supported by the end effectors of the second robot arms 2320b suspended over the far pedestals 2306 and supported by the corresponding lift pins 2318.

In FIG. 42, the lift pins 2318 for the near pedestals 2306 have been extended to lift the two wafers 2316 that are still supported by the second robot arms 2320b off of the end effectors of the second robot arms 2320b. As discussed above with respect to FIGS. 30, 32, and 40, the lift pins 2318 for the near pedestals 2306 may be raised in a staggered fashion, with each wafer 2316 still supported by the second robot arms 2320b being caused to be centered over its respective near pedestal 2306 prior to the lift pins 2318 for that pedestal being raised to lift that wafer 2316 off of the supporting second robot arm 2320b. Such centering may be performed concurrently or serially depending on the particular configuration of robot arm system used.

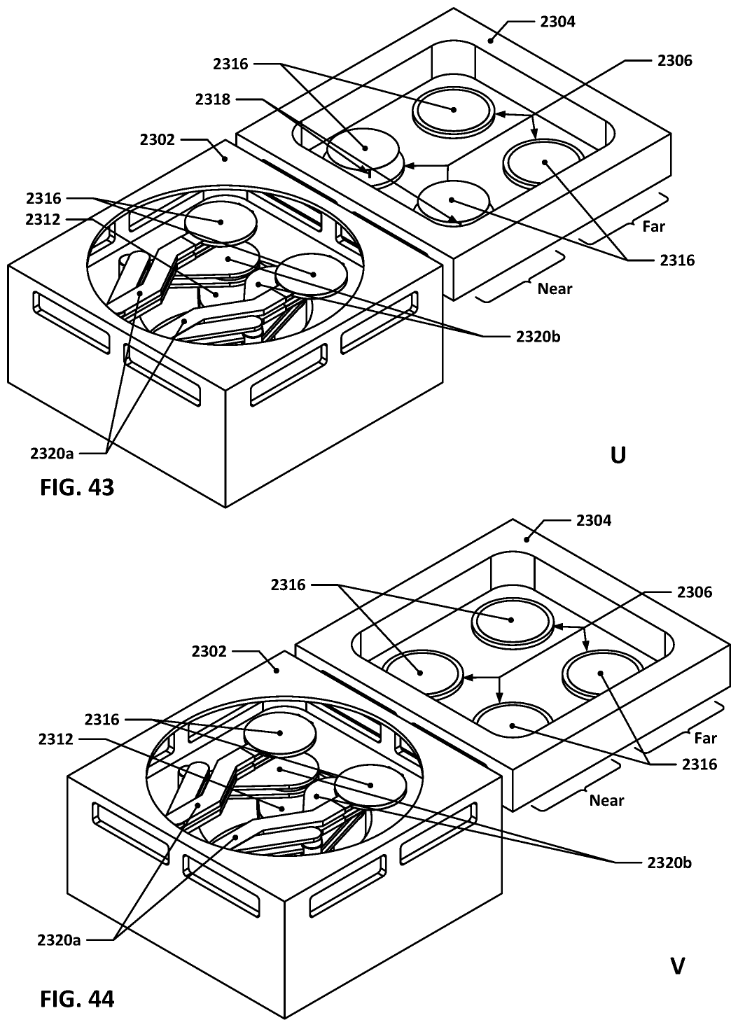

In FIG. 43, the second robot arms 2320b have been caused to transition into the retracted state, thereby leaving the remaining pair of wafers 2316 supported on the lift pins 2318 of the near pedestals 2306.

In FIG. 44, the lift pins 2318 of the near pedestals 2306 are caused to retract, thus lowering the last two wafers 2316 of the second set of wafers 2316 onto their respective near pedestals 2306. It will be understood, of course, that the wafers 2316 placed at the far pedestals 2306 do not need to be lowered onto their respective far pedestals 2306 as part of the operations depicted in FIG. 42, but may instead be lowered at a later time, e.g., simultaneously with the lowering of the wafers 2316 onto the near pedestals 2306 (such as during the operations depicted in FIG. 44).

Other sequences of operation may also be practiced using the robot arms systems discussed above, although such alternative sequences may require additional movements, e.g., placing both robot arms into the retracted state more often, that may prolong the wafer transfer process and reduce throughput. Such alternative usage of the robot handling systems discussed herein, while perhaps less efficient, is also considered to be within the scope of this disclosure.

The above discussion has focused almost entirely on robot arm systems that feature two pairs of robot arms. However, as discussed earlier in this disclosure, some implementations of the robot arm systems discussed herein may feature only a single pair of opposing robot arms that are mounted to a common torso unit. Robot arm systems with two pair of robot arms, while more expensive and more complex to control, generally offer a significant through-put benefit in that one pair of robot arms may be used to hold and support a group of wafers to be placed into a chamber while the other pair of robot arms is used to remove a group of wafers from the chamber to make way for the waiting group. Thus, the wafers to be placed are able to be delivered to the chamber immediately after the wafers that were in the chamber are removed, without requiring any gross movement of the torso unit. Robot arm systems with only a single pair of opposing robot arms do not have this capability—any wafers that are removed from a chamber by such a robot arm system will need to be withdrawn from the chamber, rotated so as to face another chamber or wafer-receiving location, caused to place the removed wafers in a new location, and then retrieve another set of wafers that is to be delivered to the chamber from which the first set was originally retrieved. This requires a significantly higher number of operations, and thus greatly increases the amount of time that is required to swap one set of wafers for another within a process chamber.

However, such a throughput penalty may not matter in semiconductor processing tools in which a chamber may not be able to be immediately loaded with the next set of wafers after removal of a set of wafers where processing is complete. For example, if a semiconductor processing tool is configured to perform a post-processing cleaning operation on a chamber at after each set of wafers that is processed therein is removed, then there may be period of time after removal of the wafers during which the next set of wafers is unable to be placed therein due to such a cleaning operation being performed. If the duration of the cleaning cycle is long enough, the robot arm system will be able to deliver the removed wafers to their next destination, retrieve the next set of wafers to be processed, and position that set of wafers so as to be insertable into the process chamber as soon as the cleaning operation is concluded all before the end of the cleaning operation. In such a situation, there is effectively no throughput penalty to using such a more limited robot arm system since there are external parallel throughput constraints that are more limiting than the throughput constraint of the robot arm system.

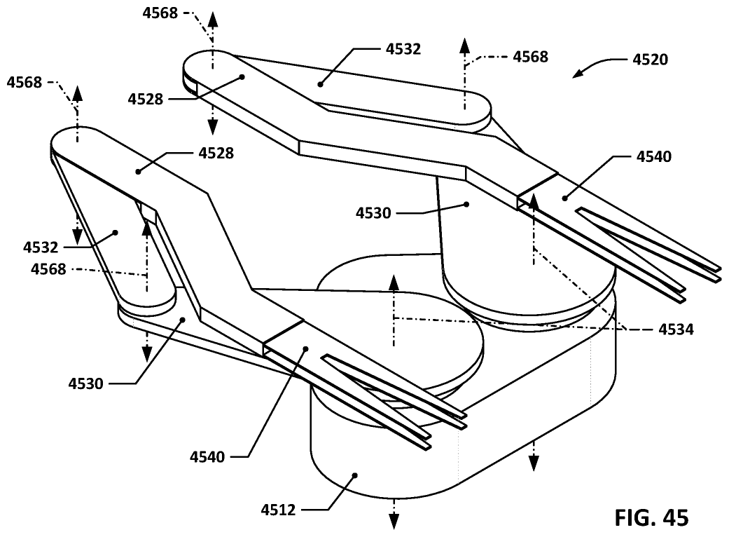

In light of the above, it will be recognized that the robot arm systems discussed herein may, in some implementations, include only a single pair of opposing robot arms that are supported by a common torso unit. Two examples of such robot arm systems are discussed below with respect to FIGS. 45-48.

FIG. 45 depicts an isometric view of an example of a robot arm system with only a single pair of robot arms. The depicted robot arm system includes robot arms 4520 that each include a base link 4530, an intermediate arm link 4532, and an end effector support arm 4528 that supports an end effector 4540. The base links 4530 are both supported by a common torso unit 4512 and may be rotatably connected with the torso unit 4512 so as to be rotatable relative thereto about corresponding axes 4534. The intermediate arm links 4532 may each be connected with a respective different one of the two base links 4530 so as to be rotatable about a corresponding rotational axis 4568, and the end effector support arms 4528 may each be connected with a respective different one of the two intermediate arm links 4532 so as to be rotatable about a corresponding rotational axis 4568.

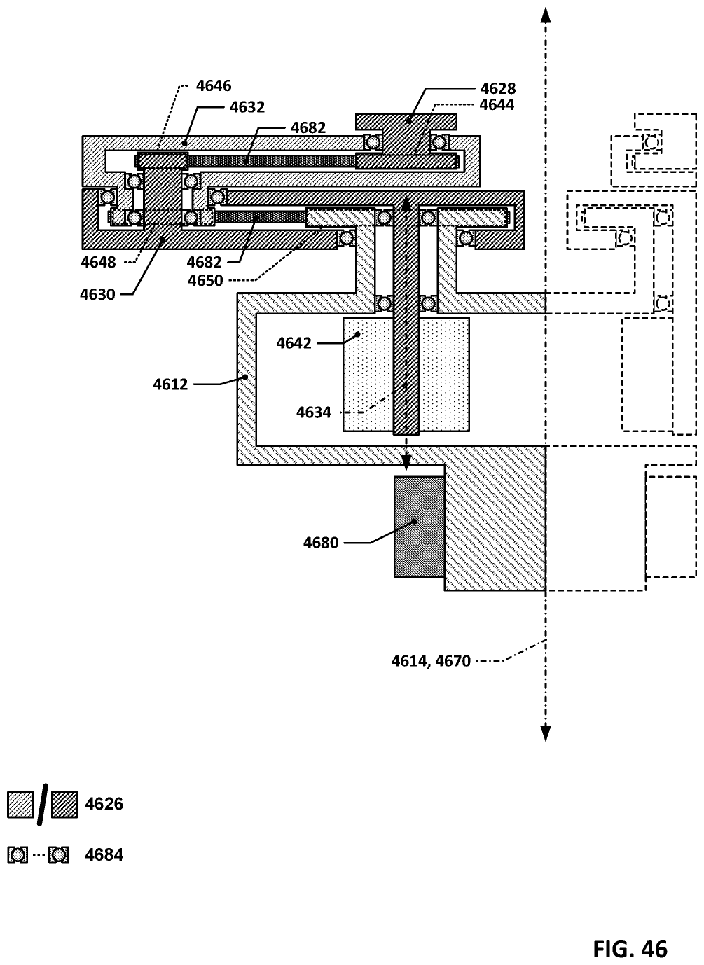

FIG. 46 depicts a cutaway schematic representation of one such robot arm system. As shown, only half of a robot arm system is visible, with the other half (a portion of which is shown) rendered in broken lines. The robot arm system includes a torso unit 4612 that may be rotatable about a rotational axis 4614; a reference plane 4670 of the torso unit 4612 is also shown—the reference plane 4670 may, for example, be a plane of general symmetry in the robot arm system and may be perpendicular to the page of FIG. 46 and coincident with the rotational axis 4614. A torso unit drive motor 4680 may be provided to provide rotational input to the torso unit 4612, thereby allowing the robot arm system to be rotated, e.g., similar to as shown in FIGS. 2-4.

The torso unit 4612 may contain an arm drive motor 4642 which may be configured to provide rotational input to a corresponding one of the robot arms. In this particular example, the arm drive motor 4642 is directly connected with a corresponding robot arm, and there may be another arm drive motor 4642 provided on the other side of the reference plane 4670 to drive the other robot arm. However, in other implementations, a single arm drive motor 4642 may be provided that is configured to drive both robot arms simultaneously, e.g., through the use of belts, gearing, or other mechanisms for transferring rotational power from one rotational axis to another, offset but parallel, rotational axis. Generally speaking, it may be desirable to move both robot arms in parallel/tandem, although in implementations where the robot arms are not commonly driven, each robot arm may, in some such implementations, be driven at different times from the other robot arm. This may, however, result in lower throughput of wafers being placed or picked by such robot arm systems.

As shown, the arm drive motor 4642 is configured to cause a base link 4630 of the arm links 4626 to rotate relative to the torso unit 4612 when driven. The base link 4630 may be rotatably connected with an intermediate arm link 4632, as indicated by the bearings 4684 that are shown in the interface between them. Similar to FIGS. 17 and 18. The various rotational interfaces of FIG. 46 are generally indicated by representative bearings 4684, although it will be understood that there may be a variety of ways in which such bearings may be arranged in order to achieve similar rotational motions, and the depicted locations are not to be considered limiting in any manner.

A system of internal pulleys and drive belts may be used to cause the intermediate arm link 4632 and end effector support arm 4628 that may be rotatably connected with the intermediate arm link 4632 to also rotate relative to the arm link 4626 to which each is rotatably connected in tandem with rotation of the base link 4630 relative to the torso unit.

For example, an intermediate arm link drive pulley 4650 may be provided that is fixed in space relative to the torso unit 4612. Similarly, an intermediate arm link pulley 4648 may be provided that is fixed in space relative to the intermediate arm link 4632; a belt 4682 may be provided that spans between the intermediate arm link pulley 4648 and the intermediate arm link drive pulley 4650. The intermediate arm link drive pulley 4650 may be sized so as to be twice as large in radius as the intermediate arm link pulley 4648. Thus, when the base link 4630 is caused to rotate relative to the torso unit 4612, and thus the intermediate arm link drive pulley 4650, this causes the belt 4682 spanning between the intermediate arm link pulley 4648 and the intermediate arm link drive pulley 4650 to drive the intermediate arm link pulley 4648 at twice the rotational rate of the base link 4630 (and in the opposite rotational direction). This causes the intermediate arm link 4632 to rotate relative to the base link 4630 by twice as much, and in the opposite direction, as the base link 4630 rotates relative to the torso unit 4612.

The intermediate arm link 4632 may also be configured internally with a belt and pulley system that may similarly cause the end effector support arm 4628 to rotate relative to the intermediate arm link 4632 in tandem with rotation of the base link 4630 relative to the torso unit 4612. For example, the intermediate arm link 4632 may have within it an end effector support arm drive pulley 4646 that is fixed in space relative to the base link 4630 and an end effector support arm pulley 4644 that is fixed in space relative to the end effector support arm 4628. Another belt 4682 may span between the end effector support arm drive pulley 4646 and the end effector support arm pulley 4644. In this case, the end effector support arm drive pulley 4646 may have a radius that is half that of the end effector support arm pulley 4644, thereby causing the end effector support arm 4628 to rotate relative to the intermediate arm link 4632 at half the rate that the intermediate arm link 4632 rotates relative to the base link 4630. Such an arrangement may be used to cause a single rotational input to the base link 4630 to generate rotational movement in the base link 4630 and the intermediate arm link 4632 relative to the torso unit while causing the end effector support arm 4628 to simply translate, without rotation, relative to the torso unit 4612.

As can be seen in the arm links 4626, a shaft may be provided that extends up from the base link 4630 and provides a fixed structure to which the end effector support arm drive pulley 4646 may be connected; the shaft can be axisymmetric along its length, if desired. It will be understood that the various arm links, pulleys, etc, that are shown, while often depicted as being contiguous with other elements, may, in practice, be provided by assemblies of multiple pieces that may, for example, be bolted together so as to form a “fixed” assembly.

The robot arm system of FIG. 46 features robot arms that are able to extend or retract—independently of each other if driven by separate arm drive motors or slaved together if driven by a common arm drive motor—relative to the torso unit 4612. While such robot arms may also be rotated in unison about an axis due to rotation of the torso unit 4612 about that axis, such robot arms are not capable of rotating relative to the torso unit 4612. For clarity, “rotation of a robot arm” or the like refers to rotation of the end effector of that robot arm—for example, various arm links of the robot arm of FIG. 46 will necessarily rotate relative to the torso unit 4612 during any movement of the robot arm, but the end effector of that robot arm can only translate relative to the torso unit 4612 without rotation. As such, the robot arm of FIG. 46 will be understood to not be able to rotate relative to the torso unit 4612.

The robot arm system of FIG. 46 may be used to pick or place wafers into a process chamber in much the same manner as depicted in FIGS. 23 through 44 for the first robot arms or the second robot arms of the robot arm system depicted therein, except that, of course, the actions taken with both pairs of first and second robot arms in FIGS. 23 through 44 would instead be performed with a single pair of robot arms, thereby requiring, for example, only a single set of four wafers to be handled by the robot arm system at a time and for additional robot arm system movements to be performed, for example, in between the operations of FIGS. 28 and 29 in order to remove the set of wafers that was retrieved by the robot arms from the process chamber in FIG. 27 from the robot arms and to then place on the robot arms another set of wafers that are to be placed into the process chamber in FIG. 29. Similar additional robot arm system movements would need to be performed in between the operations of FIGS. 38 and 39 as well.

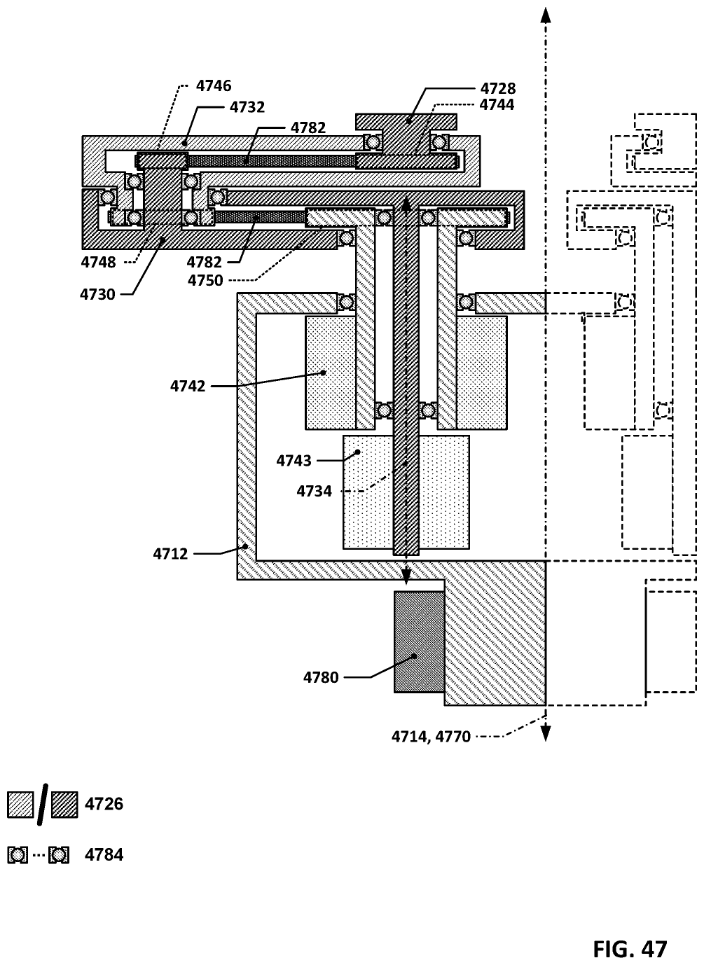

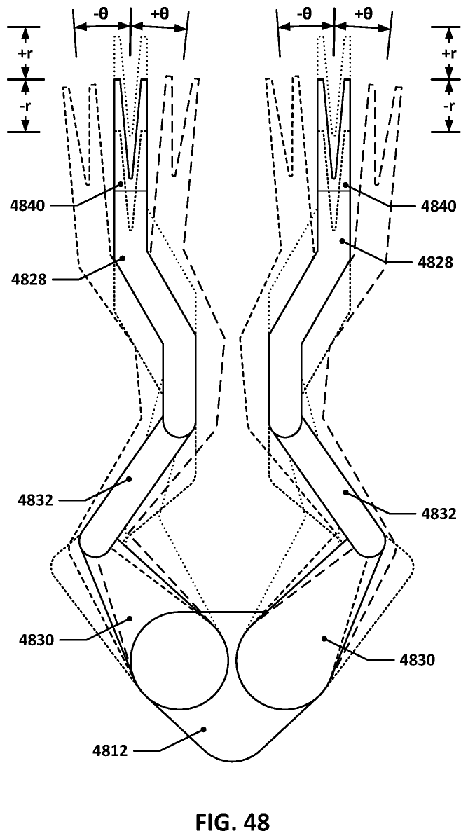

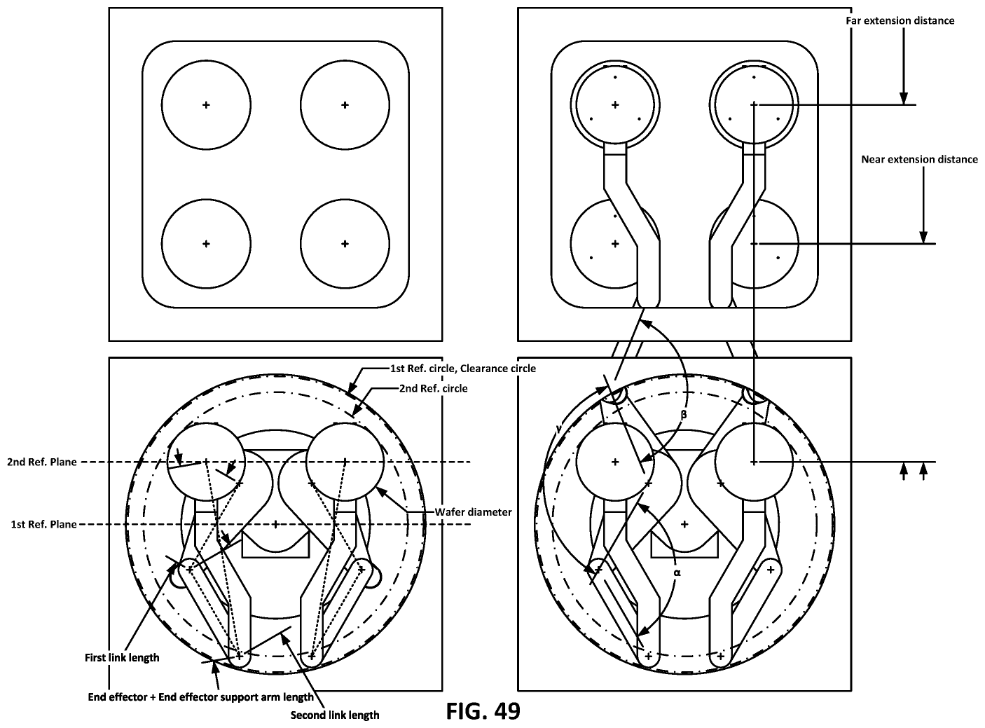

Robot arm systems with a single pair of robot arms supported by a torso unit, as discussed with respect to FIG. 46, may also be designed so as to permit for rotation of the robot arms relative to the torso unit, similar to the capability of the robot arm system of FIG. 18. Such an implementation is discussed below with respect to FIGS. 47 and 48.

The robot arm system of FIG. 47 is nearly identical in structure to that shown in FIG. 46, and it will be understood that the descriptions of elements of the robot arm system of FIG. 46 that are referenced by the same last two digits as corresponding elements in FIG. 47 are equally applicable to those corresponding elements of FIG. 47. In the interest of brevity, such elements are not separately described below and the reader is instead directed to refer to the earlier discussion of similar elements bearing the same last two digits with respect to FIG. 46 for descriptions of such elements in FIG. 47.

The implementation of FIG. 47 differs from that of FIG. 46 in that the intermediate link drive pulley 4750 is not, as in FIG. 46, fixed with respect to the torso unit 4712 but is instead configured to be rotated by arm rotation motor 4743. When the arm rotation motor 4743 is kept stationary and the arm drive motor 4742 activated, the robot arm may be caused to cause the end effector thereof to translate relative to the torso unit 4712. However, when the arm drive motor 4742 and the arm rotation motor 4743 are both caused to activate in unison so as to cause the intermediate link drive pulley 4750 to rotate in the same direction, by the same amount, and at the same speed as the base link 4730, the robot arm may simply rotate about the axis 4734 without any extension or retraction of the end effector thereof. Such robot arm systems may also be operated so as to perform both extension/retraction of the end effectors thereof and rotation of the robot arms (and thus the end effectors) relative to the torso unit simultaneously, e.g., by causing the intermediate link drive pulley 4750 to rotate by different amounts and/or speeds and/or directions as compared with the intermediate link drive pulley 4750.

As discussed above, the end effectors of the robot arms of FIG. 46 are able to be rotated in unison relative to the transfer chamber/processing chamber(s) by way of the rotation of the torso unit 4712. However, the end effectors of the robot arms of FIG. 46 are not able to be rotated relative to one another. In contrast, the implementation of FIG. 47 not only allows the end effectors of the robot arms to be rotated in unison relative to the transfer chamber/process chamber(s), but also allows each robot arm to be rotated relative to the other robot arm and the torso unit 4712.

Implementations such as that of FIG. 47 allow each robot arm to be extended to a different amount and rotated to a different relative angle relative to the other robot arm. FIG. 48 depicts an example of a robot arm system with a torso unit 4812 that supports two robot arms each having a base link 4830, an intermediate arm link 4832, and an end effector support arm 4828 that supports an end effector 4840. In FIG. 48, the robot arms are shown in a far extension state. Each robot arm may, due to having a configuration such as that shown in FIG. 47, be capable of being moved—independently of the other robot arm—from the depicted location thereof so as to, for example, extend further by a distance of up to +r, retract inward by a distance of up to −r, swivel left by an angle of up to −θ, and/or swivel right by an angle of up to +θ, or any combination thereof. This allows the centers of wafers supported by the end effectors 4840 to be independently repositioned so as to be centered on pedestals that may be located beneath the end effectors 4840. The dotted outlines that are shown represent the silhouettes of the robot arms in the further-extended and partially retracted states, and the dashed outlines that are shown represent silhouettes of the robot arms in the left/right rotation states.

It will be appreciated that the range of movements shown in FIG. 48 is, while feasible, generally exaggerated in comparison to the amount of actual robot arm movement that may be performed during wafer centering operations. For example, the amount by which wafers may need to be repositioned during centering operations is typically on the order of a millimeter or two or less, so the amount of extension/retraction or left/right rotation that may be needed to perform wafer centering may be on the order of only a millimeter or two of extension and/or retraction and/or less than a degree of rotation.

The implementations discussed above allow, for example, each robot arm to be controllable so as to be able to perform a wafer centering operation relative to a pedestal of a processing chamber independently of, and at the same time as, a wafer centering operation being performed by the other robot arm. Thus, both robot arms are able to simultaneously be controlled so as to center wafers supported thereby over respective pedestals.

It will also be appreciated that a hybrid of the robot arm systems of FIGS. 46 and 47 may be employed as well, e.g., with one of the two robot arms being configured as shown in FIG. 46 and the other being configured as shown in FIG. 47. In such an implementation, each robot arm would be able to be independently controlled so as to extend, retract, and/or rotate relative to the transfer chamber housing the robot arm system (and the process chamber in which wafers are being placed), thereby allowing wafers supported thereby to be subjected to simultaneous centering operations associated with two different pedestal locations within the process chamber. Rotational adjustment of the robot arm that is configured as shown in FIG. 46 in such an implementation is obtained by rotating the torso unit that supports the robot arms—by combining such torso unit rotation with extension or retraction of that robot arm. such a robot arm may be controlled so as to move the wafer supported thereby in any direction by an amount needed in order to center the wafer on a desired target location. Similarly, rotational adjustment of the robot arm that is configured as shown in FIG. 47 in such an implementation is obtained by causing that robot arm to rotate relative to the torso unit. By combining such rotational movement of that arm relative to the torso unit with extension or retraction of that robot arm relative to the torso unit, such a robot arm may also be controlled so as to move the wafer supported thereby in any direction by an amount needed in order to center the wafer on a desired target location. However, it will be recognized that any rotational movement of the torso unit that is performed in order to adjust the rotational position of the robot arm that is configured as shown in FIG. 46 will necessarily also cause the robot arm that is configured as shown in FIG. 47 (and that is also supported by the torso unit) to undergo a similar rotation—the robot arm that is configured as shown in FIG. 47 may therefore need to undergo additional rotational and/or extension/retraction adjustment to “correct out” the rotational movements that it experiences as a result of the torso unit rotations that are performed as part of rotational adjustment of the robot arm that is configured as shown in FIG. 46. Such a hybrid system, while more kinematically complex than the system shown in FIG. 47, may provide similar performance to that shown in FIG. 47, but offers the benefit of requiring one less motor than would be required to support the implementation of FIG. 47. A similar approach may also be adopted for a hybrid version of robot arm systems with two pairs of robot arms, e.g., a robot arm system in which the first and second robot arms on one side of a torso unit are configured as shown in FIG. 17, while the first and second robot arms on the other side of the torso unit are configured as shown in FIG. 18.

It will be appreciated that the robot arm systems discussed herein are configured so as to provide a transfer-chamber based wafer handling solution that is able to not only simultaneously place a pair of wafers into side-by-side stations that are adjacent to the transfer chamber, but to also be able to simultaneously place a pair of wafers into side-by-side stations that are located on the other side of the initial pair of stations from the transfer chamber.

In some such implementations, it may be desirable to reduce the overall footprint of such semiconductor processing tools while still having quad-station modules connected with the transfer chamber. To that end, the transfer chamber may be sized approximately the same size as the quad-station modules, which may naturally limit the size that the robot arm system located within the transfer chamber may have while in the retracted state. At the same time, such robot arm systems may, in some cases, be required to be able to have a reach that is roughly the same magnitude as the length or width of the transfer chamber or the adjacent QSM. In some implementations, in order to provide the necessary amount of reach while still allowing for the transfer chamber to be sized generally the same size as the adjacent QSM, the robot arm system may be designed to have certain structural characteristics that make efficient use of the available space within such a transfer module but still allow the robot arm system to attain the maximum reach needed to directly place wafers in any station of an adjacent QSM.

For example, when the torso unit of such a robot arm system rotates relative to the transfer chamber while the robot arm system is in the retracted state, the portion of the robot arm system (inclusive, in this case, of any wafers that can be carried thereby) that is furthest from the axis of rotation about which the torso unit is rotating may define a clearance circle (centered on the axis of rotation). This clearance circle must generally fit within the interior of the transfer chamber without intersecting any of the walls (or other portions) thereof. If the clearance circle were to intersect with the transfer chamber, then the portion of the robot arm system that defines the clearance circle could collide with the transfer chamber during rotation.

To aid in the following discussion. FIG. 49 is provided to show two top views of an example robot arm system in a transfer chamber adjacent to a QSM; in the left view, the robot arms are all in the retracted state, while the right view shows one pair of robot arms in the far extension state. Various parameters are indicated in FIG. 49 that are referenced below, e.g., the clearance circle discussed above.

The various arm links and end effectors (and the wafers that may be supported thereby) of the robot arm system must fit within the clearance circle when in the retracted state. The clearance circle thus generally acts to limit the maximum size of such components, which, in turn, has the practical effect of limiting the maximum reach of such a robot arm system. In some such robot arm system implementations, the robot arm links may be designed so as to have a maximum reach (far extension distance), when in the far-extension state, that is greater than or equal to the diameter of the clearance circle, e.g., 0%, up to 5%, up to 10%, up to 15%, up to 20% higher than the diameter of the clearance circle.

Another geometric characteristic of some such robot arm systems may be defined by a first reference circle and a second reference circle. The first reference circle may be centered on the torso unit's rotational axis and defined by the portions of the edges of wafers supported by the robot arm system (when in use to transport the wafers) that are farthest from the center of rotation of the torso unit when the robot arm system is in the retracted state. The second reference circle may also be centered on the torso unit's rotational axis and defined by the ends of the end effector support arms that are farthest from the center of rotation of the torso unit. It will be recognized that one or the other, or both, of the first and second reference circles may, in some cases, be co-radial with the clearance circle. In some implementations, the first reference circle and the second reference circle may have diameters that are within 5% or less, 4% or less, 3% or less, 2% or less, or 1% or less of one another (for example, if the first reference circle has a diameter of 1 unit, the second may have a diameter of (or between) 1.05 or 0.95 units). In some such implementations, at least one robot arm on each side of the torso unit may be configured such that the portions of the edges of a wafers supported thereby (when in use to transport the wafers) that are farthest from the center of rotation of the torso unit when the robot arm system is in the retracted state each define a corresponding first reference circle that is centered on the torso unit axis of rotation: furthermore, the at least one robot arm on each side of the torso unit may be further configured such that the end of the end effector support arm thereof that is farthest from the center of rotation of the torso unit defines a corresponding second reference circle centered on the rotation axis of the torso unit. In such an implementation, the at least two first reference circles and the at least two second reference circles may all have diameters that are within 5% or less, 4% or less, 3% or less, 2% or less, or 1% of each other. By configuring the end effectors and end effector support arms in such a manner, e.g., such that wafers supported thereby when the robot arms are in the retracted state have outer edges that are the same distance, or almost the same distance, away from the center of rotation of the torso unit as the outermost edges or surfaces of the end effector support arm, the length of the end effector support arms may make full use of the available space within the clearance circle. This allows the end effector support arm to have a length that is sufficient to provide the reach necessary for the robot arm system to be able to reach to the far pedestals in a QSM.

Yet another characteristic of robot arms systems such as those discussed herein that relates to the clearance circle is the ratio of the amount of extension that such robot arms are configured to provide in comparison to the diameter of the clearance circle thereof when in the retracted state. In some such implementations, such robot arm systems may be configured to, when in the far extension state, have extended from their positions in the retracted state by an amount that is greater than the diameter of the clearance circle. In some cases, the amount of extension that such arms may undergo when transiting from the retracted state to the far extension state may be as much as 105% or more, 110% or more, or 115% or more of the diameter of the clearance circle. In some such implementations, the entire rotational joint that connects the first link to the second link of a robot arm that is in the far extension state may lie entirely outside of the clearance circle. Such a characteristic may allow the robot arm to have a greater amount of reach that may facilitate reaching to the far pedestals in a QSM when in the far extension state.

Another characteristic of some of the robot arm systems discussed herein is that the arm links of such robot arm systems may be belt-driven systems that are capable of larger angular displacements than, for example, parallel-linkage-driven arm systems. For example, in some implementations that feature a first link that is rotatably connected with the torso unit and a second link that is rotatably connected with the first link and with an end effector support arm, the first link and the second link may be driven so as to rotate relative to one another by a total angle α+β of greater than 180°, e.g., greater than 200°. Similarly, the first links may be rotatable relative to the torso unit by angles γ greater than 90°, e.g., greater than 100°. Such high rotational angles may permit such robot arms to extend to a much greater extent than robot arms with lower angular movement capabilities.

Another characteristic of some of the robot arm systems discussed herein is that the rotational axes of the rotational joints that rotatably couple the first links with the torso unit may all lie in between a first reference plane and a second reference plane when such robot arm systems are in the retracted state. The first reference plane and the second reference plane may be parallel to each other, with the first reference plane being coincident with, and parallel to, the rotational axis of the torso unit, and the second reference plane passing through locations on the end effectors that coincide with the centers of wafers when such wafers are being transported by the end effectors. Thus, the rotational axes of such rotational joints may be thought of as being “forward” of the center of rotation of the torso unit with respect to a viewpoint looking through the axis of rotation of the torso unit and in the direction that the robot arms can be extended along. By configuring such arms to have such an offset, the lengths of the first and second links may be caused to be increased, thereby allowing for a greater amount of travel of the end effector support arms responsive to rotation of the first and second links.

Yet a further characteristic of some of the robot arm systems discussed herein is that a first length of the end effector support arm and end effector, as measured from the rotational axis about which the end effector support arm rotates relative to the second link of the robot arm to a location that coincides with the center of wafer when the wafer is being supported by the end effector, may be greater than a second length that represents the sum of the lengths, as measured between their respective rotational centers, of the first and second links of the robot arm. In some such implementations, the first length may be 5% or more greater than the second length. Such a characteristic may further facilitate enhancing the reach of such a robot arm system.

As discussed earlier, the robot arm systems discussed herein may be controlled by a controller. In some implementations, the controller may be included as part of a system, which may include or be part of the above-described examples. Such systems may include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), light source control for radiative heating, pressure settings, vacuum settings, power settings, radio frequency (RF) generator settings. RF matching circuit settings, frequency settings, flow rate settings, fluid delivery settings, positional and operation settings, wafer transfers into and out of a tool or chamber and other transfer tools and/or load locks connected to or interfaced with a specific system.

Broadly speaking, the controller may be defined as electronics having various integrated circuits, logic, memory devices, and/or software that store computer-executable instructions, receive computer-executable instructions, issue computer-executable instructions, execute computer-executable instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory. In particular, the controller may be configured to cause the robot arm systems disclosed herein, as well as lift pin mechanisms for pedestals, to undergo operations such as are described herein, particularly with respect to FIGS. 23 through 44.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “transitionable,” if used, will be understood to refer to a device or mechanism is that is specifically configured to be transitioned between two or more states or configurations. For example, a door would be transitionable between an open state or configuration and a closed state or configuration.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

It is to be further understood that the present disclosure encompasses at least the following non-exclusive list of implementations.
Implementation 1: A system comprising: a base; a torso unit rotatably connected with the base such that the torso unit is rotatable relative to the base about a main rotational axis; a pair of first robot arms supported by the torso unit; and a pair of second robot arms supported by the torso unit, wherein: the first robot arms are each configured to transition between at least a first retracted state, a first near-extension state, and a first far-extension state, a first distal location of each first robot arm that is furthest from the main rotational axis when that first robot arm is in the first far-extension state is closer to the main rotational axis when that first robot arm is in the first retracted state than when that first robot arm is in the first near-extension state, the first distal location of each first robot arm is closer to the main rotational axis when that first robot arm is in the first near-extension state than when that first robot arm is in the first far-extension state, the second robot arms are each configured to transition between at least a second retracted state, a second near-extension state, and a second far-extension state, a second distal location of each second robot arm that is furthest from the main rotational axis when that second robot arm is in the second far-extension state is closer to the main rotational axis when that second robot arm is in the second retracted state than when that second robot arm is in the second near-extension state, and the second distal location of each second robot arm is closer to the main rotational axis when that second robot arm is in the second near-extension state than when that second robot arm is in the second far-extension state.
Implementation 2: The system of implementation 1, wherein: each of the first robot arms is configured to support two wafers in an over/under configuration with one of the two wafers centered on a corresponding upper first location that is fixed with respect to a portion of that first robot arm that is configured to support the wafers and the other of the two wafers centered on a corresponding lower first location that is fixed with respect to the portion of that first robot arm that is configured to support the wafers, the upper first locations are each nominally centered over different first corners of a first square region when the first robot arms are at least in one of the first near-extension state or the first far-extension state, the lower first locations are each nominally centered over different second corners of the first square region different from the first corners of the first square region when the first robot arms are at least in the other of the first near-extension state or the first far-extension state, each of the second robot arms is configured to support two wafers in an over/under configuration with one of the two wafers centered on a corresponding upper second location that is fixed with respect to a portion of that second robot arm that is configured to support the wafers and the other of the two wafers centered on a corresponding lower second location that is fixed with respect to the portion of that second robot arm that is configured to support the wafers, the upper second locations are each nominally centered over different first corners of a second square region when the second robot arms are at least in one of the second near-extension state or the second far-extension state, the lower second locations are each nominally centered over different second corners of the second square region different from the first corners of the second square region when the second robot arms are at least in the other of the second near-extension state or the second far-extension state, and the first square region and the second square region are located in the same position and have the same orientation and the same size.
Implementation 3: The system of implementation 2, wherein the upper first location and the lower first location for at least one of the first robot arms both lie along a corresponding common vertical axis.
Implementation 4: The system of implementation 2, wherein the upper first location and the lower first location for at least one of the first robot arms both lie along different, non-coaxial vertical axes.
Implementation 5: The system of any one of implementations 1 through 4, wherein, for each first robot arm: that first robot arm has a corresponding first end effector support arm and a plurality of corresponding first arm links, the corresponding first arm links for that first robot arm including a corresponding first base link and one or more corresponding first intermediate arm links, the corresponding first base link for that first robot arm is rotatably connected with the torso unit such that the corresponding first base link for that first robot arm is rotatable relative to the torso unit about a corresponding first axis, and the corresponding first base link for that first robot arm supports the one or more corresponding first intermediate arm links and the one or more corresponding first base links for that first robot arm support the corresponding first end effector support arm for that first robot arm: and wherein, for each second robot arm: that second robot arm has a corresponding second end effector support arm and a plurality of corresponding second arm links, the corresponding second arm links for that second robot arm including a corresponding second base link and one or more corresponding second intermediate arm links, the corresponding second base link for that second robot arm is rotatably connected with the torso unit such that the corresponding second base link for that second robot arm is rotatable relative to the torso unit about a corresponding second axis, and the corresponding second base link for that second robot arm supports the one or more corresponding second intermediate arm links and the one or more corresponding second base links for that second robot arm support the corresponding second end effector support arm for that second robot arm, wherein: the first axes and the second axes are all substantially parallel to one another, the first axes are spaced apart from one another in directions perpendicular to the first axes, and the second axes are spaced apart from one another in directions perpendicular to the second axes.
Implementation 6: The system of implementation 5, wherein: each first robot arm is configured to cause the corresponding first end effector support arm for that first robot arm to translate along a corresponding translation axis relative to the torso unit responsive, at least in part, to rotation of the first base link for that first robot arm relative to the torso unit, each second robot arm is configured to cause the corresponding second end effector support arm for that second robot arm to translate along a corresponding translation axis relative to the torso unit responsive, at least in part, to rotation of the second base link for that second robot arm relative to the torso unit, and the translation axes of the first robot arms and the second robot arms are all substantially parallel with one another.
Implementation 7: The system of either implementation 5 or implementation 6, wherein: the first arm links in the plurality of corresponding first arm links for each of the first robot arms are configured to rotate relative to one another about corresponding rotational axes substantially parallel to the first axes, the first end effector support arm for each of the first robot arms is configured to rotate about a corresponding rotational axis relative to the corresponding first intermediate arm link of that first robot arm closest thereto, wherein that corresponding rotational axis is substantially parallel to the first axes, the second arm links in the plurality of corresponding second arm links for each of the second robot arms are configured to rotate relative to one another about corresponding rotational axes substantially parallel to the second axes, and the second end effector support arm for each of the second robot arms is configured to rotate about a corresponding rotational axis relative to the corresponding second intermediate arm link of that second robot arm closest thereto, wherein that corresponding rotational axis is substantially parallel to the second axes.
Implementation 8: The system of implementation 7, wherein each first robot arm has two corresponding first arm links and each second robot arm has two corresponding second arm links.
Implementation 9: The system of implementation 8, wherein: each of the first base links has a corresponding first base link length defined by the distance between the first axis and the corresponding rotational axis about which the corresponding first intermediate arm link is configured to rotate relative to that first base link, each of the first intermediate arm links has a corresponding first intermediate arm link length defined by the distance between the corresponding rotational axis about which that first intermediate arm link is configured to rotate relative to the corresponding first base link and the corresponding rotational axis that the corresponding first end effector support arm is configured to rotate relative to that first intermediate arm link, each of the second base links has a corresponding second base link length defined by the distance between the second axis and the corresponding rotational axis about which the corresponding second intermediate arm link is configured to rotate relative to that second base link, each of the second intermediate arm links has a corresponding second intermediate arm link length defined by the distance between the corresponding rotational axis about which that second intermediate arm link is configured to rotate relative to the corresponding second base link and the corresponding rotational axis that the corresponding second end effector support arm is configured to rotate relative to that second intermediate arm link, the first base link length and the first intermediate arm link length for at least one of the first robot arms are equal, and the second base link length and the second intermediate arm link length for at least one of the second robot arms are equal.
Implementation 10: The system of implementation 9, wherein: the first base link length and the first intermediate arm link length for at least one of the first robot arms are equal to each other, the second base link length and the second intermediate arm link length for at least one of the second robot arms are equal to each other, and the first base link length is longer than the second base link length.
Implementation 11: The system of implementation 9, wherein: the first base link length and the first intermediate arm link length for at least one of the first robot arms are equal to each other and to the second base link length and the second intermediate arm link length for at least one of the second robot arms.
Implementation 12: The system of implementation 9, wherein: the first base link length and the first intermediate arm link length for both of the first robot arms are equal, and the second base link length and the second intermediate arm link length for both of the second robot arms are equal.
Implementation 13: The system of implementation 12, wherein the first base link length and the first intermediate arm link length for both of the first robot arms and the second base link length and the second intermediate arm link length for both of the second robot arms are all equal.
Implementation 14: The system of either of implementations 11 or 13, wherein: the first base link length, the second base link length, the first intermediate arm link length, and the second intermediate arm link length for a first pair of the first and second robot arms located on a common side of a reference plane of the torso unit that is coplanar with the main rotation axis and interposed between both of the first robot arms are all the same, the first axis and the second axis of the first pair of the first and second robot arms are coaxial, the first base link of the first robot arm of the first pair of the first and second robot arms is fixed in space with respect to a corresponding first inner bypass portion, the first intermediate arm link of the first robot arm of the first pair of the first and second robot arms is fixed in space with respect to a corresponding first outer bypass portion, the first inner bypass portion includes a corresponding first portion that is fixedly connected with the first base link of the first robot arm of the first pair of the first and second robot arms, a corresponding second portion that is rotatably connected with the first intermediate arm link of the first robot arm of the first pair of the first and second robot arms, and a corresponding bridging portion that spans between the corresponding first portion and the corresponding second portion of the first inner bypass portion and that is positioned such that the corresponding bridging portion of the first inner bypass portion is positioned further from the first axis of the first robot arm of the first pair of the first and second robot arms than the corresponding rotational axis about which the corresponding first intermediate arm link of the first robot arm of the first pair of the first and second robot arms is configured to rotate relative to the first base link of the first robot arm of the first pair of the first and second robot arms, the first outer bypass portion includes a corresponding first portion that is rotatably connected with the first base link of the first robot arm of the first pair of the first and second robot arms, a corresponding second portion that is fixedly connected with the first intermediate arm link of the first robot arm of the first pair of the first and second robot arms, and a corresponding bridging portion that spans between the corresponding first portion and the corresponding second portion of the first outer bypass portion and that is positioned such that the corresponding bridging portion of the first outer bypass portion is positioned further from the first axis of the first robot arm of the first pair of the first and second robot arms than the corresponding bridging portion of the first inner bypass portion when the first robot arm of the first pair of the first and second robot arms is in the first retracted state.
Implementation 15: The system of implementation 14, wherein: the first base link length, the second base link length, the first intermediate arm link length, and the second intermediate arm link length for a second pair of the first and second robot arms located on an opposite side of the reference plane of the torso unit are all the same, the first axis and the second axis of the second pair of the first and second robot arms are coaxial, the first base link of the first robot arm of the second pair of the first and second robot arms is fixed in space with respect to a corresponding second inner bypass portion, the first intermediate arm link of the first robot arm of the second pair of the first and second robot arms is fixed in space with respect to a corresponding second outer bypass portion, the second inner bypass portion includes a corresponding first portion that is fixedly connected with the first base link of the first robot arm of the second pair of the first and second robot arms, a corresponding second portion that is rotatably connected with the first intermediate arm link of the first robot arm of the second pair of the first and second robot arms, and a corresponding bridging portion that spans between the corresponding first portion and the corresponding second portion of the second inner bypass portion and that is positioned such that the corresponding bridging portion of the second inner bypass portion is positioned further from the first axis of the first robot arm of the second pair of the first and second robot arms than the corresponding rotational axis about which the corresponding first intermediate arm link of the first robot arm of the second pair of the first and second robot arms is configured to rotate relative to the first base link of the first robot arm of the second pair of the first and second robot arms, and the second outer bypass portion includes a corresponding first portion that is rotatably connected with the first base link of the first robot arm of the second pair of the first and second robot arms, a corresponding second portion that is fixedly connected with the first intermediate arm link of the first robot arm of the second pair of the first and second robot arms, and a corresponding bridging portion that spans between the corresponding first portion and the corresponding second portion of the second outer bypass portion and that is positioned such that the corresponding bridging portion of the second outer bypass portion is positioned further from the first axis of the first robot arm of the second pair of the first and second robot arms than the corresponding bridging portion of the second inner bypass portion when the first robot arm of the second pair of the first and second robot arms is in the first retracted state.
Implementation 16: The system of implementation 15, wherein the first pair of first and second robot arms and the second pair of first and second robot arms are arranged symmetrically with respect to the reference plane.
Implementation 17: The system of any one of implementations 9 or 11 through 13, wherein the first axes are spaced apart by a distance that is different than a distance that the second axes are spaced apart by.
Implementation 18: The system of any one of implementations 1 through 17, wherein: the first end effector support arms each have a corresponding first portion, a corresponding second portion, and a corresponding offset jog portion; the corresponding first portion and the corresponding second portion of each of the first end effector support arms extend along parallel axes that are offset from one another in a direction perpendicular to those parallel axes, and the corresponding offset jog portion of each of the first end effector support arms spans between the corresponding first portion and the corresponding second portion of that first end effector support arm.
Implementation 19: The system of implementation 18, wherein: the second end effector support arms each have a corresponding first portion, a corresponding second portion, and a corresponding offset jog portion; the corresponding first portion and the corresponding second portion of each of the second end effector support arms extend along parallel axes that are offset from one another in a direction perpendicular to those parallel axes, and the corresponding offset jog portion of each of the second end effector support arms spans between the corresponding first portion and the corresponding second portion of that second end effector support arm.
Implementation 20: The system of any one of implementations 1 through 19, further comprising a transfer chamber, wherein: the base is fixedly mounted with respect to the transfer chamber, the torso unit is located at least partially within the transfer chamber, the first robot arms are located entirely within the transfer chamber when in the first retracted state, the second robot arms are located entirely within the transfer chamber when in the second retracted state, and the torso unit, along with the first robot arms and the second robot arms, is rotatable by at least 90° within and relative to the transfer chamber when the first robot arms are in the first retracted state and the second robot arms are in the second retracted state.
Implementation 21: The system of implementation 20, further comprising one or more multi-station processing chambers, wherein: each multi-station processing chamber is connected with the transfer chamber by one or more corresponding wafer transfer passages, each multi-station processing chamber has a corresponding pair of near pedestals that are closer to the transfer chamber and a corresponding pair of far pedestals that are farther from the transfer chamber, the first robot arms are configured to transfer wafers to the corresponding pair of near pedestals of each of the multi-station processing chambers when the torso unit is rotated to align the first robot arms with the one or more corresponding wafer transfer passages of that multi-station processing chamber and the first robot arms are in the first near-extension state, the first robot arms are configured to transfer wafers to the corresponding pair of far pedestals of each of the multi-station processing chambers when the torso unit is rotated to align the first robot arms with the one or more corresponding wafer transfer passages of that multi-station processing chamber and the first robot arms are in the first far-extension state, the second robot arms are configured to transfer wafers to the corresponding pair of near pedestals of each of the multi-station processing chambers when the torso unit is rotated to align the second robot arms with the one or more corresponding wafer transfer passages of that multi-station processing chamber and the second robot arms are in the second near-extension state, and the second robot arms are configured to transfer wafers to the corresponding pair of far pedestals of each of the multi-station processing chambers when the torso unit is rotated to align the second robot arms with the one or more corresponding wafer transfer passages of that multi-station processing chamber and the second robot arms are in the second far-extension state.
Implementation 22: The system of implementation 21, wherein each multi-station processing chamber is a quad-station module.
Implementation 23: The system of either implementation 21 or implementation 22, further comprising one or more active wafer centering sensor systems, each configured to obtain center location measurements of wafers transported through one of the wafer transfer passages by the first robot arms and/or the second robot arms.
Implementation 24: The system of any one of implementations 1 through 22, further comprising a controller including one or more memory devices and one or more processors. the one or more memory devices storing computer-executable instructions which, when executed by the one or more processors, cause the one or more processors to cause: a) the first robot arms to transition from the first retracted state to the first far-extension state while each supporting a pair of wafers, b) the first robot arms to remain in the first far-extension state while bottom wafers supported by the first robot arms are lifted off of the first robot arms, c) the first robot arms to transition from the first far-extension state to the first near-extension state after (b) and while each supporting the wafer of the pair of wafers supported by that first robot arm that was not removed in (b), d) the first robot arms to remain in the first near-extension state while upper wafers supported by the first robot arms are lifted off of the first robot arms, and e) the first robot arms to transition from the first near-extension state to the first retracted state after (d) and while each supporting no wafer.
Implementation 25: The system of implementation 24, wherein the one or more memory devices further store computer-executable instructions which, when executed by the one or more processors, cause the one or more processors to cause, sequentially: the torso unit to rotate, at least one of the first robot arms to extend or retract, or the torso unit to rotate and the at least one of the first robot arms to extend or retract so as to center one of the wafers lifted off the first robot arms during (b) on a first far target location prior to lifting that wafer off of the first robot arm supporting that wafer at the start of (b), and the torso unit to rotate, at least the other of the first robot arms to extend or retract, or the torso unit to rotate and the at least the other of the first robot arms to extend or retract so as to center the other of the wafers lifted off the first robot arms during (b) on a second far target location prior to lifting that wafer off of the first robot arm supporting that wafer at the start of (b).
Implementation 26: The system of implementation 24, wherein the one or more memory devices further store computer-executable instructions which, when executed by the one or more processors, cause the one or more processors to cause, at least partially simultaneously: one of the first robot arms to adjust an amount of extension thereof, an amount of rotation thereof relative to the torso unit, or an amount of extension thereof and an amount of rotation thereof relative to the torso unit so as to center one of the wafers lifted off the first robot arms during (b) on a first far target location prior to lifting that wafer off of the first robot arm supporting that wafer at the start of (b), and the other of the first robot arms to adjust an amount of extension thereof, an amount of rotation thereof relative to the torso unit, or an amount of extension thereof and an amount of rotation thereof relative to the torso unit so as to center the other of the wafers lifted off the first robot arms during (b) on a second far target location prior to lifting that wafer off of the first robot arm supporting that wafer at the start of (b).
Implementation 27: The system of implementation 24, wherein the one or more memory devices further store computer-executable instructions which, when executed by the one or more processors, cause the one or more processors to cause, at least partially simultaneously: one of the first robot arms to adjust an amount of extension thereof, an amount of rotation thereof relative to the torso unit, or an amount of extension thereof and an amount of rotation thereof relative to the torso unit so as to center one of the wafers lifted off the first robot arms during (b) on a first far target location prior to lifting that wafer off of the first robot arm supporting that wafer at the start of (b), and the torso unit to rotate, at least the other of the first robot arms to extend or retract, or the torso unit to rotate and the at least the other of the first robot arms to extend or retract so as to center the other of the wafers lifted off the first robot arms during (b) on a second far target location prior to lifting that wafer off of the first robot arm supporting that wafer at the start of (b).
Implementation 28: The system of any one of implementations 24 through 26, wherein the one or more memory devices further store computer-executable instructions which, when executed by the one or more processors, cause the one or more processors to cause: f) the first robot arms to transition from the first retracted state to the first near-extension state while each supporting no wafers, g) the first robot arms to remain in the first near-extension state while each of the first robot arms has a corresponding wafer placed thereupon, h) the first robot arms to transition from the first near-extension state to the first far-extension state after (g) and while each supports the single wafer placed thereupon in (g), i) the first robot arms to remain in the first far-extension state while each of the first robot arms has another wafer placed thereupon and in a location beneath the wafer already supported by that first robot arm, and j) the first robot arms to transition from the first far-extension state to the first retracted state after (i) and while each supporting the two wafers placed thereupon.
Implementation 29: The system of any one of implementations 24 through 28, wherein the one or more memory devices further store computer-executable instructions which, when executed by the one or more processors, cause the one or more processors to cause: 1) the second robot arms to transition from the second retracted state to the second far-extension state while each supporting a pair of wafers, 2) the second robot arms to remain in the second far-extension state while bottom wafers supported by the second robot arms are lifted off of the second robot arms, 3) the second robot arms to transition from the second far-extension state to the second near-extension state after (2) and while each supporting the wafer of the pair of wafers supported by that second robot arm that was not removed in (2), 4) the second robot arms to remain in the second near-extension state while upper wafers supported by the second robot arms are lifted off of the second robot arms, and 5) the second robot arms to transition from the second near-extension state to the second retracted state after (4) and while each supporting no wafer.
Implementation 30: The system of implementation 29, wherein the one or more memory devices further store computer-executable instructions which, when executed by the one or more processors, cause the one or more processors to cause, sequentially: the torso unit to rotate, at least one of the second robot arms to extend or retract, or the torso unit to rotate and the at least one of the second robot arms to extend or retract so as to center one of the wafers lifted off the second robot arms during (2) on a first far target location prior to lifting that wafer off of the second robot arm supporting that wafer at the start of (2), and the torso unit to rotate, at least the other of the second robot arms to extend or retract, or the torso unit to rotate and the at least the other of the second robot arms to extend or retract so as to center the other of the wafers lifted off the second robot arms during (2) on a second far target location prior to lifting that wafer off of the second robot arm supporting that wafer at the start of (2).
Implementation 31: The system of implementation 29, wherein the one or more memory devices further store computer-executable instructions which, when executed by the one or more processors, cause the one or more processors to cause, at least partially simultaneously: one of the second robot arms to adjust an amount of extension thereof, an amount of rotation thereof relative to the torso unit, or an amount of extension thereof and an amount of rotation thereof relative to the torso unit so as to center one of the wafers lifted off the second robot arms during (2) on a first far target location prior to lifting that wafer off of the second robot arm supporting that wafer at the start of (2), and
the other of the second robot arms to adjust an amount of extension thereof, an amount of rotation thereof relative to the torso unit, or an amount of extension thereof and an amount of rotation thereof relative to the torso unit so as to center the other of the wafers lifted off the second robot arms during (2) on a second far target location prior to lifting that wafer off of the second robot arm supporting that wafer at the start of (2).
Implementation 32: The system of implementation 24, wherein the one or more memory devices further store computer-executable instructions which, when executed by the one or more processors, cause the one or more processors to cause, at least partially simultaneously: one of the second robot arms to adjust an amount of extension thereof, an amount of rotation thereof relative to the torso unit, or an amount of extension thereof and an amount of rotation thereof relative to the torso unit so as to center one of the wafers lifted off the second robot arms during (2) on a first far target location prior to lifting that wafer off of the second robot arm supporting that wafer at the start of (2), and the torso unit to rotate, at least the other of the second robot arms to extend or retract, or the torso unit to rotate and the at least the other of the second robot arms to extend or retract so as to center the other of the wafers lifted off the second robot arms during (2) on a second far target location prior to lifting that wafer off of the second robot arm supporting that wafer at the start of (2).
Implementation 33: The system of either implementation 24 or implementation 25, wherein the one or more memory devices further store computer-executable instructions which, when executed by the one or more processors, cause the one or more processors to cause: 6) the second robot arms to transition from the second retracted state to the second near-extension state while each supporting no wafers, 7) the second robot arms to remain in the second near-extension state while each of the second robot arms has a corresponding wafer placed thereupon, 8) the second robot arms to transition from the second near-extension state to the second far-extension state after (7) and while each supports the single wafer placed thereupon in (7), 9) the second robot arms to remain in the second far-extension state while each of the second robot arms has another wafer placed thereupon and in a location beneath the wafer already supported by that second robot arm, and 10) the second robot arms to transition from the second far-extension state to the second retracted state after (9) and while each supporting the two wafers placed thereupon.
Implementation 34: A system comprising: a base; a torso unit rotatably connected with the base such that the torso unit is rotatable relative to the base about a main rotational axis; and a pair of robot arms supported by the torso unit, wherein: the robot arms are each configured to transition between at least a retracted state, a near-extension state, and a far-extension state, a distal location of each robot arm that is furthest from the main rotational axis when that robot arm is in the far-extension state is closer to the main rotational axis when that robot arm is in the retracted state than when that robot arm is in the near-extension state, and the distal location of each robot arm is closer to the main rotational axis when that robot arm is in the near-extension state than when that robot arm is in the far-extension state.
Implementation 35: The system of implementation 34, wherein: each of the robot arms is configured to support two wafers in an over/under configuration with one of the two wafers centered on a corresponding upper location that is fixed with respect to a portion of that robot arm that is configured to support the wafers and the other of the two wafers centered on a corresponding lower location that is fixed with respect to the portion of that robot arm that is configured to support the wafers, the upper locations are each nominally centered over different first corners of a square region when the robot arms are at least in one of the near-extension state or the far-extension state, and the lower locations are each nominally centered over different second corners of the square region different from the first corners of the square region when the robot arms are at least in the other of the near-extension state or the far-extension state.
Implementation 36: The system of implementation 35, wherein the upper location and the lower location for at least one of the robot arms both lie along a corresponding common vertical axis.
Implementation 37: The system of implementation 35, wherein the upper location and the lower location for at least one of the robot arms both lie along different, non-coaxial vertical axes.
Implementation 38: The system of any one of implementations 34 through 37, wherein, for each robot arm: that robot arm has a corresponding end effector support arm and a plurality of corresponding arm links, the corresponding arm links for that robot arm including a corresponding base link and one or more corresponding intermediate arm links, the corresponding base link for that robot arm is rotatably connected with the torso unit such that the corresponding base link for that robot arm is rotatable relative to the torso unit about a corresponding first axis, and the corresponding base link for that robot arm supports the one or more corresponding intermediate arm links and the one or more corresponding base links for that robot arm support the corresponding end effector support arm for that robot arm, and wherein: the first axes are substantially parallel to one another and spaced apart from one another in directions perpendicular to the first axes.
Implementation 39: The system of implementation 38, wherein: each robot arm is configured to cause the corresponding end effector support arm for that robot arm to translate along a corresponding translation axis relative to the torso unit responsive, at least in part, to rotation of the base link for that robot arm relative to the torso unit, and the translation axes of the robot arms are substantially parallel with one another.
Implementation 40: The system of either implementation 38 or implementation 39, wherein: the arm links in the plurality of corresponding arm links for each of the robot arms are configured to rotate relative to one another about corresponding rotational axes substantially parallel to the first axes, and the end effector support arm for each of the robot arms is configured to rotate about a corresponding rotational axis relative to the corresponding intermediate arm link of that robot arm closest thereto, wherein that corresponding rotational axis is substantially parallel to the first axes.
Implementation 41: The system of implementation 40, wherein each robot arm has two corresponding arm links.
Implementation 42: The system of implementation 41, wherein: each of the base links has a corresponding base link length defined by the distance between the first axis and the corresponding rotational axis about which the corresponding intermediate arm link is configured to rotate relative to that base link, each of the intermediate arm links has a corresponding intermediate arm link length defined by the distance between the corresponding rotational axis about which that intermediate arm link is configured to rotate relative to the corresponding base link and the corresponding rotational axis that the corresponding end effector support arm is configured to rotate relative to that intermediate arm link, and the base link lengths and the intermediate arm link lengths are equal.
Implementation 43: The system of any one of implementations 34 through 42, wherein the robot arms are arranged symmetrically with respect to a reference plane.
Implementation 44: The system of any one of implementations 34 through 43, wherein: the end effector support arms each have a corresponding first portion, a corresponding second portion, and a corresponding offset jog portion: the corresponding first portion and the corresponding second portion of each of the end effector support arms extend along parallel axes that are offset from one another in a direction perpendicular to those parallel axes, and the corresponding offset jog portion of each of the end effector support arms spans between the corresponding first portion and the corresponding second portion of that end effector support arm.
Implementation 45: The system of any one of implementations 34 through 44, further comprising a transfer chamber, wherein: the base is fixedly mounted with respect to the transfer chamber, the torso unit is located at least partially within the transfer chamber, the robot arms are located entirely within the transfer chamber when in the retracted state, and the torso unit, along with the robot arms, is rotatable by at least 90° within and relative to the transfer chamber when the robot arms are in the retracted state.
Implementation 46: The system of implementation 45, further comprising one or more multi-station processing chambers, wherein: each multi-station processing chamber is connected with the transfer chamber by one or more corresponding wafer transfer passages, each multi-station processing chamber has a corresponding pair of near pedestals that are closer to the transfer chamber and a corresponding pair of far pedestals that are farther from the transfer chamber, the robot arms are configured to transfer wafers to the corresponding pair of near pedestals of each of the multi-station processing chambers when the torso unit is rotated to align the robot arms with the one or more corresponding wafer transfer passages of that multi-station processing chamber and the robot arms are in the near-extension state, and the robot arms are configured to transfer wafers to the corresponding pair of far pedestals of each of the multi-station processing chambers when the torso unit is rotated to align the robot arms with the one or more corresponding wafer transfer passages of that multi-station processing chamber and the robot arms are in the far-extension state.
Implementation 47: The system of implementation 46, wherein each multi-station processing chamber is a quad-station module.
Implementation 48: The system of either implementation 46 or implementation 47, further comprising one or more active wafer centering sensor systems, each configured to obtain center location measurements of wafers transported through one of the wafer transfer passages by the robot arms.
Implementation 49: The system of any one of implementations 34 through 47, further comprising a controller including one or more memory devices and one or more processors, the one or more memory devices storing computer-executable instructions which, when executed by the one or more processors, cause the one or more processors to cause: a) the robot arms to transition from the retracted state to the far-extension state while each supporting a pair of wafers, b) the robot arms to remain in the far-extension state while bottom wafers supported by the robot arms are lifted off of the robot arms, c) the robot arms to transition from the far-extension state to the near-extension state after (b) and while each supporting the wafer of the pair of wafers supported by that robot arm that was not removed in (b), d) the robot arms to remain in the near-extension state while upper wafers supported by the robot arms are lifted off of the robot arms, and e) the robot arms to transition from the near-extension state to the retracted state after (d) and while each supporting no wafer.
Implementation 50: The system of implementation 49, wherein the one or more memory devices further store computer-executable instructions which, when executed by the one or more processors, cause the one or more processors to cause, sequentially: the torso unit to rotate, at least one of the robot arms to extend or retract, or the torso unit to rotate and the at least one of the robot arms to extend or retract so as to center one of the wafers lifted off the robot arms during (b) on a first far target location prior to lifting that wafer off of the robot arm supporting that wafer at the start of (b), and the torso unit to rotate, at least the other of the robot arms to extend or retract, or the torso unit to rotate and the at least the other of the robot arms to extend or retract so as to center the other of the wafers lifted off the robot arms during (b) on a second far target location prior to lifting that wafer off of the robot arm supporting that wafer at the start of (b).
Implementation 51: The system of implementation 49, wherein the one or more memory devices further store computer-executable instructions which, when executed by the one or more processors, cause the one or more processors to cause, at least partially simultaneously: one of the robot arms to adjust an amount of extension thereof, an amount of rotation thereof relative to the torso unit, or an amount of extension thereof and an amount of rotation thereof relative to the torso unit so as to center one of the wafers lifted off the robot arms during (b) on a first far target location prior to lifting that wafer off of the robot arm supporting that wafer at the start of (b), and the other of the robot arms to adjust an amount of extension thereof, an amount of rotation thereof relative to the torso unit, or an amount of extension thereof and an amount of rotation thereof relative to the torso unit so as to center the other of the wafers lifted off the robot arms during (b) on a second far target location prior to lifting that wafer off of the robot arm supporting that wafer at the start of (b).
Implementation 52: The system of implementation 49, wherein the one or more memory devices further store computer-executable instructions which, when executed by the one or more processors, cause the one or more processors to cause, at least partially simultaneously: one of the robot arms to adjust an amount of extension thereof, an amount of rotation thereof relative to the torso unit, or an amount of extension thereof and an amount of rotation thereof relative to the torso unit so as to center one of the wafers lifted off the robot arms during (b) on a first far target location prior to lifting that wafer off of the robot arm supporting that wafer at the start of (b), and the torso unit to rotate, at least the other of the robot arms to extend or retract, or the torso unit to rotate and the at least the other of the robot arms to extend or retract so as to center the other of the wafers lifted off the robot arms during (b) on a second far target location prior to lifting that wafer off of the robot arm supporting that wafer at the start of (b).
Implementation 53: The system of any one of implementations 49 through 52, wherein the one or more memory devices further store computer-executable instructions which, when executed by the one or more processors, cause the one or more processors to cause: f) the robot arms to transition from the retracted state to the near-extension state while each supporting no wafers, g) the robot arms to remain in the near-extension state while each of the robot arms has a corresponding wafer placed thereupon, h) the robot arms to transition from the near-extension state to the far-extension state after (g) and while each supports the single wafer placed thereupon in (g), i) the robot arms to remain in the far-extension state while each of the robot arms has another wafer placed thereupon and in a location beneath the wafer already supported by that robot arm, and j) the robot arms to transition from the far-extension state to the retracted state after (i) and while each supporting the two wafers placed thereupon.

1. A system comprising:
a base;
a torso unit rotatably connected with the base such that the torso unit is rotatable relative to the base about a main rotational axis;
a pair of first robot arms supported by the torso unit; and
a pair of second robot arms supported by the torso unit, wherein:
the first robot arms are each configured to transition between at least a first retracted state, a first near-extension state, and a first far-extension state,
a first distal location of each first robot arm that is furthest from the main rotational axis when that first robot arm is in the first far-extension state is closer to the main rotational axis when that first robot arm is in the first retracted state than when that first robot arm is in the first near-extension state,
the first distal location of each first robot arm is closer to the main rotational axis when that first robot arm is in the first near-extension state than when that first robot arm is in the first far-extension state,
the second robot arms are each configured to transition between at least a second retracted state, a second near-extension state, and a second far-extension state,
a second distal location of each second robot arm that is furthest from the main rotational axis when that second robot arm is in the second far-extension state is closer to the main rotational axis when that second robot arm is in the second retracted state than when that second robot arm is in the second near-extension state, and
the second distal location of each second robot arm is closer to the main rotational axis when that second robot arm is in the second near-extension state than when that second robot arm is in the second far-extension state.

2. The system of claim 1, wherein:
each of the first robot arms is configured to support two wafers in an over/under configuration with one of the two wafers centered on a corresponding upper first location that is fixed with respect to a portion of that first robot arm that is configured to support the wafers and the other of the two wafers centered on a corresponding lower first location that is fixed with respect to the portion of that first robot arm that is configured to support the wafers,
the upper first locations are each nominally centered over different first corners of a first square region when the first robot arms are at least in one of the first near-extension state or the first far-extension state,
the lower first locations are each nominally centered over different second corners of the first square region different from the first corners of the first square region when the first robot arms are at least in the other of the first near-extension state or the first far-extension state,
each of the second robot arms is configured to support two wafers in an over/under configuration with one of the two wafers centered on a corresponding upper second location that is fixed with respect to a portion of that second robot arm that is configured to support the wafers and the other of the two wafers centered on a corresponding lower second location that is fixed with respect to the portion of that second robot arm that is configured to support the wafers,
the upper second locations are each nominally centered over different first corners of a second square region when the second robot arms are at least in one of the second near-extension state or the second far-extension state,
the lower second locations are each nominally centered over different second corners of the second square region different from the first corners of the second square region when the second robot arms are at least in the other of the second near-extension state or the second far-extension state, and
the first square region and the second square region are located in the same position and have the same orientation and the same size.

3. The system of claim 2, wherein the upper first location and the lower first location for at least one of the first robot arms both lie along a corresponding common vertical axis.

4. The system of claim 2, wherein the upper first location and the lower first location for at least one of the first robot arms both lie along different, non-coaxial vertical axes.

5. The system of any one of claim 1,
wherein, for each first robot arm:
that first robot arm has a corresponding first end effector support arm and a plurality of corresponding first arm links, the corresponding first arm links for that first robot arm including a corresponding first base link and one or more corresponding first intermediate arm links,
the corresponding first base link for that first robot arm is rotatably connected with the torso unit such that the corresponding first base link for that first robot arm is rotatable relative to the torso unit about a corresponding first axis, and
the corresponding first base link for that first robot arm supports the one or more corresponding first intermediate arm links and the one or more corresponding first base links for that first robot arm support the corresponding first end effector support arm for that first robot arm; and
wherein, for each second robot arm:
that second robot arm has a corresponding second end effector support arm and a plurality of corresponding second arm links, the corresponding second arm links for that second robot arm including a corresponding second base link and one or more corresponding second intermediate arm links,
the corresponding second base link for that second robot arm is rotatably connected with the torso unit such that the corresponding second base link for that second robot arm is rotatable relative to the torso unit about a corresponding second axis, and
the corresponding second base link for that second robot arm supports the one or more corresponding second intermediate arm links and the one or more corresponding second base links for that second robot arm support the corresponding second end effector support arm for that second robot arm, wherein:
the first axes and the second axes are all substantially parallel to one another,
the first axes are spaced apart from one another in directions perpendicular to the first axes, and
the second axes are spaced apart from one another in directions perpendicular to the second axes.

6. The system of claim 5, wherein:
each first robot arm is configured to cause the corresponding first end effector support arm for that first robot arm to translate along a corresponding translation axis relative to the torso unit responsive, at least in part, to rotation of the first base link for that first robot arm relative to the torso unit,
each second robot arm is configured to cause the corresponding second end effector support arm for that second robot arm to translate along a corresponding translation axis relative to the torso unit responsive, at least in part, to rotation of the second base link for that second robot arm relative to the torso unit, and
the translation axes of the first robot arms and the second robot arms are all substantially parallel with one another.

7. The system of claim 5, wherein:
the first arm links in the plurality of corresponding first arm links for each of the first robot arms are configured to rotate relative to one another about corresponding rotational axes substantially parallel to the first axes,
the first end effector support arm for each of the first robot arms is configured to rotate about a corresponding rotational axis relative to the corresponding first intermediate arm link of that first robot arm closest thereto, wherein that corresponding rotational axis is substantially parallel to the first axes,
the second arm links in the plurality of corresponding second arm links for each of the second robot arms are configured to rotate relative to one another about corresponding rotational axes substantially parallel to the second axes, and
the second end effector support arm for each of the second robot arms is configured to rotate about a corresponding rotational axis relative to the corresponding second intermediate arm link of that second robot arm closest thereto, wherein that corresponding rotational axis is substantially parallel to the second axes.

8. The system of claim 7, wherein each first robot arm has two corresponding first arm links and each second robot arm has two corresponding second arm links.

9. The system of claim 8, wherein:
each of the first base links has a corresponding first base link length defined by the distance between the first axis and the corresponding rotational axis about which the corresponding first intermediate arm link is configured to rotate relative to that first base link,
each of the first intermediate arm links has a corresponding first intermediate arm link length defined by the distance between the corresponding rotational axis about which that first intermediate arm link is configured to rotate relative to the corresponding first base link and the corresponding rotational axis that the corresponding first end effector support arm is configured to rotate relative to that first intermediate arm link,
each of the second base links has a corresponding second base link length defined by the distance between the second axis and the corresponding rotational axis about which the corresponding second intermediate arm link is configured to rotate relative to that second base link,
each of the second intermediate arm links has a corresponding second intermediate arm link length defined by the distance between the corresponding rotational axis about which that second intermediate arm link is configured to rotate relative to the corresponding second base link and the corresponding rotational axis that the corresponding second end effector support arm is configured to rotate relative to that second intermediate arm link,
the first base link length and the first intermediate arm link length for at least one of the first robot arms are equal, and
the second base link length and the second intermediate arm link length for at least one of the second robot arms are equal.

10. The system of claim 9, wherein:
the first base link length and the first intermediate arm link length for at least one of the first robot arms are equal to each other,
the second base link length and the second intermediate arm link length for at least one of the second robot arms are equal to each other, and
the first base link length is longer than the second base link length.

11. The system of claim 9, wherein:
the first base link length and the first intermediate arm link length for at least one of the first robot arms are equal to each other and to the second base link length and the second intermediate arm link length for at least one of the second robot arms.

12. The system of claim 9, wherein:
the first base link length and the first intermediate arm link length for both of the first robot arms are equal, and
the second base link length and the second intermediate arm link length for both of the second robot arms are equal.

13. The system of claim 12, wherein the first base link length and the first intermediate arm link length for both of the first robot arms and the second base link length and the second intermediate arm link length for both of the second robot arms are all equal.

14. The system of claim 11, wherein:
the first base link length, the second base link length, the first intermediate arm link length, and the second intermediate arm link length for a first pair of the first and second robot arms located on a common side of a reference plane of the torso unit that is coplanar with the main rotation axis and interposed between both of the first robot arms are all the same,
the first axis and the second axis of the first pair of the first and second robot arms are coaxial,
the first base link of the first robot arm of the first pair of the first and second robot arms is fixed in space with respect to a corresponding first inner bypass portion,
the first intermediate arm link of the first robot arm of the first pair of the first and second robot arms is fixed in space with respect to a corresponding first outer bypass portion,
the first inner bypass portion includes a corresponding first portion that is fixedly connected with the first base link of the first robot arm of the first pair of the first and second robot arms, a corresponding second portion that is rotatably connected with the first intermediate arm link of the first robot arm of the first pair of the first and second robot arms, and a corresponding bridging portion that spans between the corresponding first portion and the corresponding second portion of the first inner bypass portion and that is positioned such that the corresponding bridging portion of the first inner bypass portion is positioned further from the first axis of the first robot arm of the first pair of the first and second robot arms than the corresponding rotational axis about which the corresponding first intermediate arm link of the first robot arm of the first pair of the first and second robot arms is configured to rotate relative to the first base link of the first robot arm of the first pair of the first and second robot arms,
the first outer bypass portion includes a corresponding first portion that is rotatably connected with the first base link of the first robot arm of the first pair of the first and second robot arms, a corresponding second portion that is fixedly connected with the first intermediate arm link of the first robot arm of the first pair of the first and second robot arms, and a corresponding bridging portion that spans between the corresponding first portion and the corresponding second portion of the first outer bypass portion and that is positioned such that the corresponding bridging portion of the first outer bypass portion is positioned further from the first axis of the first robot arm of the first pair of the first and second robot arms than the corresponding bridging portion of the first inner bypass portion when the first robot arm of the first pair of the first and second robot arms is in the first retracted state.

15. The system of claim 14, wherein:
the first base link length, the second base link length, the first intermediate arm link length, and the second intermediate arm link length for a second pair of the first and second robot arms located on an opposite side of the reference plane of the torso unit are all the same,
the first axis and the second axis of the second pair of the first and second robot arms are coaxial,
the first base link of the first robot arm of the second pair of the first and second robot arms is fixed in space with respect to a corresponding second inner bypass portion,
the first intermediate arm link of the first robot arm of the second pair of the first and second robot arms is fixed in space with respect to a corresponding second outer bypass portion,
the second inner bypass portion includes a corresponding first portion that is fixedly connected with the first base link of the first robot arm of the second pair of the first and second robot arms, a corresponding second portion that is rotatably connected with the first intermediate arm link of the first robot arm of the second pair of the first and second robot arms, and a corresponding bridging portion that spans between the corresponding first portion and the corresponding second portion of the second inner bypass portion and that is positioned such that the corresponding bridging portion of the second inner bypass portion is positioned further from the first axis of the first robot arm of the second pair of the first and second robot arms than the corresponding rotational axis about which the corresponding first intermediate arm link of the first robot arm of the second pair of the first and second robot arms is configured to rotate relative to the first base link of the first robot arm of the second pair of the first and second robot arms, and
the second outer bypass portion includes a corresponding first portion that is rotatably connected with the first base link of the first robot arm of the second pair of the first and second robot arms, a corresponding second portion that is fixedly connected with the first intermediate arm link of the first robot arm of the second pair of the first and second robot arms, and a corresponding bridging portion that spans between the corresponding first portion and the corresponding second portion of the second outer bypass portion and that is positioned such that the corresponding bridging portion of the second outer bypass portion is positioned further from the first axis of the first robot arm of the second pair of the first and second robot arms than the corresponding bridging portion of the second inner bypass portion when the first robot arm of the second pair of the first and second robot arms is in the first retracted state.

16. The system of claim 15, wherein the first pair of first and second robot arms and the second pair of first and second robot arms are arranged symmetrically with respect to the reference plane.

17. The system of claim 9, wherein the first axes are spaced apart by a distance that is different than a distance that the second axes are spaced apart by.

18. The system of claim 1, wherein:
the first end effector support arms each have a corresponding first portion, a corresponding second portion, and a corresponding offset jog portion;
the corresponding first portion and the corresponding second portion of each of the first end effector support arms extend along parallel axes that are offset from one another in a direction perpendicular to those parallel axes, and
the corresponding offset jog portion of each of the first end effector support arms spans between the corresponding first portion and the corresponding second portion of that first end effector support arm.

19. The system of claim 18, wherein:
the second end effector support arms each have a corresponding first portion, a corresponding second portion, and a corresponding offset jog portion;
the corresponding first portion and the corresponding second portion of each of the second end effector support arms extend along parallel axes that are offset from one another in a direction perpendicular to those parallel axes, and
the corresponding offset jog portion of each of the second end effector support arms spans between the corresponding first portion and the corresponding second portion of that second end effector support arm.

20. The system of claim 1, further comprising a transfer chamber, wherein:
the base is fixedly mounted with respect to the transfer chamber,
the torso unit is located at least partially within the transfer chamber,
the first robot arms are located entirely within the transfer chamber when in the first retracted state,
the second robot arms are located entirely within the transfer chamber when in the second retracted state, and
the torso unit, along with the first robot arms and the second robot arms, is rotatable by at least 90° within and relative to the transfer chamber when the first robot arms are in the first retracted state and the second robot arms are in the second retracted state.
